(19) United States
(12) Patent Application Publication
(10) Pub. No.: US 2026/0019078 A1
(43) Pub. Date: Jan. 15, 2026

(54) ISOLATION SWITCH AND SEQUENCER

(71) Applicant: ROHM CO., LTD., Kyoto-shi (JP)

(72) Inventor: Koji SAITO, Kyoto-shi (JP)

(21) Appl. No.: 19/335,327

(22) Filed: Sep. 22, 2025

Related U.S. Application Data
(63) Continuation of application No. PCT/JP2024/001304, filed on Jan. 18, 2024.

(30) Foreign Application Priority Data
Mar. 29, 2023 (JP) 2023-052960
Aug. 10, 2023 (JP) 2023-130700

(51) Int. Cl. H03K 17/691; H03K 17/082; H03K 17/74

(52) U.S. Cl. CPC H03K 17/691; H03K 17/082; H03K 17/74

(57) ABSTRACT

A conduction circuit includes a first primary coil that is connected to a pulse supply circuit, and a first secondary coil that is electromagnetically coupled to the first primary coil. The pulse supply circuit is configured to supply a pulse signal to the first primary coil under a state in which a control signal is at a first level, and supply a pulse signal to a second primary coil for a certain period after a time point when the control signal is switched from the first level to a second level that is different from the first level.

### CROSS REFERENCE TO RELATED APPLICATIONS

This application is a continuation under 35 U.S.C. § 120 of PCT/JP2024/001304 filed on Jan. 18, 2024, which is incorporated herein by reference, and which claimed priority Japanese Patent Application No. 2023-052960 filed on Mar. 29, 2023, and Japanese Patent Application No. 2023-130700 filed on Aug. 10, 2023. The present application likewise claims priority under 35 U.S.C. § 119 to Japanese Application No. No. 2023-052960 filed on Mar. 29, 2023, and Japanese Patent Application No. 2023-130700 filed on Aug. 10, 2023, the entire content of which is also incorporated herein by reference.

### TECHNICAL FIELD

The present disclosure relates to isolation switches and sequencers using the isolation switches. Moreover, the present disclosure relates to signal transmission devices.

### BACKGROUND ART

Hitherto, switches that isolate a primary circuit and a secondary circuit from each other by using photocouplers have been employed (e.g., refer to Patent Document 1).

Moreover, signal transmission devices that transmit a signal between a primary circuit system and a secondary circuit system while electrically isolating between the primary circuit system and the secondary circuit system are used in various applications (e.g., power supply devices or motor driving devices).

Note that, Patent Document 2, which is another disclosure by the present applicant, can be cited as one example of the related art that relates to the above description.

### CITATION LIST

### Patent Literature

Patent Document 1: JP-A-2020-096051
Patent Document 2: WO-A-2022/070944

### BRIEF DESCRIPTION OF DRAWINGS

FIG. 1 is a diagram illustrating the basic configuration of a signal transmission device.

FIG. 2 is a diagram illustrating the basic structure of a transformer chip.

FIG. 3 is a perspective view of a semiconductor device used as a two-channel transformer chip.

FIG. 4 is a plan view of the semiconductor device shown in FIG. 3.

FIG. 5 is a plan view of a layer in the semiconductor device shown in FIG. 3 where low-potential coils are formed.

FIG. 6 is a plan view of a layer in the semiconductor device shown in FIG. 3 where high-potential coils are formed.

FIG. 7 is a cross-sectional view taken along line VIII-VIII shown in FIG. 6.

FIG. 8 is an enlarged view (showing a separation structure) of region XIII shown in FIG. 7.

FIG. 9 is a diagram schematically showing an example of the layout of a transformer chip.

FIG. 10 is a diagram showing the first embodiment of signal transmission devices.

FIG. 11 is a chart showing a first operation example (intermittent) of the first embodiment.

FIG. 12 is a chart showing a second operation example (continuous) of the first embodiment.

FIG. 13 is a diagram showing a second embodiment of the signal transmission devices.

FIG. 14 is a diagram showing a third embodiment of the signal transmission devices.

FIG. 15 is a chart showing an operation example of the third embodiment.

FIG. 16 is a diagram showing a fourth embodiment of the signal transmission devices.

FIG. 17 is a diagram showing a fifth embodiment of the signal transmission devices.

FIG. 18 is a diagram showing a sixth embodiment of the signal transmission devices.

FIG. 19 is a chart showing an operation example of the sixth embodiment.

FIG. 20 is a diagram showing a seventh embodiment of the signal transmission devices.

FIG. 21 is a diagram showing an eighth embodiment of the signal transmission devices.

FIG. 22 is a chart showing an operation example of the eighth embodiment.

FIG. 23 is a schematic circuit diagram showing an embodiment of an isolation switch according to the embodiments of the present disclosure.

FIG. 24 is a timing chart showing the operation of the isolation switch.

FIG. 25 is a timing chart showing the operation of the isolation switch of a first modification.

FIG. 26 is a schematic circuit diagram of an isolation switch of a second modification.

FIG. 27 is a timing chart showing the operation of the isolation switch of the second modification.

FIG. 28 is a schematic circuit diagram of an isolation switch of a third modification.

FIG. 29 is a schematic circuit diagram of an isolation switch of a fourth modification.

FIG. 30 is a schematic circuit diagram of an isolation switch of a fifth modification.

FIG. 31 is a timing chart showing the operation of the isolation switch of the fifth modification.

FIG. 32 is a schematic circuit diagram of an isolation switch of a sixth modification.

FIG. 33 is a schematic circuit diagram showing another configuration example of the isolation switch of the sixth modification.

FIG. 34 is a schematic circuit diagram of an isolation switch of a seventh modification.

FIG. 35 is a timing chart showing the operation of the isolation switch of the seventh modification.

FIG. 36 is a diagram showing an additional embodiment of the isolation switches.

FIG. 37 is a diagram showing a first main part of the isolation switch according to the additional embodiment.

FIG. 38 is a chart showing an operation example of the first main part.

FIG. 39 is a diagram showing a second main part of the isolation switch according to the additional embodiment.

FIG. 40 is a diagram showing a third main part of the isolation switch according to the additional embodiment.

FIG. 41 is a diagram showing a third chip in the third main part.

FIG. 42 is a diagram showing a modification of the third main part.

FIG. 43 is a diagram showing the third chip in the modification of the third main part.

FIG. 44 is a diagram showing a modification of the second chip.

FIG. 45 is a chart showing an operation example of the second chip of the modification.

FIG. 46 is a diagram showing an additional embodiment of the signal transmission devices.

FIG. 47 is a diagram showing a configuration example of an isolation supply circuit.

FIG. 48 is a diagram showing a modification of the signal transmission device according to the additional embodiment.

FIG. 49 is a diagram showing a modification of the isolation supply circuit.

FIG. 50 is a diagram showing a modification of inquiring isolation devices.

### DESCRIPTION OF EMBODIMENTS

### Detailed Description

In the following description, exemplary embodiments of the present disclosure will be described in detail referring to the drawings. In all the drawings to be referred to, the same components are denoted by the same reference symbols, and no redundant description will be given of the same components in principle.

First, some of the terms used in the embodiments of the present disclosure will be described. The “connection” between a plurality of parts that form a circuit, such as any devices, wirings (lines), and nodes encompasses not only cases of mechanical connection but also cases of electrical connection, that is, states in which current is allowed to flow. That is, the “connection” encompasses cases of “electrical connection.”

The line refers to wirings through which electrical signals are propagated or supplied. The ground potential refers to a reference conductive portion with a potential of 0 V as a reference, or refers to the potential of 0 V itself. The reference conductive portion is formed of a conductor such as a metal. The potential of 0 V may sometimes be referred to as the ground potential. In the embodiments of the present disclosure, voltages described without particular reference represent potentials with respect to the ground potential.

The “level” represents levels of potentials, and any signals or voltages at Hi level have potentials higher than those at Lo level. Any digital signals are at signal levels of Hi level or Lo level. With regard to any specific signal or voltage, strict meaning of “a signal or a voltage is at Hi level” is “a level of a signal or a voltage is at Hi level,” and strict meaning of “a signal or a voltage is at Lo level” is “a level of a signal or a voltage is at Lo level.” The level of the signal may be expressed as the signal level, and the level of the voltage may be expressed as a voltage level. With regard to any specific signal, an inverted signal of this signal is at Lo level when this signal is at Hi level, and the inverted signal of this signal is at Hi level when this signal is at Lo level. Note that, Hi level may sometimes be referred to as first level.

With regard to any signal at the signal level of Hi level or Lo level, a period during which the level of the signal is at Hi level is referred to as Hi-level period. Likewise, a period during which the level of the signal is at Lo level is referred to as Lo-level period. The same applies to any voltage at the voltage level of Hi level or Lo level.

Switching devices are turned on or turned off. Under a state in which the switching device has been turned on, conduction between both the terminals of the switch is established. On the other hand, under a state in which the switching device has been turned off, the conduction between both the terminals of the switch is unestablished. Moreover, a period during which the switching device has been turned on is referred to as ON period, and a period during which the switching device has been turned off is referred to as OFF period. Likewise, switching on of the switching device that has been turned off may sometimes be referred to as turn-on, and switching off of the switching device that has been turned on may sometimes be referred to as turn-off.

An MOS (Metal Oxide Semiconductor) field-effect transistor may be used as an example of the switching device. The MOS field-effect transistor refers to a transistor with a gate structure constituted by at least three layers of “a layer formed of a conductor or a semiconductor such as polysilicon with a small resistance value,” “an insulation layer,” and “a P-channel, an N-channel, or an intrinsic semiconductor layer.” That is, the gate structure of the MOS field-effect transistor is not limited to the three-layer structure constituted by a metal, an oxide, and a semiconductor.

With regard to any transistor configured as a field-effect transistor such as the MOS field-effect transistor, under a state in which the transistor has been turned on, conduction between the drain and the source of the transistor is established. Likewise, under a state in which the transistor has been turned off, the conduction between the drain and the source is unestablished (cut off). The same applies to transistors that are not classified as the field-effect transistors. In any MOS field-effect transistors described below, unless otherwise noted, the backgate is connected to the source. Note that, in the following description, the MOS field-effect transistor may sometimes be simply referred to as MOS transistor.

### <Signal Transmission Device (Basic Configuration)>

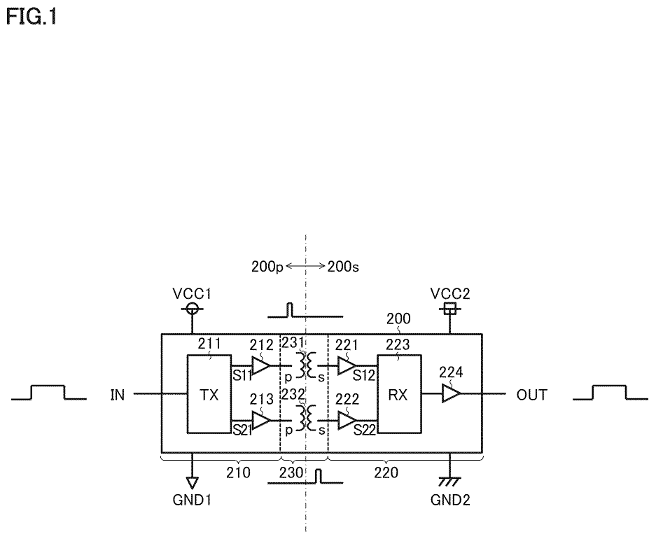

FIG. 1 is a diagram illustrating the basic configuration of a signal transmission device. The signal transmission device 200 of this configuration example is a semiconductor integrated circuit device (what is generally called an isolated gate driver IC) that, while isolating between a primary circuit system 200p (VCC1-GND1 system) and a secondary circuit system 200s (VCC2-GND2 system), transmits a pulse signal from the primary circuit system 200p to the secondary circuit system 200s to drive the gate of a switching device (unillustrated) provided in the secondary circuit system 200s. The signal transmission device 200 has, for example, a controller chip 210, a driver chip 220, and a transformer chip 230 sealed in a single package.

The controller chip 210 is a semiconductor chip that operates by being supplied with a supply voltage VCC1 (e.g., seven volts at the maximum with respect to GND1). The controller chip 210 has, for example, a pulse transmission circuit 211 and buffers 212 and 213 integrated in it.

The pulse transmission circuit 211 is a pulse generator that generates transmission pulse signals S11 and S21 according to an input pulse signal IN. More specifically, when indicating that the input pulse signal IN is at high level, the pulse transmission circuit 211 pulse-drives (outputs a single or a plurality of pulses in) the transmission pulse signal S11; when indicating that the input pulse signal IN is at low level, the pulse transmission circuit 211 pulse-drives the transmission pulse signal S21. That is, the pulse transmission circuit 211 pulse-drives either the transmission pulse signal S11 or S21 according to the logic level of the input pulse signal IN.

The buffer 212 receives the transmission pulse signal S11 from the pulse transmission circuit 211, and pulse-drives the transformer chip 230 (more specifically, a transformer 231).

The buffer 213 receives the transmission pulse signal S21 from the pulse transmission circuit 211, and pulse-drives the transformer chip 230 (more specifically, a transformer 232).

The driver chip 220 is a semiconductor chip that operates by being supplied with a supply voltage VCC2 (e.g., 30 volts at the maximum with respect to GND2). The driver chip 220 has, for example, buffers 221 and 222, a pulse reception circuit 223, and a driver 224 integrated in it.

The buffer 221 performs waveform shaping on a reception pulse signal S12 induced in the transformer chip 230 (specifically, the transformer 231), and outputs the result to the pulse reception circuit 223.

The buffer 222 performs waveform shaping on a reception pulse signal S22 induced in the transformer chip 230 (specifically, the transformer 232), and outputs the result to the pulse reception circuit 223.

According to the reception pulse signals S12 and S22 fed to it via the buffers 221 and 222, the pulse reception circuit 223 drives the driver 224 to generate an output pulse signal OUT. More specifically, the pulse reception circuit 223 drives the driver 224 to raise the output pulse signal OUT to high level in response to the reception pulse signal S12 being pulse-driven and to drop the output pulse signal OUT to low level in response to the reception pulse signal S22 being pulse-driven. That is, the pulse reception circuit 223 switches the logic level of the output pulse signal OUT according to the logic level of the input pulse signal IN. As the pulse reception circuit 223, for example, an RS flip-flop can be suitably used.

The driver 224 generates the output pulse signal OUT under the driving and control of the pulse reception circuit 223.

The transformer chip 230, while isolating between the controller chip 210 and the driver chip 220 on a direct-current basis using the transformers 231 and 232, outputs the transmission pulse signals S11 and S21 fed to the transformer chip 230 from the pulse transmission circuit 211 to, as the reception pulse signals S12 and S22, the pulse reception circuit 223. In the present description, “isolating on a direct-current basis” means leaving two elements to be isolated from each other unconnected by a conductor.

More specifically, the transformer 231 outputs, according to the transmission pulse signal S11 fed to the primary coil 231p, the reception pulse signal S12 from the secondary coil 231s. Likewise, the transformer 232 outputs, according to the transmission pulse signal S21 fed to the primary coil 232p, the reception pulse signal S22 from the secondary coil 232s.

In this way, owing to the characteristics of spiral coils used in isolated communication, the input pulse signal IN is split into two transmission pulse signals S11 and S21 (corresponding to a rise signal and a fall signal) to be transmitted via the two transformers 231 and 232 from the primary circuit system 200p to the secondary circuit system 200s.

Note that the signal transmission device 200 of this configuration example has, separately from the controller chip 210 and the driver chip 220, the transformer chip 230 that incorporates the transformers 231 and 232 alone, and those three chips are sealed in a single package.

With this configuration, the controller chip 210 and the driver chip 220 can each be formed by a common low- to middle-withstand-voltage process (with a withstand voltage of several volts to several tens of volts). This eliminates the need for a dedicated high-withstand-voltage process (with a withstand voltage of several kilovolts), and helps reduce manufacturing costs.

The signal transmission device 200 can be employed suitably, for example, in a power supply device or motor driving device in a vehicle-mounted device incorporated in a vehicle. Such a vehicle can be an engine vehicle or an electric vehicle (an xEV such as a BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

### <Transformer Chip (Basic Structure)>

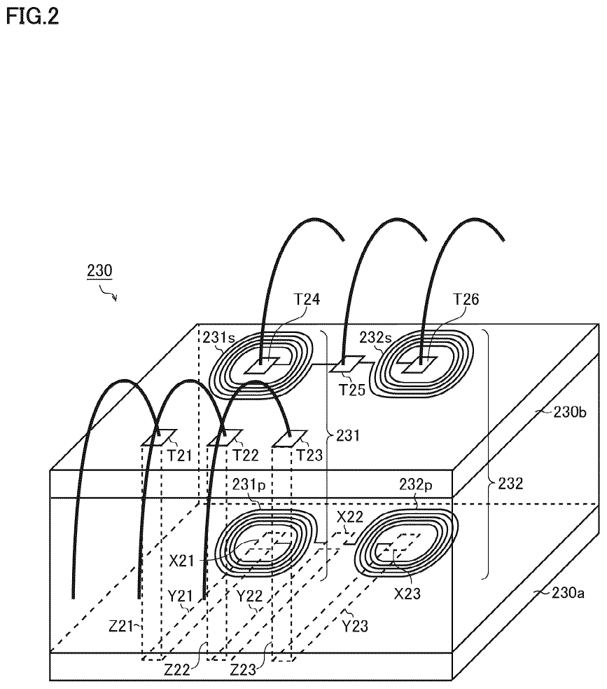

Next, the basic structure of the transformer chip 230 will be described. FIG. 2 is a diagram showing the basic structure of the transformer chip 230. In the transformer chip 230 shown there, the transformer 231 includes a primary coil 231p and a secondary coil 231s that face each other in the up-down direction; the transformer 232 includes a primary coil 232p and a secondary coil 232s that face each other in the up-down direction.

The primary coils 231p and 232p are both formed in a first wiring layer (lower layer) 230a in the transformer chip 230. The secondary coils 231s and 232s are both formed in a second wiring layer (the upper layer in the diagram) 230b in the transformer chip 230. The secondary coil 231s is disposed right above the primary coil 231p and faces the primary coil 231p; the secondary coil 232s is disposed right above the primary coil 232p and faces the primary coil 232p.

The primary coil 231p is laid in a spiral shape so as to encircle an internal terminal X21 clockwise, starting at the first terminal of the primary coil 231p, which is connected to the internal terminal X21. The second terminal of the primary coil 231p, which corresponds to its end point, is connected to an internal terminal X22. Likewise, the primary coil 232p is laid in a spiral shape so as to encircle an internal terminal X23 anticlockwise, starting at the first terminal of the primary coil 232p, which is connected to the internal terminal X23. The second terminal of the primary coil 232p, which corresponds to its end point, is connected to the internal terminal X22. The internal terminals X21, X22, and X23 are arrayed on a straight line in the illustrated order.

The internal terminal X21 is connected, via a wiring Y21 and a via Z21 both conductive, to an external terminal T21 in the second layer 230b. The internal terminal X22 is connected, via a wiring Y22 and a via Z22 both conductive, to an external terminal T22 in the second layer 230b. The internal terminal X23 is connected, via a wiring Y23 and a via Z23 both conductive, to an external terminal T23 in the second layer 230b. The external terminals T21 to T23 are disposed in a straight row and are used for wire-bonding with the controller chip 210.

The secondary coil 231s is laid in a spiral shape so as to encircle an external terminal T24 anticlockwise, starting at the first terminal of the secondary coil 231s, which is connected to the external terminal T24. The second terminal of the secondary coil 231s, which corresponds to its end point, is connected to an external terminal T25. Likewise, the secondary coil 232s is laid in a spiral shape so as to encircle an external terminal T26 clockwise, starting at the first terminal of the secondary coil 232s, which is connected to the external terminal T26. The second terminal of the secondary coil 232s, which corresponds to its end point, is connected to the external terminal T25. The external terminals T24, T25, and T26 are disposed in a straight row in the illustrated order and are used for wire-bonding with the driver chip 220.

The secondary coils 231s and 232s are AC-connected to the primary coils 231p and 232p, respectively, by magnetic coupling, and are DC-isolated from the primary coils 231p and 232p. That is, the driver chip 220 is AC-connected to the controller chip 210 via the transformer chip 230 and is DC-isolated from the controller chip 210 by the transformer chip 230.

### <Transformer Chip (Two-Channel Type)>

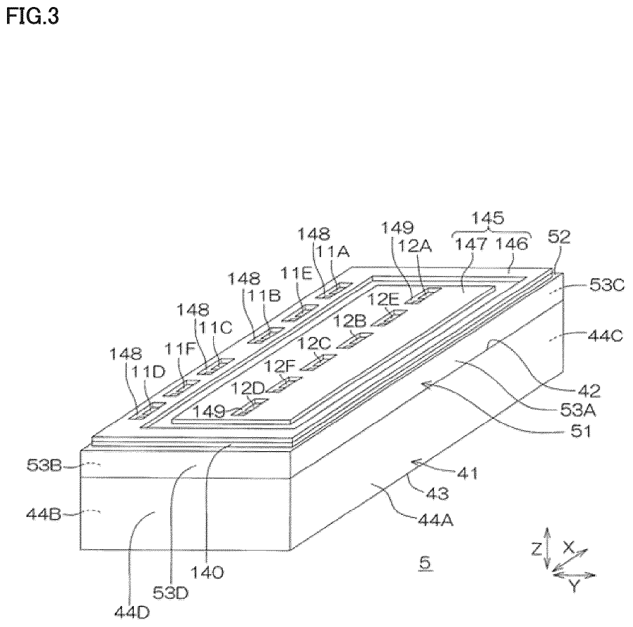

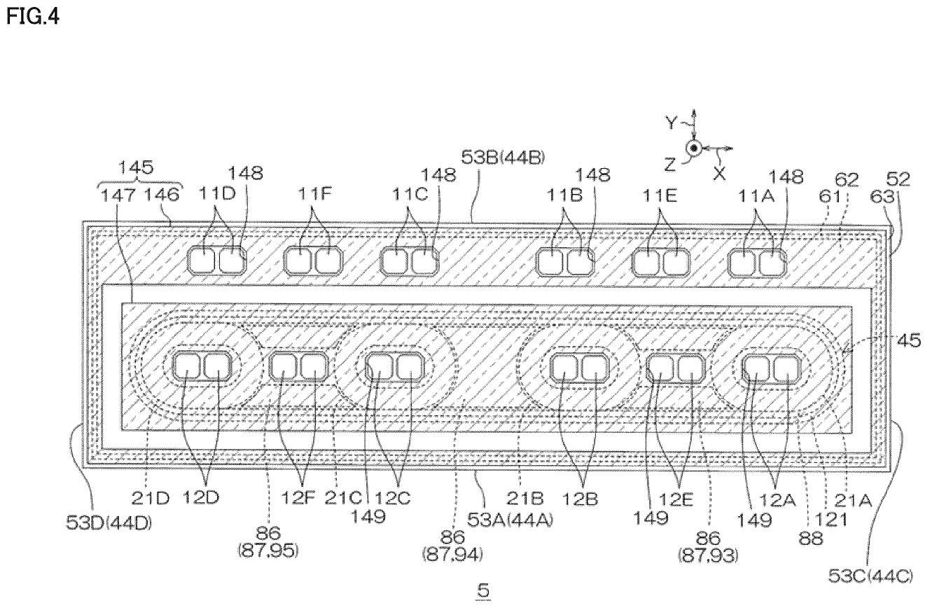

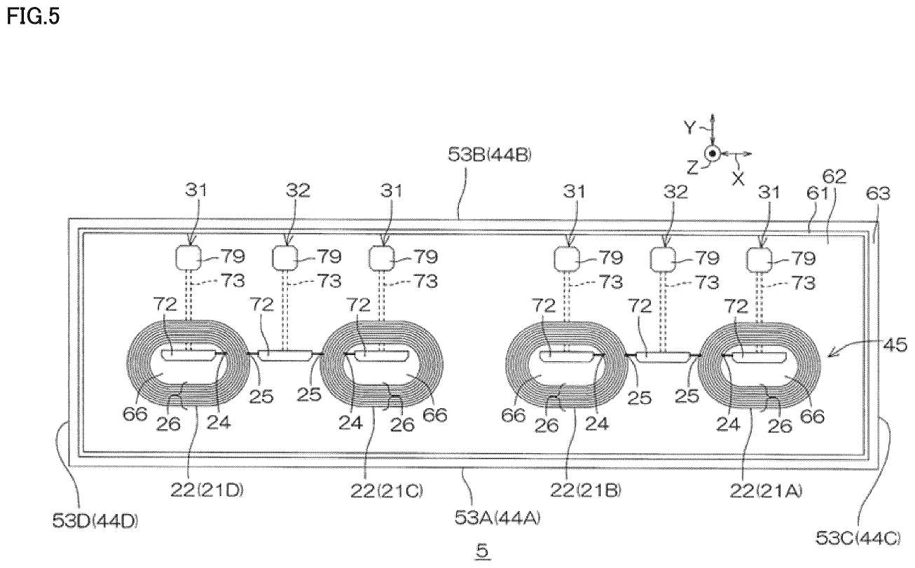

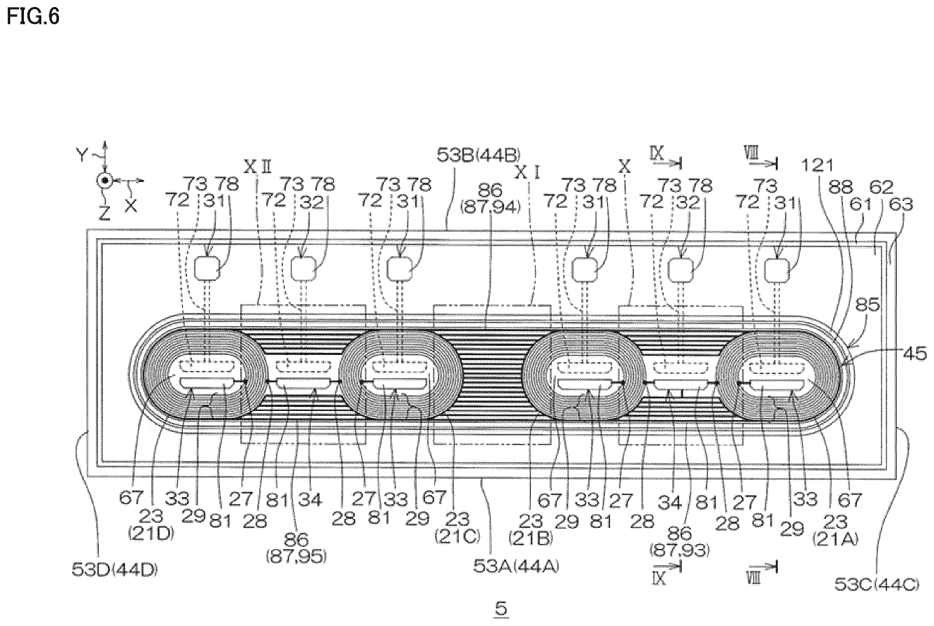

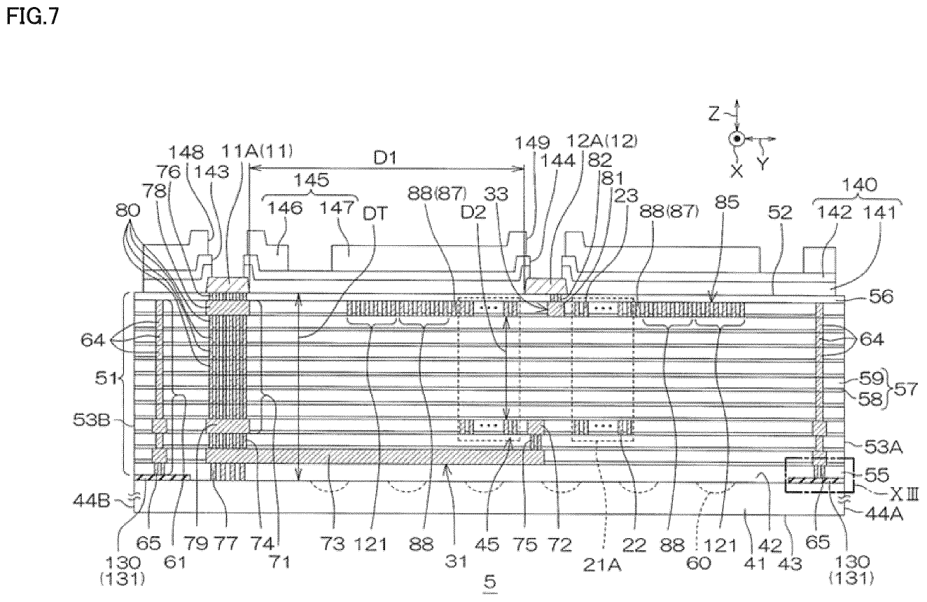

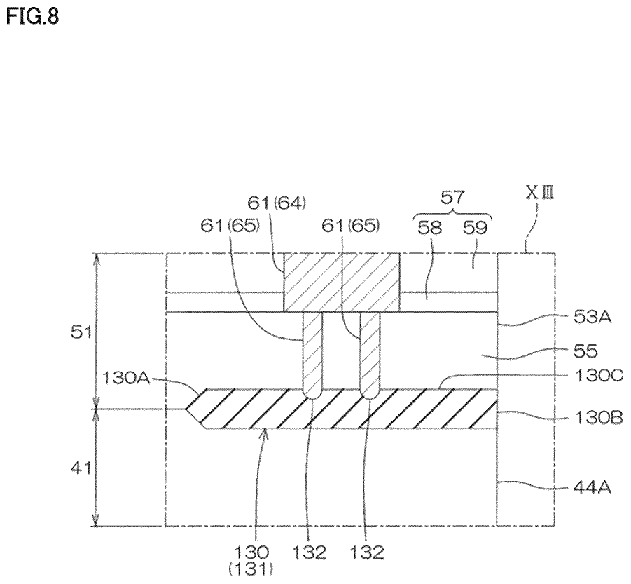

FIG. 3 is a perspective view of a semiconductor device 5 used as a two-channel transformer chip. FIG. 4 is a plan view of the semiconductor device 5 shown in FIG. 3. FIG. 5 is a plan view showing a layer in the semiconductor device 5 shown in FIG. 3 where low-potential coils 22 (corresponding to the primary coils of transformers) are formed. FIG. 6 is a plan view showing a layer in the semiconductor device 5 shown in FIG. 3 where high-potential coils 23 (corresponding to the secondary coils of transformers) are formed. FIG. 7 is a sectional view along line VIII-VIII shown in FIG. 6. FIG. 8 is an enlarged view of region XIII shown in FIG. 7, which shows a separation structure 130.

Referring to FIG. 3 to FIG. 7, the semiconductor device 5 includes a semiconductor chip 41 in the shape of a rectangular parallelepiped. The semiconductor chip 41 contains at least one of silicon, a wide band gap semiconductor, and a compound semiconductor.

The wide band gap semiconductor is a semiconductor with a band gap larger than that of silicon (about 1.12 eV). Preferably, the wide band gap semiconductor has a band gap of 2.0 eV or more. The wide band gap semiconductor can be SiC (silicon carbide). The compound semiconductor can be a III-V group compound semiconductor. The compound semiconductor can contain at least one aluminum nitride (AlN), indium nitride (InN), gallium nitride (GaN), and gallium arsenide (GaAs).

In the embodiment, the semiconductor chip 41 includes a semiconductor substrate made of silicon. The semiconductor chip 41 can be an epitaxial substrate that has a stacked structure composed of a semiconductor substrate made of silicon and an epitaxial layer made of silicon. The semiconductor substrate can be of an n-type or p-type conductivity. The epitaxial layer can be of an n-type or p-type.

The semiconductor chip 41 has a first principal surface 42 at one side, a second principal surface 43 at the other side, and chip side walls 44A to 44D that connect the first and second principal surfaces 42 and 43 together. As seen in a plan view from the normal direction Z to them (hereinafter simply expressed as “as seen in a plan view”), the first and second principal surfaces 42 and 43 are each formed in a quadrangular shape (in the embodiment, in a rectangular shape).

The chip side walls 44A to 44D include a first chip side wall 44A, a second chip side wall 44B, a third chip side wall 44C, and a fourth chip side wall 44D. The first and second chip side walls 44A and 44B constitute the longer sides of the semiconductor chip 41. The first and second chip side walls 44A and 44B extend along a first direction X and face away from each other in a second direction Y. The third and fourth chip side walls 44C and 44D constitute the shorter sides of the semiconductor chip 41. The third and fourth chip side walls 44C and 44D extend in the second direction Y and face away from each other in the first direction X. The chip side walls 44A to 44D have polished surfaces.

The semiconductor device 5 further includes an insulation layer 51 formed on the first principal surface 42 of the semiconductor chip 41. The insulation layer 51 has an insulation principal surface 52 and insulation side walls 53A to 53D. The insulation principal surface 52 is formed in a quadrangular shape (in the embodiment, a rectangular shape) that fits the first principal surface 42 as seen in a plan view. The insulation principal surface 52 extends parallel to the first principal surface 42.

The insulation side walls 53A to 53D include a first insulation side wall 53A, a second insulation side wall 53B, a third insulation side wall 53C, and a fourth insulation side wall 53D. The insulation side walls 53A to 53D extend from the circumferential edge of the insulation principal surface 52 toward the semiconductor chip 41, and are continuous with the chip side walls 44A to 44D. Specifically, the insulation side walls 53A to 53D are formed to be flush with the chip side walls 44A to 44D. The insulation side walls 53A to 53D constitute polished surfaces that are flush with the chip side walls 44A to 44D.

The insulation layer 51 has a stacked structure of multilayer insulation layers that include a bottom insulation layer 55, a top insulation layer 56, and a plurality of (in the embodiment, eleven) interlayer insulation layers 57. The bottom insulation layer 55 is an insulation layer that directly covers the first principal surface 42. The top insulation layer 56 is an insulation layer that constitutes the insulation principal surface 52. The plurality of interlayer insulation layers 57 are insulation layers that are interposed between the bottom and top insulation layers 55 and 56. In the embodiment, the bottom insulation layer 55 has a single-layer structure that contains silicon oxide. In the embodiment, the top insulation layer 56 has a single-layer structure that contains silicon oxide. The bottom and top insulation layers 55 and 56 can each have a thickness of 1 μm or more but 3 μm or less (e.g., about 2 μm).

The plurality of interlayer insulation layers 57 each have a stacked structure that includes a first insulation layer 58 at the bottom insulation layer 55 side and a second insulation layer 59 at the top insulation layer 56 side. The first insulation layer 58 can contain silicon nitride. The first insulation layer 58 is formed as an etching stopper layer for the second insulation layer 59. The first insulation layer 58 can have a thickness of 0.1 μm or more but 1 μm or less (e.g., about 0.3 μm).

The second insulation layer 59 is formed on top of the first insulation layer 58 and contains an insulating material different from that of the first insulation layer 58. The second insulation layer 59 can contain silicon oxide. The second insulation layer 59 can have a thickness of 1 μm or more but 3 μm or less (e.g., about 2 μm). Preferably, the second insulation layer 59 is given a thickness larger than that of the first insulation layer 58.

The insulation layer 51 can have a total thickness DT of 5 μm or more but 50 μm or less. The insulation layer 51 can have any total thickness DT and any number of interlayer insulation layers 57 stacked together, which are adjusted according to the desired dielectric strength voltage (dielectric breakdown withstand voltage). The bottom insulation layer 55, the top insulation layer 56, and the interlayer insulation layers 57 can employ any insulating material, which is thus not limited to any particular insulating material.

The semiconductor device 5 includes a first functional device 45 formed in the insulation layer 51. The first functional device 45 includes one or a plurality of (in the embodiment, a plurality of) transformers 21 (corresponding to the transformers mentioned previously). That is, the semiconductor device 5 is a multichannel device that includes a plurality of transformers 21. The plurality of transformers 21 are formed in an inner part of the insulation layer 51, at intervals from the insulation side walls 53A to 53D. The plurality of transformers 21 are formed at intervals from each other in the first direction X.

Specifically, the plurality of transformers 21 include a first transformer 21A, a second transformer 21B, a third transformer 21C, and a fourth transformer 21D that are formed in this order from the insulation side wall 53C side to the insulation side wall 53D side as seen in a plan view. The plurality of transformers 21A to 21D have similar structures. In the following description, the structure of the first transformer 21A will be described as an example. No separate description will be given of the structures of the second, third, and fourth transformers 21B, 21C, and 21D, to which the description of the structure of the first transformer 21A is to be taken to apply.

Referring to FIG. 5 to FIG. 7, the first transformer 21A includes a low-potential coil 22 and a high-potential coil 23. The low-potential coil 22 is formed in the insulation layer 51. The high-potential coil 23 is formed in the insulation layer 51 so as to face the low-potential coil 22 in the normal direction Z. In the embodiment, the low- and high-potential coils 22 and 23 are formed in a region between the bottom and top insulation layers 55 and 56 (i.e., in the plurality of interlayer insulation layers 57).

The low-potential coil 22 is formed in the insulation layer 51, at the bottom insulation layer 55 (semiconductor chip 41) side, and the high-potential coil 23 is formed in the insulation layer 51, at the top insulation layer 56 (insulation principal surface 52) side with respect to the low-potential coil 22. That is, the high-potential coil 23 faces the semiconductor chip 41 across the low-potential coil 22. The low- and high-potential coils 22 and 23 can be disposed at any places. The high-potential coil 23 can face the low-potential coil 22 across one or more interlayer insulation layers 57.

The distance between the low- and high-potential coils 22 and 23 (i.e., the number of interlayer insulation layers 57 stacked together) is adjusted appropriately according to the dielectric strength voltage and electric field strength between the low- and high-potential coils 22 and 23. In the embodiment, the low-potential coil 22 is formed in the third interlayer insulation layer 57 as counted from the bottom insulation layer 55 side. In the embodiment, the high-potential coil 23 is formed in the first interlayer insulation layer 57 as counted from the top insulation layer 56 side.

The low-potential coil 22 is embedded in the interlayer insulation layer 57 so as to penetrate the first and second insulation layers 58 and 59. The low-potential coil 22 includes a first inner end 24, a first outer end 25, and a first spiral portion 26 that is patterned in a spiral shape between the first inner and outer ends 24 and 25. The first spiral portion 26 is patterned in a spiral shape that extends in an elliptical (oval) shape as seen in a plan view. The part of the first spiral portion 26 that forms its inner circumferential edge defines a first inner region 66 that is in an elliptical shape as seen in a plan view.

The first spiral portion 26 can have a number of turns of 5 or more but 30 or less. The first spiral portion 26 can have a width of 0.1 μm or more but 5 μm or less. Preferably, the first spiral portion 26 has a width of 1 μm or more but 3 μm or less. The width of the first spiral portion 26 is defined by its width in the direction orthogonal to the spiraling direction. The first spiral portion 26 has a first winding pitch of 0.1 μm or more but 5 μm or less. Preferably, the first winding pitch is 1 μm or more but 3 μm or less. The first winding pitch is defined by the distance between two parts of the first spiral portion 26 that are adjacent to each other in the direction orthogonal to the spiraling direction.

The first spiral portion 26 can have any winding shape and the first inner region 66 can have any planar shape, which are thus not limited to those shown in FIG. 5 etc. The first spiral portion 26 can be wound in a polygonal shape, such as a triangular or quadrangular shape, or in a circular shape as seen in a plan view. The first inner region 66 can be defined, so as to fit the winding shape of the first spiral portion 26, in a polygonal shape, such as a triangular or quadrangular shape, or in a circular shape as seen in a plan view.

The low-potential coil 22 can contain at least one of titanium, titanium nitride, copper, aluminum, and tungsten. The low-potential coil 22 can have a stacked structure composed of a barrier layer and a body layer. The barrier layer defines a recessed space in the interlayer insulation layer 57. The barrier layer can contain at least one of titanium and titanium nitride. The body layer can contain at least one of copper, aluminum, and tungsten.

The high-potential coil 23 is embedded in the interlayer insulation layer 57 so as to penetrate the first and second insulation layers 58 and 59. The high-potential coil 23 includes a second inner end 27, a second outer end 28, and a second spiral portion 29 that is patterned in a spiral shape between the second inner and outer ends 27 and 28. The second spiral portion 29 is patterned in a spiral shape that extends in an elliptical (oval) shape as seen in a plan view. The part of the second spiral portion 29 that forms its inner circumferential edge defines a second inner region 67 that is in an elliptical shape as seen in a plan view in the embodiment. The second inner region 67 in the second spiral portion 29 faces the first inner region 66 in the first spiral portion 26 in the normal direction Z.

The second spiral portion 29 can have a number of turns of 5 or more but 30 or less. The number of turns of the second spiral portion 29 relative to that of the first spiral portion 26 is adjusted according to the target value of voltage boosting. Preferably, the number of turns of the second spiral portion 29 is larger than that of the first spiral portion 26. Needless to say, the number of turns of the second spiral portion 29 can be smaller than or equal to that of the first spiral portion 26.

The second spiral portion 29 can have a width of 0.1 μm or more but 5 μm or less. Preferably, the second spiral portion 29 has a width of 1 μm or more but 3 μm or less. The width of the second spiral portion 29 is defined by its width in the direction orthogonal to the spiraling direction. Preferably, the width of the second spiral portion 29 is equal to the width of the first spiral portion 26.

The second spiral portion 29 can have a second winding pitch of 0.1 μm or more but 5 μm or less. Preferably, the second winding pitch is 1 μm or more but 3 μm or less. The second winding pitch is defined by the distance between two parts of the second spiral portion 29 that are adjacent to each other in the direction orthogonal to the spiraling direction. Preferably, the second winding pitch is equal to the first winding pitch of the first spiral portion 26.

The second spiral portion 29 can have any winding shape and the second inner region 67 can have any planar shape, which are thus not limited to those shown in FIG. 6 etc. The second spiral portion 29 can be wound in a polygonal shape, such as a triangular or quadrangular shape, or in a circular shape as seen in a plan view. The second inner region 67 can be defined, so as to fit the winding shape of the second spiral portion 29, in a polygonal shape, such as a triangular or quadrangular shape, or in a circular shape as seen in a plan view.

Preferably, the high-potential coil 23 is formed of the same conductive material as the low-potential coil 22. That is, preferably, like the low-potential coil 22, the high-potential coil 23 includes a barrier layer and a body layer.

Referring to FIG. 4, the semiconductor device 5 includes a plurality of (in the diagram, twelve) low-potential terminals 11 and a plurality of (in the diagram, twelve) high-potential terminals 12. The plurality of low-potential terminals 11 are electrically connected to the low-potential coils 22 of the corresponding transformers 21A to 21D, respectively. The plurality of high-potential terminals 12 are electrically connected to the high-potential coils 23 of the corresponding transformers 21A to 21D respectively.

The plurality of low-potential terminals 11 are formed on the insulation principal surface 52 of the insulation layer 51. Specifically, the plurality of low-potential terminals 11 are formed in a second insulation side wall 53B side region, at an interval from the plurality of transformers 21A to 21D in the second direction Y, and are arrayed at intervals from each other in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. Actually, in the embodiment, two each of the plurality of low-potential terminals 11A to 11F are formed. The plurality of low-potential terminals 11A to 11F may each include any number of terminals.

The first low-potential terminal 11A faces the first transformer 21A in the second direction Y as seen in a plan view. The second low-potential terminal 11B faces the second transformer 21B in the second direction Y as seen in a plan view. The third low-potential terminal 11C faces the third transformer 21C in the second direction Y as seen in a plan view. The fourth low-potential terminal 11D faces the fourth transformer 21D in the second direction Y as seen in a plan view. The fifth low-potential terminal 11E is formed in a region between the first and second low-potential terminals 11A and 11B as seen in a plan view. The sixth low-potential terminal 11F is formed in a region between the third and fourth low-potential terminals 11C and 11D as seen in a plan view.

The first low-potential terminal 11A is electrically connected to the first inner end 24 of the first transformer 21A (low-potential coil 22). The second low-potential terminal 11B is electrically connected to the first inner end 24 of the second transformer 21B (low-potential coil 22). The third low-potential terminal 11C is electrically connected to the first inner end 24 of the third transformer 21C (low-potential coil 22). The fourth low-potential terminal 11D is electrically connected to the first inner end 24 of the fourth transformer 21D (low-potential coil 22).

The fifth low-potential terminal 11E is electrically connected to the first outer end 25 of the first transformer 21A (low-potential coil 22) and to the first outer end 25 of the second transformer 21B (low-potential coil 22). The sixth low-potential terminal 11F is electrically connected to the first outer end 25 of the third transformer 21C (low-potential coil 22) and to the first outer end 25 of the fourth transformer 21D (low-potential coil 22).

The plurality of high-potential terminals 12 are formed on the insulation principal surface 52 of the insulation layer 51, at an interval from the plurality of low-potential terminals 11. Specifically, the plurality of high-potential terminals 12 are formed in a first insulation side wall 53A side region, at an interval from the plurality of low-potential terminals 11 in the second direction Y, and are arrayed at intervals from each other in the first direction X.

The plurality of high-potential terminals 12 are formed in regions close to the corresponding transformers 21A to 21D, respectively, as seen in a plan view. The high-potential terminals 12 being close to the transformers 21A to 21D means that, as seen in a plan view, the distance between the high-potential terminals 12 and the transformers 21 is smaller than the distance between the low-potential terminals 11 and the high-potential terminals 12.

Specifically, as seen in a plan view, the plurality of high-potential terminals 12 are formed at intervals from each other along the first direction X so as to face the plurality of transformers 21A to 21D along the first direction X. More specifically, as seen in a plan view, the plurality of high-potential terminals 12 are formed at intervals from each other along the first direction X so as to be located in the second inner regions 67 in the high-potential coils 23 and in regions between adjacent high-potential coils 23. As a result, as seen in a plan view, the plurality of high-potential terminals 12 are, along with the transformers 21A to 21D, arrayed in one row along the first direction X.

The plurality of high-potential terminals 12 include a first high-potential terminal 12A, a second high-potential terminal 12B, a third high-potential terminal 12C, a fourth high-potential terminal 12D, a fifth high-potential terminal 12E, and a sixth high-potential terminal 12F. Actually, in the embodiment, two each of the plurality of high-potential terminals 12A to 12F are formed. The plurality of high-potential terminals 12A to 12F may each include any number of terminals.

The first high-potential terminal 12A is formed in the second inner region 67 in the first transformer 21A (high-potential coil 23) as seen in a plan view. The second high-potential terminal 12B is formed in the second inner region 67 in the second transformer 21B (high-potential coil 23) as seen in a plan view. The third high-potential terminal 12C is formed in the second inner region 67 in the third transformer 21C (high-potential coil 23) as seen in a plan view. The fourth high-potential terminal 12D is formed in the second inner region 67 in the fourth transformer 21D (high-potential coil 23) as seen in a plan view. The fifth high-potential terminal 12E is formed in a region between the first and second transformers 21A and 21B as seen in a plan view. The sixth high-potential terminal 12F is formed in a region between the third and fourth transformers 21C and 21D as seen in a plan view.

The first high-potential terminal 12A is electrically connected to the second inner end 27 of the first transformer 21A (high-potential coil 23). The second high-potential terminal 12B is electrically connected to the second inner end 27 of the second transformer 21B (high-potential coil 23). The third high-potential terminal 12C is electrically connected to the second inner end 27 of the third transformer 21C (high-potential coil 23). The fourth high-potential terminal 12D is electrically connected to the second inner end 27 of the fourth transformer 21D (high-potential coil 23).

The fifth high-potential terminal 12E is electrically connected to the second outer end 28 of the first transformer 21A (high-potential coil 23) and to the second outer end 28 of the second transformer 21B (high-potential coil 23). The sixth high-potential terminal 12F is electrically connected to the second outer end 28 of the third transformer 21C (high-potential coil 23) and to the second outer end 28 of the fourth transformer 21D (high-potential coil 23).

Referring to FIG. 5 and FIG. 7, the semiconductor device 5 includes a first low-potential wiring 31, a second low-potential wiring 32, a first high-potential wiring 33, and a second high-potential wiring 34, all formed in the insulation layer 51. Actually, in the embodiment, a plurality of first low-potential wirings 31, a plurality of second low-potential wirings 32, a plurality of first high-potential wirings 33, and a plurality of second high-potential wirings 34 are formed.

The first and second low-potential wirings 31 and 32 hold the low-potential coils 22 of the first and second transformers 21A and 21B at equal potentials. The first and second low-potential wirings 31 and 32 also hold the low-potential coils 22 of the third and fourth transformers 21C and 21D at equal potentials. In the embodiment, the first and second low-potential wirings 31 and 32 hold the low-potential coils 22 of all the transformers 21A to 21D at equal potentials.

The first and second high-potential wirings 33 and 34 hold the high-potential coils 23 of the first and second transformers 21A and 21B at equal potentials. The first and second high-potential wirings 33 and 34 also hold the high-potential coils 23 of the third and fourth transformers 21C and 21D at equal potentials. In the embodiment, the first and second high-potential wirings 33 and 34 hold the high-potential coils 23 of all the transformers 21A to 21D at equal potentials.

The plurality of first low-potential wirings 31 are electrically connected respectively to the corresponding low-potential terminals 11A to 11D and to the first inner ends 24 of the corresponding transformers 21A to 21D (low-potential coils 22). The plurality of first low-potential wirings 31 have similar structures. In the following description, the structure of the first low-potential wiring 31 connected to the first low-potential terminal 11A and to the first transformer 21A will be described as an example. No separate description will be given of the structures of the other first low-potential wirings 31, to which the description of the structure of the first low-potential wiring 31 connected to the first transformer 21A is to be taken to apply.

The first low-potential wiring 31 includes a through wiring 71, a low-potential connection wiring 72, a lead wiring 73, a first connection plug electrode 74, a second connection plug electrode 75, one or a plurality of (in this embodiment, a plurality of) pad plug electrodes 76, and one or a plurality of (in this embodiment, a plurality of) substrate plug electrodes 77.

Preferably, the through wiring 71, the low-potential connection wiring 72, the lead wiring 73, the first connection plug electrode 74, the second connection plug electrode 75, the pad plug electrodes 76, and the substrate plug electrodes 77 are formed of the same conductive material as the low-potential coil 22 and the like. That is, preferably, like the low-potential coil 22 and the like, the through wiring 71, the low-potential connection wiring 72, the lead wiring 73, the first connection plug electrode 74, the second connection plug electrode 75, the pad plug electrodes 76, and the substrate plug electrodes 77 each include a barrier layer and a body layer.

The through wiring 71 penetrates a plurality of interlayer insulation layers 57 in the insulation layer 51 and extends in a columnar shape along the normal direction Z. In the embodiment, the through wiring 71 is formed in a region between the bottom and top insulation layers 55 and 56 in the insulation layer 51. The through wiring 71 has a top end part at the top insulation layer 56 side and a bottom end part at the bottom insulation layer 55 side. The top end part of the through wiring 71 is formed in the same interlayer insulation layer 57 as the high-potential coil 23 and is covered by the top insulation layer 56. The bottom end part of the through wiring 71 is formed in the same interlayer insulation layer 57 as the low-potential coil 22.

In the embodiment, the through wiring 71 includes a first electrode layer 78, a second electrode layer 79, and a plurality of wiring plug electrodes 80. In the through wiring 71, the first and second electrode layers 78 and 79 and the wiring plug electrodes 80 are formed of the same conductive material as the low-potential coil 22 and the like. That is, like the low-potential coil 22 and the like, the first and second electrode layers 78 and 79 and the wiring plug electrodes 80 each include a barrier layer and a body layer.

The first electrode layer 78 constitutes the top end part of the through wiring 71. The second electrode layer 79 constitutes the bottom end part of the through wiring 71. The first electrode layer 78 is formed as an island, and faces the low-potential terminal 11 (first low-potential terminal 11A) in the normal direction Z. The second electrode layer 79 is formed as an island, and faces the first electrode layer 78 in the normal direction Z.

The plurality of wiring plug electrodes 80 are embedded respectively in the plurality of interlayer insulation layers 57 located in a region between the first and second electrode layers 78 and 79. The plurality of wiring plug electrodes 80 are stacked together from the bottom insulation layer 55 to the top insulation layer 56 so as to be electrically connected together, and electrically connect together the first and second electrode layers 78 and 79. The plurality of wiring plug electrodes 80 each have a plane area smaller than the plane area of either of the first and second electrode layers 78 and 79.

The number of layers stacked in the plurality of wiring plug electrodes 80 is equal to the number of layers stacked in the plurality of interlayer insulation layers 57. In the embodiment, six wiring plug electrodes 80 are embedded in interlayer insulation layers 57 respectively, and any number of wiring plug electrodes 80 can be embedded in interlayer insulation layers 57 respectively. Needless to say, one or a plurality of wiring plug electrodes 80 can be formed that penetrates a plurality of interlayer insulation layers 57.

The low-potential connection wiring 72 is formed in the same interlayer insulation layer 57 as the low-potential coil 22, in the first inner region 66 in the first transformer 21A (low-potential coil 22). The low-potential connection wiring 72 is formed as an island and faces the high-potential terminal 12 (first high-potential terminal 12A) in the normal direction Z. Preferably, the low-potential connection wiring 72 has a plane area larger than the plane area of the wiring plug electrode 80. The low-potential connection wiring 72 is electrically connected to the first inner end 24 of the low-potential coil 22.

The lead wiring 73 is formed in the interlayer insulation layer 57, in a region between the semiconductor chip 41 and the through wiring 71. In the embodiment, the lead wiring 73 is formed in the first interlayer insulation layer 57 as counted from the bottom insulation layer 55. The lead wiring 73 has a first end part at one side, a second end part at the other side, and a wiring part that connects together the first and second end parts. The first end part of the lead wiring 73 is located in a region between the semiconductor chip 41 and the bottom end part of the through wiring 71. The second end part of the lead wiring 73 is located in a region between the semiconductor chip 41 and the low-potential connection wiring 72. The wiring part extends along the first principal surface 42 of the semiconductor chip 41 and extends in the shape of a stripe in a region between the first and second end parts.

The first connection plug electrode 74 is formed in the interlayer insulation layer 57, in a region between the through wiring 71 and the lead wiring 73, and is electrically connected to the through wiring 71 and to the first end part of the lead wiring 73. The second connection plug electrode 75 is formed in the interlayer insulation layer 57, in a region between the low-potential connection wiring 72 and the lead wiring 73 and is electrically connected to the low-potential connection wiring 72 and to the second end part of the lead wiring 73.

The plurality of pad plug electrodes 76 are formed in the top insulation layer 56, in a region between the low-potential terminal 11 (first low-potential terminal 11A) and the through wiring 71 and are electrically connected to the low-potential terminal 11 and to the top end part of the through wiring 71. The plurality of substrate plug electrodes 77 are formed in the bottom insulation layer 55, in a region between the semiconductor chip 41 and the lead wiring 73. In the embodiment, the substrate plug electrodes 77 are formed in a region between the semiconductor chip 41 and the first end part of the lead wiring 73 and are electrically connected to the semiconductor chip 41 and to the first end part of the lead wiring 73.

Referring to FIG. 6 and FIG. 7, the plurality of first high-potential wirings 33 are connected respectively to the corresponding high-potential terminals 12A to 12D and to the second inner ends 27 of the corresponding transformers 21A to 21D (high-potential coils 23). The plurality of first high-potential wirings 33 have similar structures. In the following description, the structure of the first high-potential wiring 33 connected to the first high-potential terminal 12A and to the first transformer 21A will be described as an example. No description will be given of the structures of the other first high-potential wirings 33, to which the description of the structure of the first high-potential wiring 33 connected to the first transformer 21A is to be taken to apply.

The first high-potential wiring 33 includes a high-potential connection wiring 81 and one or a plurality of (in this embodiment, a plurality of) pad plug electrodes 82. Preferably, the high-potential connection wiring 81 and the pad plug electrodes 82 are formed of the same conductive material as the low-potential coil 22 and the like. That is, preferably, like the low-potential coil 22 and the like, the high-potential connection wiring 81 and the pad plug electrodes 82 each include a barrier layer and a body layer.

The high-potential connection wiring 81 is formed in the same interlayer insulation layer 57 as the high-potential coil 23, in the second inner region 67 in the high-potential coil 23. The high-potential connection wiring 81 is formed as an island, and faces the high-potential terminal 12 (first high-potential terminal 12A) in the normal direction Z. The high-potential connection wiring 81 is electrically connected to the second inner end 27 of the high-potential coil 23. The high-potential connection wiring 81 is formed at an interval from the low-potential connection wiring 72 as seen in a plan view, and does not face the low-potential connection wiring 72 in the normal direction Z. This results in an increased insulation distance between the low- and high-potential connection wirings 72 and 81 and hence an increased dielectric strength voltage in the insulation layer 51.

The plurality of pad plug electrodes 82 are formed in the top insulation layer 56, in a region between the high-potential terminal 12 (first high-potential terminal 12A) and the high-potential connection wiring 81 and are electrically connected to the high-potential terminal 12 and to the high-potential connection wiring 81. The plurality of pad plug electrodes 82 each have a plane area smaller than the plane area of the high-potential connection wiring 81 as seen in a plan view.

Referring to FIG. 7, preferably, the distance D1 between the low- and high-potential terminals 11 and 12 is larger than the distance D2 between the low- and high-potential coils 22 and 23 (D2<D1). Preferably, the distance D1 is larger than the total thickness DT of the plurality of interlayer insulation layers 57 (DT<D1). The ratio D2/D1 of the distance D2 to the distance D1 can be 0.01 or more but 0.1 or less. Preferably, the distance D1 is 100 μm or more but 500 μm or less. The distance D2 can be 1 μm or more but 50 μm or less. Preferably, the distance D2 is 5 μm or more but 25 μm or less. The distances D1 and D2 can have any values, which are adjusted appropriately according to the desired dielectric strength voltage.

Referring to FIG. 6 and FIG. 7, the semiconductor device 5 has a dummy pattern 85 that is embedded in the insulation layer 51 so as to be located around the transformers 21A to 21D as seen in a plan view.

The dummy pattern 85 is formed in a pattern different (discontinuous) from that of either of the high- and low-potential coils 23 and 22 and is independent of the transformers 21A to 21D. That is, the dummy pattern 85 does not function as part of the transformers 21A to 21D. The dummy pattern 85 is formed as a shield conductor layer that shields electric fields between the low- and high-potential coils 22 and 23 in the transformers 21A to 21D to suppress electric field concentration on the high-potential coil 23. In the embodiment, the dummy pattern 85 is patterned at a line density per unit area that is equal to the line density of the high-potential coil 23. The line density of the dummy pattern 85 being equal to the line density of the high-potential coil 23 means that the line density of the dummy pattern 85 falls within the range of ±20% of the line density of the high-potential coil 23.

The dummy pattern 85 can be formed at any depth in the insulation layer 51, which is adjusted according to the electric field strength to be attenuated. Preferably, the dummy pattern 85 is formed in a region closer to the high-potential coil 23 than to the low-potential coil 22 with respect to the normal direction Z. The dummy pattern 85 being closer to the high-potential coil 23 with respect to the normal direction Z means that, with respect to the normal direction Z, the distance between the dummy pattern 85 and the high-potential coil 23 is smaller than the distance between the dummy pattern 85 and the low-potential coil 22.

In that way, electric field concentration on the high-potential coil 23 can be suppressed properly. The smaller the distance between the dummy pattern 85 and the high-potential coil 23 with respect to the normal direction Z, the more effectively electric field concentration on the high-potential coil 23 can be suppressed. Preferably, the dummy pattern 85 is formed in the same interlayer insulation layer 57 as the high-potential coil 23. In that way, electric field concentration on the high-potential coil 23 can be suppressed more properly. The dummy pattern 85 includes a plurality of dummy patterns that are in varying electrical states. The dummy pattern 85 can include a high-potential dummy pattern.

The high-potential dummy pattern 86 can be formed at any depth in the insulation layer 51, which is adjusted according to the electric field strength to be attenuated. Preferably, the high-potential dummy pattern 86 is formed in a region closer to the high-potential coil 23 than to the low-potential coil 22 with respect to the normal direction Z. The high-potential dummy pattern 86 being closer to the high-potential coil 23 with respect to the normal direction Z means that, with respect to the normal direction Z, the distance between the high-potential dummy pattern 86 and the high-potential coil 23 is smaller than the distance between the high-potential dummy pattern 86 and the low-potential coil 22.

The dummy pattern 85 includes a floating dummy pattern that is formed in an electrically floating state in the insulation layer 51 so as to be located around the transformers 21A to 21D.

In the embodiment, the floating dummy pattern is patterned in dense lines so as to partly cover and partly expose a region around the high-potential coil 23 as seen in a plan view. The floating dummy pattern can be formed so as to have ends or no ends.

The floating dummy pattern can be formed at any depth in the insulation layer 51, which is adjusted according to the electric field strength to be attenuated.

Any number of floating lines can be provided, which is adjusted according to the electric field strength to be attenuated. The floating dummy pattern can include a plurality of floating dummy patterns.

Referring to FIG. 7, the semiconductor device 5 includes a second functional device 60 that is formed in the first principal surface 42 of the semiconductor chip 41 in a device region 62. The second functional device 60 is formed using a superficial part of the first principal surface 42 and/or a region on the first principal surface 42 of the semiconductor chip 41 and is covered by the insulation layer 51 (bottom insulation layer 55). In FIG. 7, the second functional device 60 is shown in a simplified form by broken lines indicated in a superficial part of the first principal surface 42.

The second functional device 60 is electrically connected to a low-potential terminal 11 via a low-potential wiring and is electrically connected to a high-potential terminal 12 via a high-potential wiring. Except that the low-potential wiring is patterned in the insulation layer 51 so as to be connected to the second functional device 60, it has a similar structure to the first low-potential wiring 31 (second low-potential wiring 32). Except that the high-potential wiring is patterned in the insulation layer 51 so as to be connected to the second functional device 60, it has a similar structure to the first high-potential wiring 33 (second high-potential wiring 34). No description will be given of the low- and high-potential wirings associated with the second functional device 60.

The second functional device 60 can include at least one of a passive device, a semiconductor rectification device, and a semiconductor switching device. The second functional device 60 can include a circuit network comprising a selective combination of any two or more of a passive device, a semiconductor rectification device, and a semiconductor switching device. The circuit network can constitute part or the whole of an integrated circuit.

The passive device can include a semiconductor passive device. The passive device can include one or both of a resistor and a capacitor. The semiconductor rectification device can include at least one of a pn-junction diode, a PIN diode, a Zener diode, a Schottky barrier diode, and a fast-recovery diode. The semiconductor switching device can include at least one of a BJT (bipolar junction transistor), a MISFET (metal-insulator-semiconductor field-effect transistor), an IGBT (insulated-gate bipolar junction transistor), and a JFET (junction field-effect transistor).

Referring to FIG. 5 to FIG. 7, the semiconductor device 5 further includes a scaling conductor 61 embedded in the insulation layer 51. The sealing conductor 61 is embedded in the form of walls in the insulation layer 51, at intervals from the insulation side walls 53A to 53D as seen in a plan view and partitions the insulation layer 51 into the device region 62 and an outer region 63. The sealing conductor 61 prevents moisture entry and crack development from the outer region 63 to the device region 62.

The device region 62 is a region that includes the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. The outer region 63 is a region outside the device region 62.

The sealing conductor 61 is electrically isolated from the device region 62. Specifically, the sealing conductor 61 is electrically isolated from the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. More specifically, the sealing conductor 61 is held in an electrically floating state. The sealing conductor 61 does not form a current path connected to the device region 62.

The sealing conductor 61 is formed in the shape of a stripe along the insulation side walls 53A to 53D as seen in a plan view. In the embodiment, the sealing conductor 61 is formed in a quadrangular ring shape (specifically, a rectangular ring shape) as seen in a plan view. Thus, the sealing conductor 61 defines the device region 62 in a quadrangular shape (specifically, a rectangular shape) as seen in a plan view. Furthermore, the sealing conductor 61 defines the outer region 63 in a quadrangular ring shape (specifically, a rectangular ring shape) surrounding the device region 62 as seen in a plan view.

Specifically, the sealing conductor 61 has a top end part at the insulation principal surface 52 side, a bottom end part at the semiconductor chip 41 side, and a wall part that extends in the form of walls between the top and bottom end parts. In the embodiment, the top end part of the sealing conductor 61 is formed at an interval from the insulation principal surface 52 toward the semiconductor chip 41 and is located in the insulation layer 51. In the embodiment, the top end part of the sealing conductor 61 is covered by the top insulation layer 56. The top end part of the sealing conductor 61 can be covered by one or a plurality of interlayer insulation layers 57. The top end part of the sealing conductor 61 can be exposed through the top insulation layer 56. The bottom end part of the sealing conductor 61 is formed at an interval from the semiconductor chip 41 toward the top end part.

Thus, in the embodiment, the sealing conductor 61 is embedded in the insulation layer 51 so as to be located at the semiconductor chip 41 side of the plurality of low-potential terminals 11 and the plurality of high-potential terminals 12. Moreover, in the insulation layer 51, the sealing conductor 61 faces, in the direction parallel to the insulation principal surface 52, the first functional device 45 (plurality of transformers 21), the first low-potential wirings 31, the second low-potential wirings 32, the first high-potential wirings 33, the second high-potential wirings 34, and the dummy pattern 85. In the insulation layer 51, the sealing conductor 61 can face, in the direction parallel to the insulation principal surface 52, part of the second functional device 60.

The sealing conductor 61 includes a plurality of sealing plug conductors 64 and one or a plurality of (in the embodiment, a plurality of) sealing via conductors 65. Any number of scaling via conductors 65 may be provided. Of the plurality of sealing plug conductors 64, the top sealing plug conductor 64 constitutes the top end part of the sealing conductor 61. The plurality of sealing via conductors 65 constitute the bottom end part of the scaling conductor 61. Preferably, the sealing plug conductors 64 and the sealing via conductors 65 are formed of the same conductive material as the low-potential coil 22. That is, preferably, like the low-potential coil 22 and the like, the sealing plug conductors 64 and the sealing via conductors 65 each include a barrier layer and a body layer.

The plurality of sealing plug conductors 64 are embedded in the plurality of interlayer insulation layers 57 respectively and are each formed in a quadrangular ring shape (specifically, a rectangular ring shape) surrounding the device region 62. The plurality of scaling plug conductors 64 are stacked together from the bottom insulation layer 55 to the top insulation layer 56 so as to be connected together. The number of layers stacked in the plurality of sealing plug conductors 64 is equal to the number of layers in the plurality of interlayer insulation layers 57. Needless to say, one or a plurality of scaling plug conductors 64 may be formed that penetrates a plurality of interlayer insulation layers 57.

So long as a set of a plurality of sealing plug conductors 64 constitutes one ring-shaped sealing conductor 61, not all the sealing plug conductors 64 need be formed in a ring shape. For example, at least one of the plurality of sealing plug conductors 64 can be formed so as to have ends. Or at least one of the plurality of sealing plug conductors 64 may be divided into a plurality of strip-shaped portions with ends. However, with consideration given to the risk of moisture entry and crack development into the device region 62, preferably, the plurality of sealing plug conductors 64 are formed so as to have no ends (in a ring shape).

The plurality of sealing via conductors 65 are formed in the bottom insulation layer 55, in a region between the semiconductor chip 41 and the sealing plug conductors 64. The plurality of sealing via conductors 65 are formed at an interval from the semiconductor chip 41 and are connected to the sealing plug conductors 64. The plurality of scaling via conductors 65 have a plane area smaller than the plane area of the sealing plug conductors 64. In a case where a single sealing via conductor 65 is formed, the single scaling via conductors 65 can have a plane area equal to or larger than the plane area of the scaling plug conductors 64.

The sealing conductor 61 can have a width of 0.1 μm or more but 10 μm or less. Preferably, the sealing conductor 61 has a width of 1 μm or more but 5 μm or less. The width of the sealing conductor 61 is defined by its width in the direction orthogonal to the direction in which it extends.

Referring to FIG. 7 and FIG. 8, the semiconductor device 5 further includes the separation structure 130 that is interposed between the semiconductor chip 41 and the sealing conductor 61 and that electrically isolates the sealing conductor 61 from the semiconductor chip 41. Preferably, the separation structure 130 includes an insulator. In the embodiment, the separation structure 130 is a field insulation film 131 formed on the first principal surface 42 of the semiconductor chip 41.

The field insulation film 131 includes at least one of an oxide film (silicon oxide film) and a nitride film (silicon nitride film). Preferably, the field insulation film 131 is a LOCOS (local oxidation of silicon) film as one example of an oxide film that is formed through oxidation of the first principal surface 42 of the semiconductor chip 41. The field insulation film 131 can have any thickness so long as it can insulate between the semiconductor chip 41 and the sealing conductor 61. The field insulation film 131 can have a thickness of 0.1 μm or more but 5 μm or less.

The separation structure 130 is formed on the first principal surface 42 of the semiconductor chip 41 and extends in the shape of a stripe along the scaling conductor 61 as seen in a plan view. In the embodiment, the separation structure 130 is formed in a quadrangular ring shape (specifically, a rectangular ring shape) as seen in a plan view. The separation structure 130 has a connection portion 132 to which the bottom end part of the sealing conductor 61 (i.e., the sealing via conductors 65) is connected. The connection portion 132 can form an anchor portion into which the bottom end part of the sealing conductor 61 (i.e., the sealing via conductors 65) is anchored toward the semiconductor chip 41. Needless to say, the connection portion 132 can be formed to be flush with the principal surface of the separation structure 130.

The separation structure 130 includes an inner end part 130A at the device region 62 side, an outer end part 130B at the outer region 63 side, and a main body part 130C between the inner and outer end parts 130A and 130B. As seen in a plan view, the inner end part 130A defines the region where the second functional device 60 is formed (i.e., the device region 62). The inner end part 130A can be formed integrally with an insulation film (not illustrated) formed on the first principal surface 42 of the semiconductor chip 41.

The outer end part 130B is exposed on the chip side walls 44A to 44D of the semiconductor chip 41 and is continuous with the chip side walls 44A to 44D of the semiconductor chip 41. More specifically, the outer end part 130B is formed so as to be flush with the chip side walls 44A to 44D of the semiconductor chip 41. The outer end part 130B constitutes a polished surface between, to be flush with, the chip side walls 44A to 44D of the semiconductor chip 41 and the insulation side walls 53A to 53D of the insulation layer 51. Needless to say, an embodiment is also possible where the outer end part 130B is formed within the first principal surface 42 at intervals from the chip side walls 44A to 44D.

The main body part 130C has a flat surface that extends substantially parallel to the first principal surface 42 of the semiconductor chip 41. The main body part 130C has the connection portion 132 to which the bottom end part of the sealing conductor 61 (i.e., the sealing via conductors 65) is connected. The connection portion 132 is formed in the main body part 130C, at intervals from the inner and outer end parts 130A and 130B. The separation structure 130 can be implemented in many ways other than in the form of a field insulation film 131.

Referring to FIG. 7, the semiconductor device 5 further includes an inorganic insulation layer 140 formed on the insulation principal surface 52 of the insulation layer 51 so as to cover the sealing conductor 61. The inorganic insulation layer 140 can be called a passivation layer. The inorganic insulation layer 140 protects the insulation layer 51 and the semiconductor chip 41 from above the insulation principal surface 52.

In the embodiment, the inorganic insulation layer 140 has a stacked structure composed of a first inorganic insulation layer 141 and a second inorganic insulation layer 142. The first inorganic insulation layer 141 can contain silicon oxide. Preferably, the first inorganic insulation layer 141 contains USG (undoped silicate glass), which is undoped silicon oxide. The first inorganic insulation layer 141 can have a thickness of 50 nm or more but 5000 nm or less. The second inorganic insulation layer 142 can contain silicon nitride. The second inorganic insulation layer 142 can have a thickness of 500 nm or more but 5000 nm or less. Increasing the total thickness of the inorganic insulation layer 140 helps increase the dielectric strength voltage above the high-potential coils 23.

In a configuration where the first inorganic insulation layer 141 is made of USG and the second inorganic insulation layer 142 is made of silicon nitride, USG has the higher dielectric breakdown voltage (V/cm) than silicon nitride. In view of this, when thickening the inorganic insulation layer 140, it is preferable to form the first inorganic insulation layer 141 thicker than the second inorganic insulation layer 142.

The first inorganic insulation layer 141 can contain at least one of BPSG (boron-doped phosphor silicate glass) and PSG (phosphorus silicate glass) as examples of silicon oxide. In that case, however, since the silicon oxide contains a dopant (boron or phosphorus), for an increased dielectric strength voltage above the high-potential coils 23, it is particularly preferable to form the first inorganic insulation layer 141 of USG. Needless to say, the inorganic insulation layer 140 can have a single-layer structure composed of either the first or second inorganic insulation layer 141 or 142.

The inorganic insulation layer 140 covers the entire area of the sealing conductor 61, and has a plurality of low-potential pad openings 143 and a plurality of high-potential pad openings 144 that are formed in a region outside the sealing conductor 61. The plurality of low-potential pad openings 143 expose the plurality of low-potential terminals 11 respectively. The plurality of high-potential pad openings 144 expose the plurality of high-potential terminals 12 respectively. The inorganic insulation layer 140 can have overlap parts that overlap circumferential edge parts of the low-potential terminals 11. The inorganic insulation layer 140 can have overlap parts that overlap circumferential edge parts of the high-potential terminals 12.

The semiconductor device 5 further includes an organic insulation layer 145 that is formed on the inorganic insulation layer 140. The organic insulation layer 145 can contain photosensitive resin. The organic insulation layer 145 can contain at least one of polyimide, polyamide, and polybenzoxazole. In the embodiment, the organic insulation layer 145 contains polyimide. The organic insulation layer 145 can have a thickness of 1 μm or more but 50 μm or less.

Preferably, the organic insulation layer 145 has a thickness larger than the total thickness of the inorganic insulation layer 140. Moreover, preferably, the inorganic and organic insulation layers 140 and 145 together have a total thickness larger than the distance D2 between the low- and high-potential coils 22 and 23. In that case, preferably, the inorganic insulation layer 140 has a total thickness of 2 μm or more but 10 μm or less. Preferably, the organic insulation layer 145 has a thickness of 5 μm or more but 50 μm or less. Such structures help suppress an increase in the thicknesses of the inorganic and organic insulation layers 140 and 145 while appropriately increasing the dielectric strength voltage above the high-potential coil 23 owing to the stacked film of the inorganic and organic insulation layers 140 and 145.

The organic insulation layer 145 includes a first part 146 that covers a low-potential side region and a second part 147 that covers a high-potential side region. The first part 146 covers the sealing conductor 61 across the inorganic insulation layer 140. The first part 146 has a plurality of low-potential terminal openings 148 through which the plurality of low-potential terminals 11 (low-potential pad openings 143) are respectively exposed in a region outside the sealing conductor 61. The first part 146 can have overlap parts that overlap circumferential edges (overlap parts) of the low-potential pad openings 143.

The second part 147 is formed at an interval from the first part 146, and exposes the inorganic insulation layer 140 between the first and second parts 146 and 147. The second part 147 has a plurality of high-potential terminal openings 149 through which the plurality of high-potential terminals 12 (high-potential pad openings 144) are respectively exposed. The second part 147 can have overlap parts that overlap circumferential edges (overlap parts) of the high-potential pad openings 144.

The second part 147 covers the transformers 21A to 21D and the dummy pattern 85 together. Specifically, the second part 147 covers the plurality of high-potential coils 23, the plurality of high-potential terminals 12, a first high-potential dummy pattern 87, a second high-potential dummy pattern 88, and a floating dummy pattern 121 together.

The present disclosure can be implemented in any other embodiments. The embodiment described above deals with an example where a first functional device 45 and a second functional device 60 are formed. An embodiment is however also possible that only has a second functional device 60, with no first functional device 45. In that case, the dummy pattern 85 may be omitted. This structure provides, with respect to the second functional device 60, effects similar to those mentioned in connection with the first embodiment (except those associated with the dummy pattern 85).

That is, in a case where a voltage is applied to the second functional device 60 via the low- and high-potential terminals 11 and 12, it is possible to suppress unnecessary conduction between the high-potential terminal 12 and the sealing conductor 61. Likewise, in a case where a voltage is applied to the second functional device 60 via the low- and high-potential terminals 11 and 12, it is possible to suppress unnecessary conduction between the low-potential terminal 11 and the scaling conductor 61.

The embodiment described above deals with an example where a second functional device 60 is formed. The second functional device 60, however, is not essential and can be omitted.

The embodiment described above deals with an example where a dummy pattern 85 is formed. The dummy pattern 85 however is not essential and can be omitted.

The embodiment described above deals with an example where the first functional device 45 is of a multichannel type that includes a plurality of transformers 21. It is however also possible to employ a single-channel first functional device 45 that includes a single transformer 21.

### <Transformer Layout>

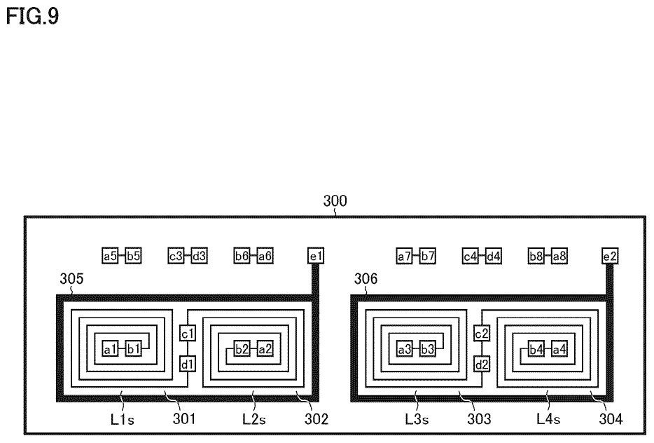

FIG. 9 is a plan view (top view) schematically showing one example of transformer layout in a two-channel transformer chip 300 (corresponding to the semiconductor device 5 described previously). The transformer chip 300 shown there includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one terminal of the secondary coil L1s of the first transformer 301, and the pads c1 and d1 are connected to the other terminal of that secondary coil L1s. The pads a2 and b2 are connected to one terminal of the secondary coil L2s of the second transformer 302, and the pads c1 and d1 are connected to the other terminal of that secondary coil L2s.

Moreover, the pads a3 and b3 are connected to one terminal of the secondary coil L3s of the third transformer 303, and the pads c2 and d2 are connected to the other terminal of that secondary coil L3s. The pads a4 and b4 are connected to one terminal of the secondary coil LAs of the fourth transformer 304, and the pads c2 and d2 are connected to the other terminal of that secondary coil L4s.

FIG. 9 does not show any of the primary coils of the first, second, third, and fourth transformers 301, 302, 303, and 304. The primary coils basically have structures similar to those of the secondary coils L1s to L4s respectively and are disposed right below the secondary coils L1s to L4s, respectively, so as to face them.

Specifically, the pads a5 and b5 are connected to one terminal of the primary coil of the first transformer 301, and the pads c3 and d3 are connected to the other terminal of that primary coil. Likewise, the pads a6 and b6 are connected to one terminal of the primary coil of the second transformer 302, and the pads c3 and d3 are connected to the other terminal of that primary coil.

Likewise, the pads a7 and b7 are connected to one terminal of the primary coil of the third transformer 303, and the pads c4 and d4 are connected to the other terminal of that primary coil. Likewise, the pads a8 and b8 are connected to one terminal of the primary coil of the fourth transformer 304, and the pads c4 and d4 are connected to the other terminal of that primary coil.

The pads a5 to a8, the pads b5 to b8, the pads c3 and c4, and the pads d3 and d4 mentioned above are each led from inside the transformer chip 300 to its surface across an unillustrated via.

Of the plurality of pads mentioned above, the pads a1 to a8 each correspond to a first current feed pad, and the pads b1 to b8 each correspond to a first voltage measurement pad; the pads c1 to c4 each correspond to a second current feed pad, and the pads d1 to d4 each correspond to a second voltage measurement pad.

Thus, the transformer chip 300 of this configuration example permits, during its defect inspection, accurate measurement of the series resistance component across each coil. It is thus possible not only to reject defective products with a broken wire in a coil but also to appropriately reject defective products with an abnormal resistance value in a coil (e.g., a midway short circuit between coils), and hence to prevent defective products from being distributed in the market.

For a transformer chip 300 that has passed the defect inspection mentioned above, the plurality of pads described above can be used for connection with a primary-side chip and a secondary-side chip (e.g., the controller chip 210 and the driver chip 220 described previously).

Specifically, the pads a1 and b1, the pads a2 and b2, the pads a3 and b3, and the pads a4 and b4 can each be connected to one of the signal input and output terminals of the secondary-side chip; the pads c1 and d1 and the pads c2 and d2 can each be connected to a common voltage application terminal (GND2) of the secondary-side chip.

On the other hand, the pads a5 and b5, the pads a6 and b6, the pads a7 and b7, and the pads a8 and b8 can each be connected to one of the signal input and output terminals of the primary-side chip; the pads c3 and d3 and the pads c4 and d4 can each be connected to a common voltage application terminal (GND1) of the primary-side chip.

Here, as shown in FIG. 9, the first to fourth transformers 301 to 304 are so arranged as to be coupled for each signal transmission direction. In terms of what is shown in the diagram, for example, the first and second transformers 301 and 302, which transmit a signal from the primary-side chip to the secondary-side chip, are coupled into a first pair by the first guard ring 305. Likewise, for example, the third and fourth transformers 303 and 304, which transmit a signal from the secondary-side chip to the primary-side chip, are coupled into a second pair by the second guard ring 306.

Such coupling is intended, in a structure where the primary and secondary coils of each of the first to fourth transformers 301 to 304 are formed so as to be stacked on each other in the up-down direction of the substrate of the transformer chip 300, to obtain a desired withstand voltage between the primary and secondary coils. The first and second guard rings 305 and 306 are, however, not essential elements.

The first and second guard rings 305 and 306 can be connected via pads e1 and e2, respectively, to a low-impedance wiring such as a grounded terminal.

In the transformer chip 300, the pads c1 and d1 are shared between the secondary coils L1s and L2s. The pads c2 and d2 are shared between the secondary coils L3s and L4s. The pads c3 and d3 are shared between the primary coils Llp and L2p. The pads c4 and d4 are shared between the primary coils that correspond to them respectively. This configuration helps reduce the number of pads and helps make the transformer chip 300 compact.

Moreover, as shown in FIG. 9, the primary and secondary coils of the first to fourth transformers 301 to 304 are preferably each wound in a rectangular shape (or, with the corners rounded, in a running-track shape) as seen in a plan view of the transformer chip 300. This configuration helps increase the area over which the primary and secondary coils overlap each other and helps enhance the transmission efficiency across the transformers.

Needless to say, the illustrated transformer layout is merely an example; any number of coils of any shape can be disposed in any layout, and pads can be disposed in any layout. Any of the chip structure, transformer layouts, etc. described above can be applied to semiconductor devices in general that have a coil integrated in a semiconductor chip.

### <Investigation of Power Supply>

In signal transmission devices that transmit a signal between a primary circuit system and a secondary circuit system while electrically isolating between them, power is supplied from respective power supplies for the primary circuit system and the secondary circuit system. However, the respective power supplies for the primary circuit system and the secondary circuit system both may not have sufficient current supply capability. In general, the signal transmission side (e.g., the primary circuit system) needs high current for driving isolation devices. Thus, in a case where the power supply for the primary circuit system is unstable or not capable enough, the signal transmission from the primary circuit system to the secondary circuit system can be disturbed.

In the signal transmission device to be utilized, for example, as an isolation comparator, an isolation amplifier, or an isolation ADC [analog-to-digital converter], the primary circuit system can serve as a detection system (the signal transmission side), and the secondary circuit system can serve as a monitoring system and a control system (the signal reception side). In this case, a power supply that is capable of stably supplying high current to the primary circuit system may not be present.

In view of the investigation described above, in the following description, a signal transmission device in which the signal transmission from the primary circuit system to the secondary circuit system is prevented from being disturbed even when the power supply for the primary circuit system is instable or not capable enough is proposed.

### <Signal Transmission Device (First Embodiment)>

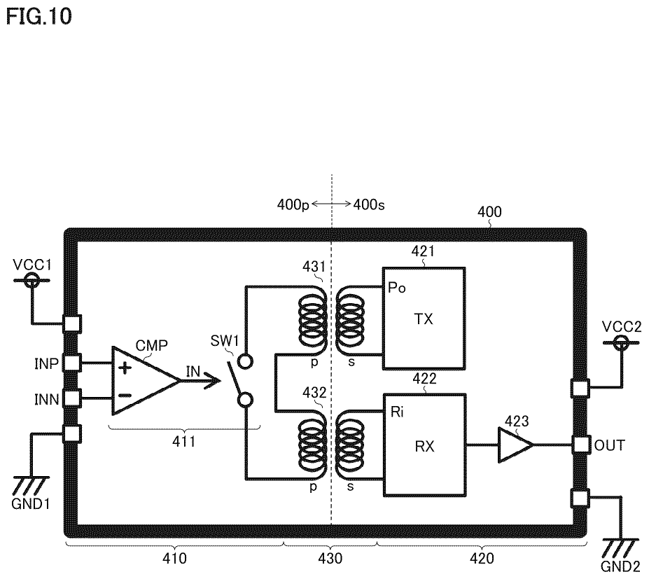

FIG. 10 is a diagram showing a first embodiment of the signal transmission devices. A signal transmission device 400 of this embodiment is a semiconductor integrated circuit device that transmits, while electrically isolating between a primary circuit system 400p (VCC1-GND1 system) and a secondary circuit system 400s (VCC2-GND2 system), the input pulse signal IN of the primary circuit system 400p as the output pulse signal OUT of the secondary circuit system 400s.

The signal transmission device 400 is widely applicable to general applications that need the signal transmission between the primary circuit system 400p and the secondary circuit system 400s while isolating between them (such as the isolation comparator, the isolation amplifier, the isolation ADC, or a motor driver or a DC/DC converter that handles high voltage).

The signal transmission device 400 may include a first chip 410, a second chip 420, and a third chip 430 like the signal transmission device 200 (FIG. 1) described previously. The first chip 410, the second chip 420, and the third chip 430 may be sealed in a single packagc.

A switching circuit 411 that is provided in the primary circuit system 400p is integrated in the first chip 410. The switching circuit 411 operates by being supplied with the supply voltage VCC1 from the power supply (unillustrated) for the primary circuit system 400p.

A drive circuit 421, a reception circuit 422, and a buffer 423 that are provided in the secondary circuit system 400s are integrated in the second chip 420. All these drive circuit 421, reception circuit 422, and buffer 423 operate by being supplied with the supply voltage VCC2 from the power supply (unillustrated) for the secondary circuit system 400s. Note that, the power supply for the secondary circuit system 400s has a capability to stably supply current that is higher than that of the power supply for the primary circuit system 400p.

Isolation devices 431 and 432 that serve as signal transmission paths between the primary circuit system 400p and the secondary circuit system 400s while electrically isolating between them are integrated in the third chip 430. The isolation devices 431 and 432 correspond respectively to a first isolation device and a second isolation device.

The isolation devices 431 and 432 may each be a transformer. That is, the isolation device 431 includes a pair of a primary coil 431p and a secondary coil 431s that can be electromagnetically coupled to each other. Likewise, the isolation device 432 includes a pair of a primary coil 432p and a secondary coil 432s that can be electromagnetically coupled to each other.

The switching circuit 411 switches a state of connection between the isolation device 431 and the isolation device 432 according to a positive-phase input pulse signal INP and a negative-phase input pulse signal INN that are differentially input from the outside of the signal transmission device 400. In terms of what is shown in the diagram, the switching circuit 411 includes a comparator CMP and a switching device SW1 (e.g., an analog switch).

The comparator CMP outputs the input pulse signal IN by comparing the positive-phase input pulse signal INP to be input to a non-inverting input terminal (+) and the negative-phase input pulse signal INN to be input to the inverting input terminal (−) with each other. The input pulse signal IN is at high level under a state in which INP>INN has been established. On the other hand, the input pulse signal IN is at low level under a state in which INP<INN has been established. The logic level of the positive-phase input pulse signal INP and the logic level of the negative-phase input pulse signal INN are inverted to each other.

The first terminal of the switching device SW1 is connected to the first terminal of the primary coil 431p that forms the isolation device 431. The second terminal of the switching device SW1 is connected to the first terminal of the primary coil 432p that forms the isolation device 432. The respective second terminals of the primary coils 431p and 432p are connected to each other. In this way, the switching device SW1 is connected in series between the primary coil 431p of the isolation device 431 and the primary coil 432p of the isolation device 432. That is, the switching device SW1 is connected to form a closed loop cooperatively with the respective primary coils 431p and 432p of the isolation devices 431 and 432.

The switching device SW1 is turned on, for example, under the state in which the input pulse signal IN is at high level. At this time, conduction between the primary coil 431p of the isolation device 431 and the primary coil 432p of the isolation device 432 is established. On the other hand, the switching device SW1 is turned off, for example, under the state in which the input pulse signal IN is at low level. At this time, the conduction between the primary coil 431p of the isolation device 431 and the primary coil 432p of the isolation device 432 is cut off.

The drive circuit 421 cyclically or continuously pulse-drives a first signal Po to be applied to the secondary coil 431s of the isolation device 431 (details will be given later).

The reception circuit 422 detects a second signal Ri to be output from the isolation device 432, and generates the output pulse signal OUT according to the input pulse signal IN.

The buffer 423 performs waveform shaping on the output pulse signal OUT, and outputs the output pulse signal OUT to the outside of the signal transmission device 400.

The isolation device 431 transmits the single-phase first signal Po from the secondary circuit system 400s to the primary circuit system 400p. The isolation device 431 functions as an inquiring isolation device.

The isolation device 432 transmits the single-phase second signal Ri from the primary circuit system 400p to the secondary circuit system 400s. The isolation device 432 functions as a responding isolation device.

### Description of Operation (First Embodiment)

Under the state in which the input pulse signal IN is at high level, the switching device SW1 is turned on. Thus, the conduction between the primary coil 431p of the isolation device 431 and the primary coil 432p of the isolation device 432 is established. Therefore, in response to the driving of the first signal Po to be applied to the secondary coil 431s of the isolation device 431, the first signal Po is generated in the primary coil 431p of the isolation device 431 (more strictly, induced signal according to the first signal Po). As a result, the primary coil 432p of the isolation device 432 is driven according to the first signal Po that is generated in the primary coil 431p of the isolation device 431. At this time, the second signal Ri (corresponding to the induced signal according to the first signal Po) is generated in the secondary coil 432s of the isolation device 432.

That is, under the state in which the input pulse signal IN is at high level, the switching circuit 411 switches the state of the connection between the isolation device 431 and the isolation device 432 to a first connection state in which the isolation device 432 is driven according to the first signal Po.

On the other hand, under the state in which the input pulse signal IN is at low level, the switching device SW1 is turned off. Thus, the conduction between the primary coil 431p of the isolation device 431 and the primary coil 432p of the isolation device 432 is cut off. Therefore, even in response to the driving of the first signal Po to be applied to the secondary coil 431s of the isolation device 431, the first signal Po is not generated in the primary coil 431p of the isolation device 431 (more strictly, the induced signal according to the first signal Po). As a result, the primary coil 432p of the isolation device 432 is not driven, and hence the second signal Ri (corresponding to the induced signal according to the first signal Po) is not generated in the secondary coil 432s of the isolation device 432.

That is, under the state in which the input pulse signal IN is at low level, the switching circuit 411 switches the state of the connection between the isolation device 431 and the isolation device 432 to a second connection state in which the isolation device 432 is not driven according to the first signal Po.

The reception circuit 422 is capable of distinguishing the logic level of the input pulse signal IN by detecting whether or not the second signal Ri has been generated in the secondary coil 432s of the isolation device 432. For example, the reception circuit 422 sets the output pulse signal OUT to high level by determining that the input pulse signal IN is at high level in response to reception of the second signal Ri. On the other hand, the reception circuit 422 sets the output pulse signal OUT to low level by determining that the input pulse signal IN is at low level in response to absence of the reception of the second signal Ri.

In this way, the signal transmission device 400 according to this embodiment employs a reflection-type isolation communication method in which the primary circuit system 400p responds to an inquiry from the secondary circuit system 400s. Thus, the primary circuit system 400p can drive the primary coil 432p of the isolation device 432 only by performing the switching control according to the input pulse signal IN. Thus, even when the power supply (unillustrated) for the primary circuit system 400p is unstable or not capable enough, the signal transmission from the primary circuit system 400p to the secondary circuit system 400s is prevented from being disturbed.

Note that, in the signal transmission device 400 of this embodiment, the drive circuit 421 that drives the first signal Po and the reception circuit 422 that receives the second signal Ri both operate by being supplied with power from a common power supply (corresponding to the power supply for the secondary circuit system 400s). Moreover, the drive circuit 421 and the reception circuit 422 are both integrated in the common second chip 420. Thus, the signal transmission device 400 of this embodiment can perform stable signal transmission without requiring margin design that takes into account various combinations of the supply voltages VCC1 and VCC2 which are different from each other. Moreover, a reception sensitivity of the second signal Ri may be adjusted according to transmission intensity of the first signal Po.

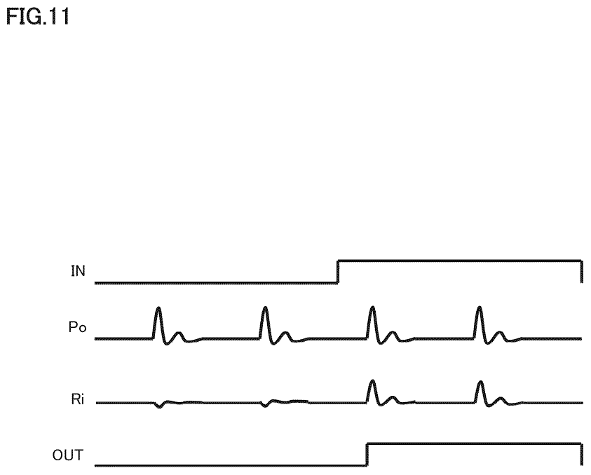

FIG. 11 is a chart showing a first operation example (intermittent) of the first embodiment. Sequentially from the top of the chart, the input pulse signal IN, the first signal Po, the second signal Ri, and the output pulse signal OUT are shown.

As shown in the chart, the drive circuit 421 may cyclically drive (e.g., pulse-drive) the first signal Po to be input to the secondary coil 431s of the isolation device 431. Under the state in which the input pulse signal IN is at high level, induced pulses are generated in the second signal Ri by the pulse-driving of the first signal Po. Thus, the reception circuit 422 sets the output pulse signal OUT to high level in response to detection of the induced pulses of the second signal Ri. On the other hand, under the state in which the input pulse signal IN is at low level, the induced pulses are not generated in the second signal Ri even when the first signal Po is pulse-driven. Thus, the reception circuit 422 sets the output pulse signal OUT to low level in response to absence of the detection of the induced pulses of the second signal Ri.

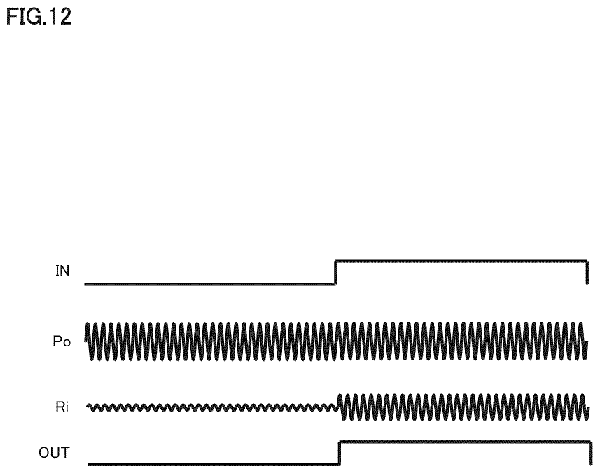

FIG. 12 is a chart showing a second operation example (continuous) of the first embodiment. As in FIG. 11 referred to previously, sequentially from the top of the chart, the input pulse signal IN, the first signal Po, the second signal Ri, and the output pulse signal OUT are shown.

As shown in the chart, the drive circuit 421 may continuously drive (e.g., sinusoidally drive) the first signal Po to be input to the secondary coil 431s of the isolation device 431. Under the state in which the input pulse signal IN is at high level, a sine wave is induced also in the second signal Ri by the sinusoidal driving of the first signal Po. Thus, the reception circuit 422 sets the output pulse signal OUT to high level in response to detection of the sine wave of the second signal Ri. On the other hand, under the state in which the input pulse signal IN is at low level, the sine wave is not induced in the second signal Ri even when the first signal Po is sinusoidally driven. Thus, the reception circuit 422 sets the output pulse signal OUT to low level in response to absence of the detection of the sine wave of the second signal Ri.

### <Signal Transmission Device (Second Embodiment)>

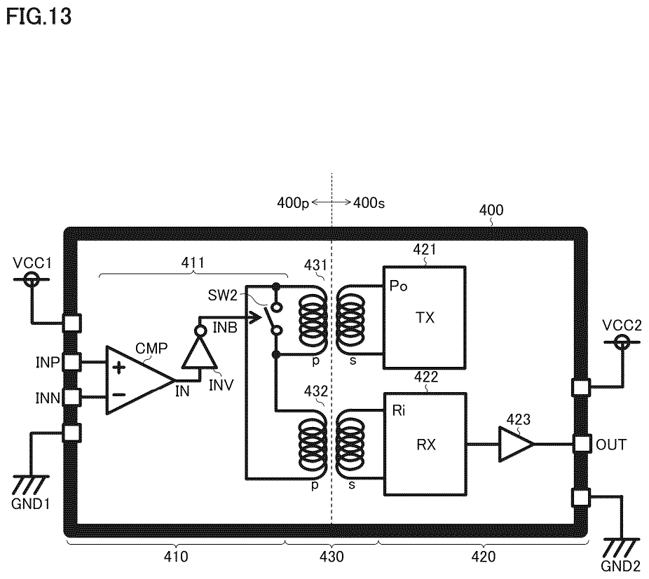

FIG. 13 is a diagram showing a second embodiment of the signal transmission devices. The signal transmission device 400 of this embodiment is basically the same as that of the first embodiment (FIG. 10) described previously except that the configuration of the switching circuit 411 is varied. In terms of what is shown in the diagram, the switching circuit 411 includes an inverter INV and a switching device SW2 in place of the switching device SW1 described previously.

The first terminal of the switching device SW2 is connected to the first terminal of the primary coil 431p. The second terminal of the switching device SW2 is connected to the second terminal of the primary coil 431p. In this way, the switching device SW2 may be connected in parallel to the primary coil 431p. Note that, the respective first terminals of the primary coils 431p and 432p are connected to each other. Likewise, the respective second terminals of the primary coils 431p and 432p are connected to each other. That is, the primary coils 431p and 432p are connected to form a closed loop.

The inverter INV generates an inverted input pulse signal INB by inverting the logic level of the input pulse signal IN. The inverted input pulse signal INB is at low level under the state in which the input pulse signal IN is at high level. On the other hand, the inverted input pulse signal INB is at high level under the state in which the input pulse signal IN is at low level.

The switching device SW2 is turned on, for example, under the state in which the inverted input pulse signal INB is at high level. At this time, the terminals of the primary coil 431p are short-circuited to each other. On the other hand, the switching device SW2 is turned off, for example, under the state in which the inverted input pulse signal INB is at low level. At this time, the terminals of the primary coil 431p are both opened.

### <Description of Operation (Second Embodiment)>

Under the state in which the input pulse signal IN is at high level, the inverted input pulse signal INB is at low level, and hence the switching device SW2 is turned off. Thus, the terminals of the primary coil 431p that forms the isolation device 431 are both opened. Therefore, in response to the driving of the first signal Po to be applied to the secondary coil 431s of the isolation device 431, the primary coil 432p of the isolation device 432 is driven according to the first signal Po that is generated in the primary coil 431p of the isolation device 431 (more strictly, the induced signal according to the first signal Po). At this time, the second signal Ri (corresponding to the induced signal according to the first signal Po) is generated in the secondary coil 432s of the isolation device 432.

That is, under the state in which the input pulse signal IN is at high level, the switching circuit 411 switches the state of the connection between the isolation device 431 and the isolation device 432 to the first connection state in which the isolation device 432 is driven according to the first signal Po.

On the other hand, under the state in which the input pulse signal IN is at low level, the inverted input pulse signal INB is at high level, and hence the switching device SW2 is turned on. Thus, the terminals of the primary coil 431p that forms the isolation device 431 are short-circuited to each other. Therefore, even in response to the driving of the first signal Po to be applied to the secondary coil 431s of the isolation device 431, the primary coil 432p of the isolation device 432 is not driven according to the first signal Po that is generated in the primary coil 431p of the isolation device 431 (more strictly, the induced signal according to the first signal Po). As a result, the second signal Ri (corresponding to the induced signal according to the first signal Po) is not generated in the secondary coil 432s of the isolation device 432.

That is, under the state in which the input pulse signal IN is at low level, the switching circuit 411 switches the state of the connection between the isolation device 431 and the isolation device 432 to the second connection state in which the isolation device 432 is not driven according to the first signal Po.

Exactly as in the first embodiment (FIG. 10) described previously, the reception circuit 422 is capable of distinguishing the logic level of the input pulse signal IN by detecting whether or not the second signal Ri has been generated in the secondary coil 432s of the isolation device 432. For example, the reception circuit 422 sets the output pulse signal OUT to high level by determining that the input pulse signal IN is at high level in response to the reception of the second signal Ri. On the other hand, the reception circuit 422 sets the output pulse signal OUT to low level by determining that the input pulse signal IN is at low level in response to the absence of the second signal Ri.

Note that, the switching device SW2 need not necessarily be connected in parallel to the primary coil 431p of the isolation device 431 as shown in the diagram. For example, the switching device SW2 may be connected in parallel to the primary coil 432p of the isolation device 432. Alternatively, the switching devices SW1 and SW2 may be provided in combination.

### <Signal Transmission Device (Third Embodiment)>

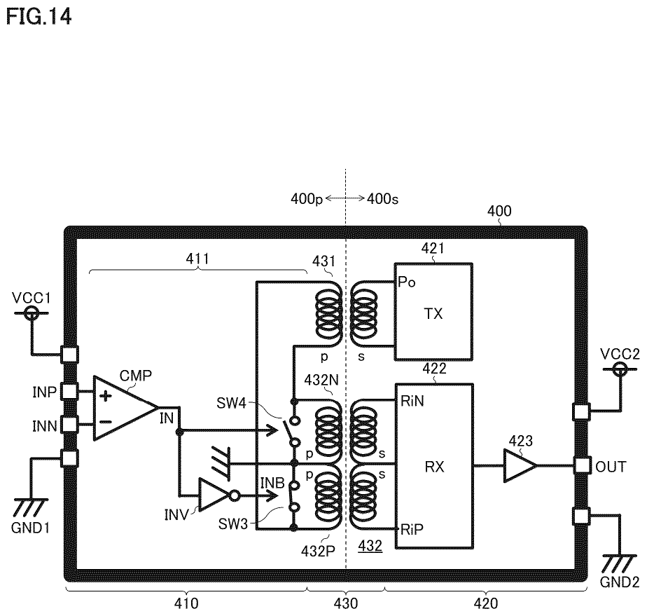

FIG. 14 is a diagram showing a third embodiment of the signal transmission devices. The signal transmission device 400 of this embodiment is basically the same as that of the second embodiment (FIG. 13) described previously except that the configuration of the switching circuit 411 is varied.

In terms of what is shown in the diagram, the isolation device 432 described previously includes a positive-phase isolation device 432P and a negative-phase isolation device 432N, and differentially outputs respective output signals from the positive-phase isolation device 432P and the negative-phase isolation device 432N as second signals Rip and RiN.

Note that, the positive-phase isolation device 432P and the negative-phase isolation device 432N may each be a transformer. That is, the positive-phase isolation device 432P includes a pair of a primary coil 432Pp and a secondary coil 432Ps that can be electromagnetically coupled to each other. Likewise, the negative-phase isolation device 432N includes a pair of a primary coil 432Np and a secondary coil 432Ns that can be electromagnetically coupled to each other.

Moreover, the switching circuit 411 includes switching devices SW3 and SW4 in place of the switching device SW2 described previously.

The first terminal of the switching device SW3 is connected to the first terminal of the primary coil 432Pp. The second terminal of the switching device SW3 is connected to the second terminal of the primary coil 432Pp. That is, the switching device SW3 is connected in parallel to the primary coil 432Pp.

The first terminal of the switching device SW4 is connected to the first terminal of the primary coil 432Np. The second terminal of the switching device SW4 is connected to the second terminal of the primary coil 432Np. That is, the switching device SW4 is connected in parallel to the primary coil 432Np.

Note that, the respective first terminals of the primary coils 431p and 432Pp are connected to each other. The respective second terminals of the primary coils 432Pp and 432Np are both connected to the grounded terminal. The second terminal of the primary coil 431p and the first terminal of the primary coil 432Np are connected to each other. That is, the primary coils 431p, 432Pp, and 432Np are connected to form a closed loop.

The switching device SW3 is turned on, for example, under the state in which the inverted input pulse signal INB is at high level. At this time, the terminals of the primary coil 432Pp are short-circuited to each other. On the other hand, the switching device SW3 is turned off, for example, under the state in which the inverted input pulse signal INB is at low level. At this time, the terminals of the primary coil 432Pp are both opened.

The switching device SW4 is turned on, for example, under the state in which the input pulse signal IN is at high level. At this time, the terminals of the primary coil 432Np are short-circuited to each other. On the other hand, the switching device SW4 is turned off, for example, under the state in which the input pulse signal IN is at low level. At this time, the terminals of the primary coil 432Np are both opened.

### Description of Operation (Third Embodiment)

Under the state in which the input pulse signal IN is at high level, and in which the inverted input pulse signal INB is at low level, the switching device SW3 is turned off, and the switching device SW4 is turned on. Thus, the terminals of the primary coil 432Pp that forms the positive-phase isolation device 432P are both opened, and the terminals of the primary coil 432Np that forms the negative-phase isolation device 432N are short-circuited to each other.

Therefore, in response to the driving of the first signal Po to be applied to the secondary coil 431s of the isolation device 431, the primary coil 432Pp of the positive-phase isolation device 432P is driven according to the first signal Po that is generated in the primary coil 431p of the isolation device 431 (more strictly, the induced signal according to the first signal Po). At this time, the positive-phase second signal RiP (corresponding to the induced signal according to the first signal Po) is generated in the secondary coil 432Ps of the positive-phase isolation device 432P. On the other hand, the negative-phase second signal RiN is not generated in the secondary coil 432Ns of the negative-phase isolation device 432N.

That is, under the state in which the input pulse signal IN is at high level, and in which the inverted input pulse signal INB is at low level, the switching circuit 411 switches the state of the connection between the isolation device 431 and the isolation device 432 to a first connection state in which the positive-phase isolation device 432P is driven according to the first signal Po.

On the other hand, under the state in which the input pulse signal IN is at low level, and in which the inverted input pulse signal INB is at high level, by contrast, the switching device SW3 is turned on, and the switching device SW4 is turned off. Thus, the terminals of the primary coil 432Pp that forms the positive-phase isolation device 432P are short-circuited to each other, and the terminals of the primary coil 432Np that forms the negative-phase isolation device 432N are both opened.

Therefore, in response to the driving of the first signal Po to be applied to the secondary coil 431s of the isolation device 431, the primary coil 432Np of the negative-phase isolation device 432N is driven according to the first signal Po that is generated in the primary coil 431p of the isolation device 431 (more strictly, the induced signal according to the first signal Po). At this time, the negative-phase second signal RiN (corresponding to the induced signal according to the first signal Po) is generated in the secondary coil 432Ns of the negative-phase isolation device 432N. On the other hand, the positive-phase second signal RiP is not generated in the secondary coil 432Ps of the positive-phase isolation device 432P.

That is, under the state in which the input pulse signal IN is at low level, and in which the inverted input pulse signal INB is at high level, the switching circuit 411 switches the state of the connection between the isolation device 431 and the isolation device 432 to a second connection state in which the negative-phase isolation device 432N is driven according to the first signal Po.

The reception circuit 422 is capable of distinguishing the logic level of the input pulse signal IN by detecting a difference between the positive-phase second signal RiP and the negative-phase second signal RiN.

For example, the reception circuit 422 may set the output pulse signal OUT to high level by determining that the input pulse signal IN is at high level under a state in which the positive-phase second signal RiP is stronger than the negative-phase second signal RiN. Alternatively, for example, the reception circuit 422 may set the output pulse signal OUT to high level by determining that the input pulse signal IN is at high level under a state in which a difference value (RiP−RiN) obtained by subtracting the negative-phase second signal RiN from the positive-phase second signal RiP is larger than a predetermined threshold (e.g., positive threshold+Vth).

On the other hand, for example, the reception circuit 422 may set the output pulse signal OUT to low level by determining that the input pulse signal IN is at low level under a state in which the positive-phase second signal RiP is weaker than the negative-phase second signal RiN. Alternatively, for example, the reception circuit 422 may set the output pulse signal OUT to low level by determining that the input pulse signal IN is at low level under a state in which the difference value (RiP-RiN) obtained by subtracting the negative-phase second signal RiN from the positive-phase second signal RiP is smaller than a predetermined threshold (e.g., negative threshold-Vth).

In this way, by the configuration in which a magnitude relationship or a magnitude of the difference value between the second signals RiP and RiN to be differentially input is detected instead of the presence or the absence of the second signal Ri to be input in a single phase, common mode transient immunity (what is generally called CMTI [common mode transient immunity]) to transients in each of the ground voltages GND1 and GND2 is enhanced.

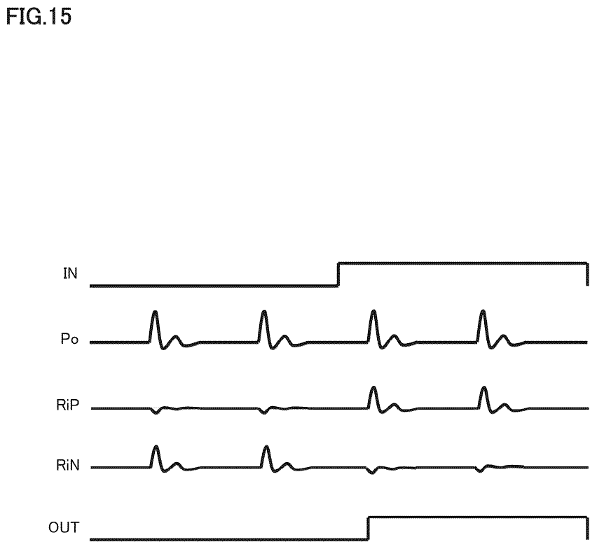

FIG. 15 is a chart showing an operation example of the third embodiment. Sequentially from the top of the chart, the input pulse signal IN, the first signal Po, the positive-phase second signal RiP, the negative-phase second signal RiN, and the output pulse signal OUT are shown. As shown in the chart, the drive circuit 421 may cyclically drive (e.g., pulse-drive) the first signal Po to be input to the secondary coil 431s of the isolation device 431.

Under the state in which the input pulse signal IN is at high level, while the induced pulses are generated in the positive-phase second signal RiP in response to the pulse-driving of the first signal Po, the induced pulses are not generated in the negative-phase second signal RiN. Thus, the reception circuit 422 detects RiP>RiN (or RiP−RiN>+Vth), and sets the output pulse signal OUT to high level.

By contrast, under the state in which the input pulse signal IN is at low level, while the induced pulses are generated in the negative-phase second signal RiN in response to the pulse-driving of the first signal Po, the induced pulses are not generated in the positive-phase second signal RiP. Thus, the reception circuit 422 detects RiP<RiN (or RiP−RiN<−Vth), and sets the output pulse signal OUT to low level.

### Signal Transmission Device (Fourth Embodiment)

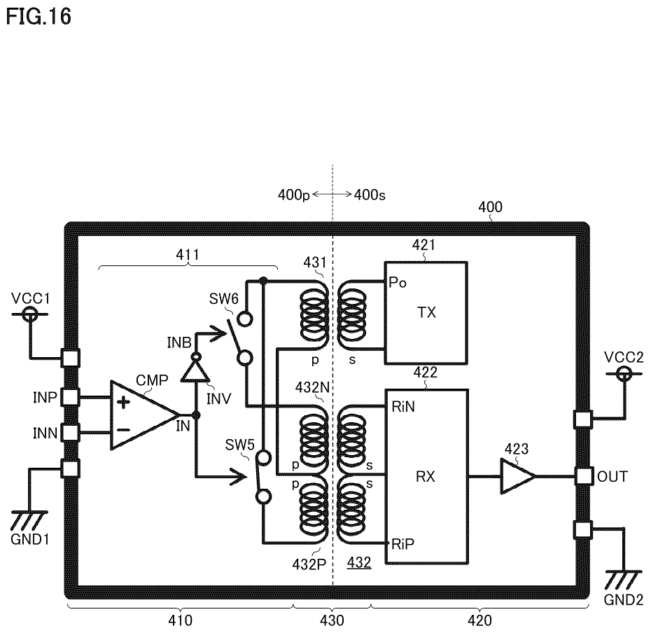

FIG. 16 is a diagram showing a fourth embodiment of the signal transmission devices. The signal transmission device 400 of this embodiment is basically the same as that of the third embodiment (FIG. 14) described previously except that the configuration of the switching circuit 411 is varied. In terms of what is shown in the diagram, the switching circuit 411 includes switching devices SW5 and SW6 in place of the switching devices SW3 and SW4 described previously.

The respective first terminals of the switching devices SW5 and SW6 are connected to the first terminal of the primary coil 431p. The second terminal of the switching device SW5 is connected to the second terminal of the primary coil 432Pp. The second terminal of the switching device SW6 is connected to the first terminal of the primary coil 432Np. The second terminal of the primary coil 431p is connected to the respective second terminals of the primary coils 432Pp and 432Np. In this way, the switching device SW5 is connected to form a closed loop cooperatively with the primary coils 431p and 432Pp. Likewise, the switching device SW6 is connected to form a closed loop cooperatively with the primary coils 431p and 432Np.

The switching device SW5 is turned on, for example, under the state in which the input pulse signal IN is at high level. At this time, conduction between the primary coil 431p of the isolation device 431 and the primary coil 432Pp of the positive-phase isolation device 432P is established. On the other hand, the switching device SW5 is turned off under the state in which the input pulse signal IN is at low level. At this time, the conduction between the primary coil 431p of the isolation device 431 and the primary coil 432Pp of the positive-phase isolation device 432P is cut off.

The switching device SW6 is turned on, for example, under the state in which the inverted input pulse signal INB is at high level. At this time, conduction between the primary coil 431p of the isolation device 431 and the primary coil 432Np of the negative-phase isolation device 432N is established. On the other hand, the switching device SW6 is turned off under the state in which the inverted input pulse signal INB is at low level. At this time, the conduction between the primary coil 431p of the isolation device 431 and the primary coil 432Np of the negative-phase isolation device 432N is cut off.

### Description of Operation (Fourth Embodiment)

Under the state in which the input pulse signal IN is at high level, and in which the inverted input pulse signal INB is at low level, the switching device SW5 is turned on, and the switching device SW6 is turned off. Thus, the conduction between the primary coil 431p and the primary coil 432Pp is established, and the conduction between the primary coil 431p and the primary coil 432Np is cut off. As a result, the positive-phase second signal RiP is generated in the secondary coil 432Ps of the positive-phase isolation device 432P. On the other hand, the negative-phase second signal RiN is not generated in the secondary coil 432Ns of the negative-phase isolation device 432N.

On the other hand, under the state in which the input pulse signal IN is at low level, and in which the inverted input pulse signal INB is at high level, by contrast, the switching device SW5 is turned off, and the switching device SW6 is turned on. Thus, the conduction between the primary coil 431p and the primary coil 432Pp is cut off, and the conduction between the primary coil 431p and the primary coil 432Np is established. As a result, the negative-phase second signal RiN is generated in the secondary coil 432Ns of the negative-phase isolation device 432N. On the other hand, the positive-phase second signal RiP is not generated in the secondary coil 432Ps of the positive-phase isolation device 432P.

The reception circuit 422 is capable of distinguishing the logic level of the input pulse signal IN by detecting the difference between the positive-phase second signal RiP and the negative-phase second signal RiN exactly as in the third embodiment (FIG. 14) described previously.

### Signal Transmission Device (Fifth Embodiment)

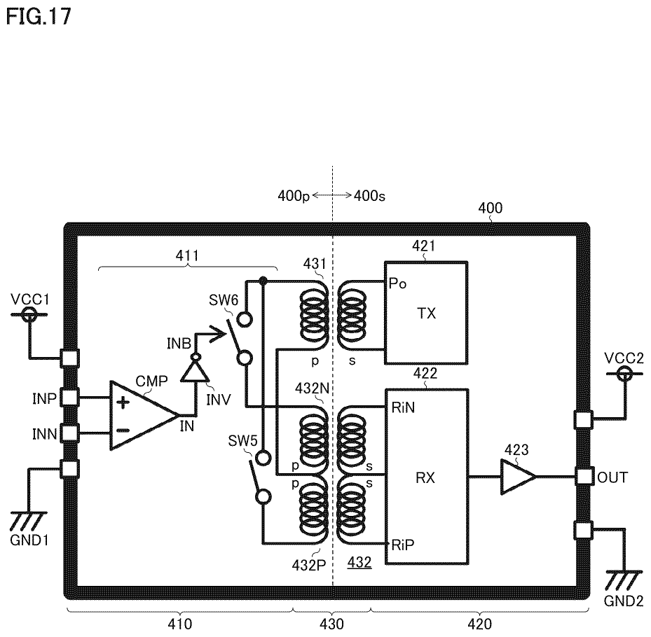

FIG. 17 is a diagram showing a fifth embodiment of the signal transmission devices. The signal transmission device 400 of this embodiment is basically the same as that of the fourth embodiment (FIG. 15) described previously except that the configuration of the switching circuit 411 is varied. In terms of what is shown in the diagram, in the switching circuit 411, the switching device SW5 described previously is always turned off.

Note that, the switching device SW5 is provided to enhance symmetry with the switching device SW6 (i.e., similarity of device layout and wiring layout on the substrate). However, the switching device SW5 may be omitted. Moreover, wirings need not necessarily be connected to the switching device SW5.

### Description of Operation (Fifth Embodiment)

Under the state in which the inverted input pulse signal INB is at low level, the switching device SW6 is turned off. Thus, the conduction between the primary coil 431p and the primary coil 432Np is cut off. As a result, even in response to the driving of the first signal Po, the negative-phase second signal RiN is not generated.

On the other hand, under the state in which the inverted input pulse signal INB is at high level, the switching device SW6 is turned on. Thus, the conduction between the primary coil 431p and the primary coil 432Np is established. As a result, in response to the driving of the first signal Po, the negative-phase second signal RiN is generated.

The reception circuit 422 is capable of distinguishing the logic level of the input pulse signal IN by detecting the difference between the positive-phase second signal RiP and the negative-phase second signal RiN exactly as in the third embodiment (FIG. 14) described previously. Moreover, when the second signals RiP and RiN are differential, an advantage of excellent common-mode transient immunity can be obtained.

Note that, in the signal transmission device 400 of this embodiment, the positive-phase second signal RiP is not generated even in response to the driving of the first signal Po. Thus, substantially, the reception circuit 422 distinguishes the logic level of the input pulse signal IN by detecting the presence or the absence of the negative-phase second signal RiN. It can be said that this configuration is similar to that of the first embodiment (FIG. 10) described previously.

### Signal Transmission Device (Sixth Embodiment)

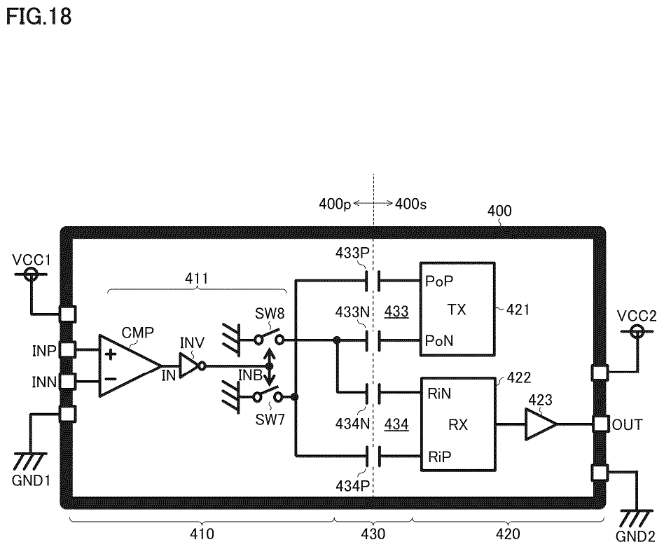

FIG. 18 is a diagram showing a sixth embodiment of the signal transmission devices. The signal transmission device 400 of this embodiment is basically the same as that of the first embodiment (FIG. 10) described previously except including isolation devices 433 and 434 (both are capacitors) in place of the isolation devices 431 and 432 (both are transformers).

The isolation device 433 includes a positive-phase isolation device 433P and a negative-phase isolation device 433N. The positive-phase isolation device 433P and the negative-phase isolation device 433N respectively transmit differential first signals PoP and PON from the secondary circuit system 400s to the primary circuit system 400p. Note that, the first signals POP and PoN are driven in phases opposite to each other. The isolation device 433 functions as an inquiring isolation device.

The isolation device 434 includes a positive-phase isolation device 434P and a negative-phase isolation device 434N. The positive-phase isolation device 434P and the negative-phase isolation device 434N respectively transmit the differential second signals RiP and RiN from the primary circuit system 400p to the secondary circuit system 400s. The isolation device 434 functions as a responding isolation device.

All the respective first terminals of the positive-phase isolation device 433P, the negative-phase isolation device 433N, the positive-phase isolation device 434P, and the negative-phase isolation device 434N are provided in the primary circuit system 400p. All the respective second terminals of the positive-phase isolation device 433P, the negative-phase isolation device 433N, the positive-phase isolation device 434P, and the negative-phase isolation device 434N are provided in the secondary circuit system 400s.

The respective first terminals of the positive-phase isolation device 433P and the positive-phase isolation device 434P are connected to each other. The respective first terminals of the negative-phase isolation device 433N and the negative-phase isolation device 434N are connected to each other. The second terminal of the positive-phase isolation device 433P is connected to the first output terminal of the drive circuit 421 (corresponding to an application terminal for the positive-phase first signal PoP). The second terminal of the negative-phase isolation device 433N is connected to the second output terminal of the drive circuit 421 (corresponding to an application terminal for the negative-phase first signal PoN). The second terminal of the positive-phase isolation device 434P is connected to the first input terminal of the reception circuit 422 (corresponding to an application terminal for the positive-phase second signal RiP). The second terminal of the negative-phase isolation device 434N is connected to the second input terminal of the reception circuit 422 (corresponding to an application terminal for the negative-phase second signal RiN).

Moreover, in the signal transmission device 400 of this embodiment, the configuration of the switching circuit 411 is also varied. In terms of what is shown in the diagram, the switching circuit 411 includes the inverter INV and switching devices SW7 and SW8 in place of the switching device SW1 described previously.

The switching device SW7 is connected between the respective first terminals of the positive-phase isolation devices 433P and 434P and a fixed potential terminal (e.g., the grounded terminal). The switching device SW8 is connected between the respective first terminals of the negative-phase isolation devices 433N and 434N and the fixed potential terminal (e.g., the grounded terminal).

The switching devices SW7 and SW8 are both turned on under the state in which the inverted input pulse signal INB is at high level. At this time, conduction between the respective first terminals of the positive-phase isolation device 433P, the negative-phase isolation device 433N, the positive-phase isolation device 434P, and the negative-phase isolation device 434N and the fixed potential terminal is established. On the other hand, the switching devices SW7 and SW8 are both turned off under the state in which the inverted input pulse signal INB is at low level. At this time, the conduction between the respective first terminals of the positive-phase isolation device 433P, the negative-phase isolation device 433N, the positive-phase isolation device 434P, and the negative-phase isolation device 434N and the fixed potential terminal is cut off.

### Description of Operation (Sixth Embodiment)

Under the state in which the input pulse signal IN is at high level, the inverted input pulse signal INB is at low level, and hence the switching devices SW7 and SW8 are both turned off. Thus, the conduction between the respective first terminals of the positive-phase isolation device 433P, the negative-phase isolation device 433N, the positive-phase isolation device 434P, and the negative-phase isolation device 434N and the fixed potential terminal is cut off. Therefore, the first signals POP and PON to be output from the drive circuit 421 are transmitted to the positive-phase isolation device 434P and the negative-phase isolation device 434N via the positive-phase isolation device 433P and the negative-phase isolation device 433N. As a result, the second signals Rip and RiN (corresponding to the first signals POP and PoN) via the positive-phase isolation device 434P and the negative-phase isolation device 434N are transmitted to the reception circuit 422.

That is, under the state in which the input pulse signal IN is at high level, the switching circuit 411 switches a state of the connection between the isolation device 433 and the isolation device 434 to a first connection state in which the isolation device 434 is driven according to the first signals POP and PoN.

On the other hand, under the state in which the input pulse signal IN is at low level, the inverted input pulse signal INB is at high level, and hence the switching devices SW7 and SW8 are both turned on. Thus, the conduction between the respective first terminals of the positive-phase isolation device 433P, the negative-phase isolation device 433N, the positive-phase isolation device 434P, and the negative-phase isolation device 434N and the fixed potential terminal is established. Therefore, the first signals POP and PON to be output from the drive circuit 421 are attenuated without being transmitted to the positive-phase isolation device 434P and the negative-phase isolation device 434N. As a result, the second signals Rip and RiN (corresponding to the first signals POP and PoN) via the positive-phase isolation device 434P and the negative-phase isolation device 434N are not transmitted to the reception circuit 422.

That is, under the state in which the input pulse signal IN is at low level, the switching circuit 411 switches the state of the connection between the isolation device 433 and the isolation device 434 to a second connection state in which the isolation device 434 is not driven according to the first signals POP and PoN.

The reception circuit 422 is capable of distinguishing the logic level of the input pulse signal IN by detecting the difference between the positive-phase second signal RiP and the negative-phase second signal RiN exactly as in the third embodiment (FIG. 14) and the fourth embodiment (FIG. 16) described previously.

Note that, in the diagram, the differential system excellent in common mode transient immunity is employed. However, the signal transmission system is not limited thereto at all, and single-phase signals may be transmitted. In that case, for example, all the negative-phase isolation devices 433N and 434N and the switching device SW8 can be omitted.

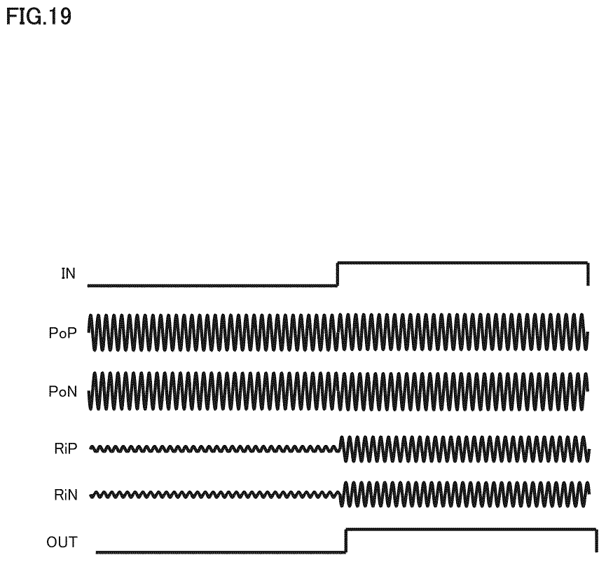

FIG. 19 is a chart showing an operation example of the sixth embodiment. Sequentially from the top of the chart, the input pulse signal IN, the positive-phase first signal POP, the negative-phase first signal PoN, the positive-phase second signal RiP, the negative-phase second signal RiN, and the output pulse signal OUT are shown. As shown in the chart, the drive circuit 421 may continuously drive (e.g., sinusoidally drive), in phases opposite to each other, the first signals PoP and PoN to be applied respectively to the second terminals of the positive-phase isolation device 433P and the negative-phase isolation device 433N.

Under the state in which the input pulse signal IN is at high level, the first signals POP and PoN are transmitted as the second signals Rip and RiN. Thus, the reception circuit 422 detects, for example, |RiP−RiN|>Vth, and sets the output pulse signal OUT to high level.

By contrast, under the state in which the input pulse signal IN is at low level, even in response to the driving of the first signals POP and PON, the first signals POP and PoN are scarcely transmitted as the second signals Rip and RiN. Thus, the reception circuit 422 detects, for example, |RiP−RiN|<Vth, and sets the output pulse signal OUT to low level.

### Signal Transmission Device (Seventh Embodiment)

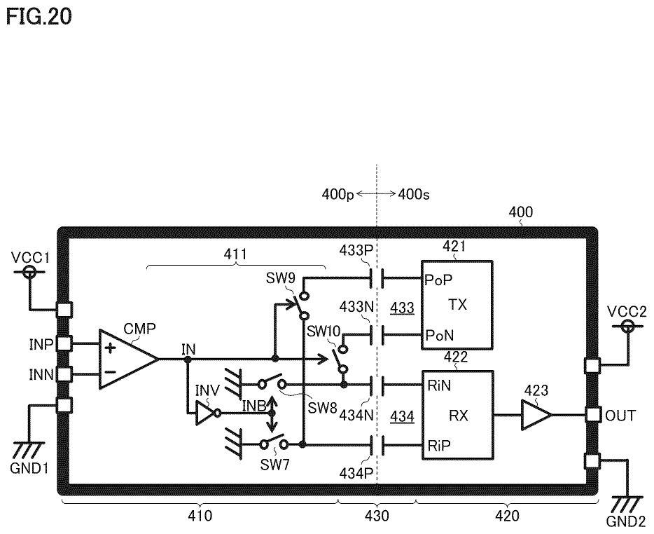

FIG. 20 is a diagram showing a seventh embodiment of the signal transmission devices. The signal transmission device 400 of this embodiment is basically the same as that of the sixth embodiment (FIG. 18) described previously except that the configuration of the switching circuit 411 is varied. In terms of what is shown in the diagram, the switching circuit 411 further includes switching devices SW9 and SW10.

The switching device SW9 is connected between the first terminal of the positive-phase isolation device 433P and the first terminal of the positive-phase isolation device 434P. The switching device SW10 is connected between the first terminal of the negative-phase isolation device 433N and the first terminal of the negative-phase isolation device 434N.

The switching devices SW9 and SW10 are both turned on under the state in which the input pulse signal IN is at high level. At this time, conduction between the first terminal of the positive-phase isolation device 433P and the first terminal of the positive-phase isolation device 434P, and conduction between the first terminal of the negative-phase isolation device 433N and the first terminal of the negative-phase isolation device 434N are both established. On the other hand, the switching devices SW9 and SW10 are both turned off under the state in which the input pulse signal IN is at low level. At this time, the conduction between the first terminal of the positive-phase isolation device 433P and the first terminal of the positive-phase isolation device 434P, and the conduction between the first terminal of the negative-phase isolation device 433N and the first terminal of the negative-phase isolation device 434N are both cut off.

### Description of Operation (Seventh Embodiment)

Under the state in which the input pulse signal IN is at high level, and in which the inverted input pulse signal INB is at low level, the switching devices SW7 and SW8 are both turned off, and the switching devices SW9 and SW10 are both turned on. Thus, the first signals PoP and PON are transmitted to the positive-phase isolation device 434P and the negative-phase isolation device 434N via the positive-phase isolation device 433P and the negative-phase isolation device 433N. As a result, the second signals Rip and RiN (corresponding to the first signals POP and PoN) via the positive-phase isolation device 434P and the negative-phase isolation device 434N are transmitted to the reception circuit 422.

On the other hand, under the state in which the input pulse signal IN is at low level, and in which the inverted input pulse signal INB is at high level, the switching devices SW7 and SW8 are both turned on, and the switching devices SW9 and SW10 are both turned off. Thus, the first signals POP and PON are attenuated without being transmitted to the positive-phase isolation device 434P and the negative-phase isolation device 434N. As a result, the second signals Rip and RiN (corresponding to the first signals POP and PoN) via the positive-phase isolation device 434P and the negative-phase isolation device 434N are not transmitted to the reception circuit 422.

The reception circuit 422 is capable of distinguishing the logic level of the input pulse signal IN by detecting the difference between the positive-phase second signal RiP and the negative-phase second signal RiN exactly as in the sixth embodiment (FIG. 18) described previously.

### Signal Transmission Device (Eighth Embodiment)

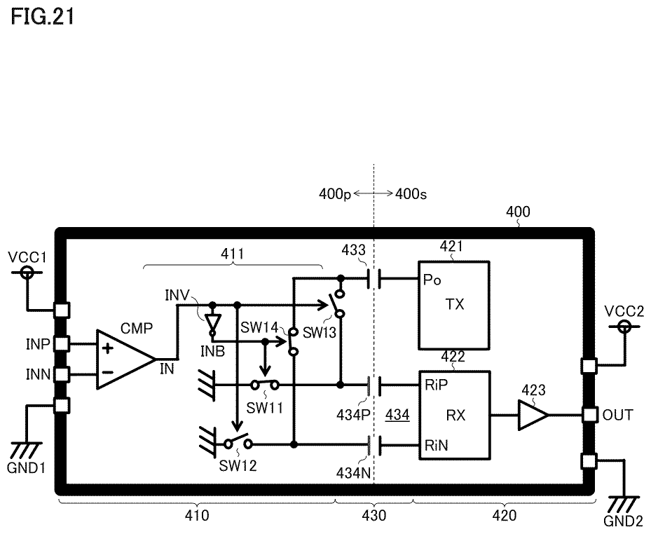

FIG. 21 is a diagram showing an eighth embodiment of the signal transmission devices. The signal transmission device 400 of this embodiment is basically the same as that of the sixth embodiment (FIG. 18) described previously except that the isolation device 433 is varied to a type that transmits the single-phase first signal Po. Moreover, accordingly, the configuration of the switching circuit 411 is also varied. In terms of what is shown in the diagram, the switching circuit 411 includes switching devices SW11 to SW14 in place of the switching devices SW7 and SW8 described previously.

The switching device SW11 is connected between the first terminal of the positive-phase isolation device 434P and the fixed potential terminal (e.g., the grounded terminal). Likewise, the switching device SW12 is connected between the first terminal of the negative-phase isolation device 434N and the fixed potential terminal (e.g., the grounded terminal). The switching device SW13 is connected between the first terminal of the isolation device 433 and the first terminal of the positive-phase isolation device 434P. Likewise, the switching device SW14 is connected between the first terminal of the isolation device 433 and the first terminal of the negative-phase isolation device 434N.

The switching device SW11 is turned on under the state in which the inverted input pulse signal INB is at high level. Thus, conduction between the first terminal of the positive-phase isolation device 434P and the fixed potential terminal is established. On the other hand, the switching device SW11 is turned off under the state in which the inverted input pulse signal INB is at low level. Thus, the conduction between the first terminal of the positive-phase isolation device 434P and the fixed potential terminal is cut off.

The switching device SW12 is turned on under the state in which the input pulse signal IN is at high level. Thus, conduction between the first terminal of the negative-phase isolation device 434N and the fixed potential terminal is established. On the other hand, the switching device SW12 is turned off under the state in which the input pulse signal IN is at low level. Thus, the conduction between the first terminal of the negative-phase isolation device 434N and the fixed potential terminal is cut off.

The switching device SW13 is turned on under the state in which the input pulse signal IN is at high level. Thus, conduction between the first terminal of the isolation device 433 and the first terminal of the positive-phase isolation device 434P is established. On the other hand, the switching device SW13 is turned off under the state in which the input pulse signal IN is at low level. Thus, the conduction between the first terminal of the isolation device 433 and the first terminal of the positive-phase isolation device 434P is cut off.

The switching device SW14 is turned on under the state in which the inverted input pulse signal INB is at high level. Thus, conduction between the first terminal of the isolation device 433 and the first terminal of the negative-phase isolation device 434N is established. On the other hand, the switching device SW14 is turned off under the state in which the inverted input pulse signal INB is at low level. Thus, the conduction between the first terminal of the isolation device 433 and the first terminal of the negative-phase isolation device 434N is cut off.

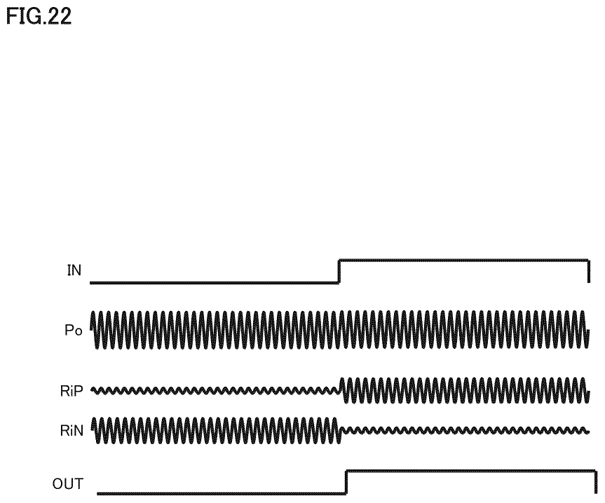

FIG. 22 is a chart showing an operation example of the eighth embodiment. Sequentially from the top of the chart, the input pulse signal IN, the first signal Po, the positive-phase second signal RiP, the negative-phase second signal RiN, and the output pulse signal OUT are shown. As shown in the chart, the drive circuit 421 may continuously drive (e.g., sinusoidally drive) the first signal Po to be applied to the second terminal of the isolation device 433.

Under the state in which the input pulse signal IN is at high level, the first signal Po is transmitted as the second signal Rip. Thus, the reception circuit 422 detects, for example, |RiP−RiN|>Vth, and sets the output pulse signal OUT to high level.

By contrast, under the state in which the input pulse signal IN is at low level, the first signal Po is transmitted as the second signal RiN. Thus, the reception circuit 422 detects, for example, |RiP−RiN|<Vth, and sets the output pulse signal OUT to low level.

### <Isolation Switch 500>

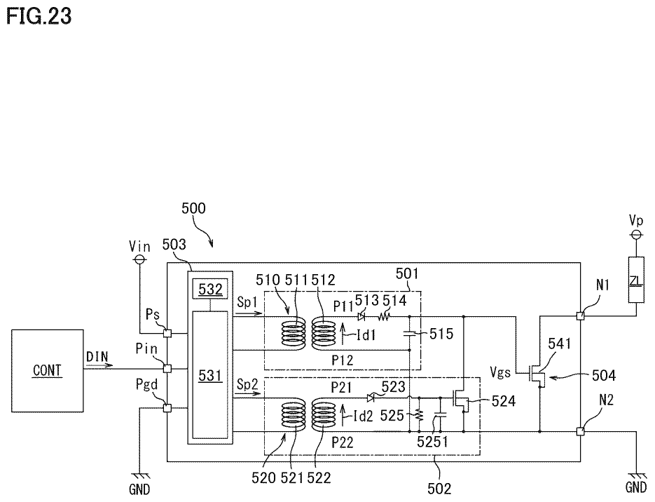

FIG. 23 is a schematic circuit diagram showing an embodiment of an isolation switch 500 according to the embodiments of the present disclosure. The isolation switch 500 shown in FIG. 23 is incorporated in a sequencer and the like, and is used as a switch that switches on/off a circuit which supplies a power voltage Vp to a load ZL.

The isolation switch 500 includes a power terminal Ps, an input terminal Pin, a grounded terminal Pgd, a first terminal N1, and a second terminal N2. The power terminal Ps is connected to a control voltage supply that supplies a control voltage Vin. The control voltage Vin is a voltage that drives a pulse supply circuit 503.

A control signal DIN being a signal that operates the load ZL is input from a control circuit CONT that is disposed on the outside to the input terminal Pin. The control signal DIN is a signal that is at Hi level under the state in which the power voltage Vp has been supplied to the load ZL, that is, a switching unit 504 described below of the isolation switch 500 has been controlled to turn on. The grounded terminal Pgd is connected to a ground potential GND.

The first terminal N1 is connected to a voltage supply that supplies the power voltage Vp to the load ZL. Note that, the load ZL is disposed between the voltage supply and the first terminal N1. The second terminal N2 is connected to the ground potential GND. The isolation switch 500 controls on/off of the switching unit 504 according to the control signal DIN, and controls the first terminal N1 and the second terminal N2 so that these terminals establish or cut off conduction. In this way, the isolation switch 500 supplies the power voltage Vp to the load ZL.

The isolation switch 500 shown in FIG. 23 includes a conduction circuit 501, an adjustment circuit 502, a pulse supply circuit 503, and the switching unit 504.

### <Switching Unit 504>

The switching unit 504 is controlled to conduct or not to conduct. In the isolation switch 500, the switching unit 504 includes a switching device 541 constituted by an n-channel MOS field-effect transistor. In the switching device 541, the drain is connected to the first terminal N1. The source is connected to the second terminal N2. The gate is connected to the conduction circuit 501, and the switching device 541 is turned on by being supplied with a voltage from the conduction circuit 501. Moreover, the gate is connected to the adjustment circuit 502, and the switching device 541 is turned off by drawing out current by the adjustment circuit 502. Furthermore, the backgate of the switching device 541 is connected to the source and to the second terminal N2 that is connected to the ground potential GND.

That is, the conduction circuit 501 is a circuit that turns on the switching device 541 which constitutes the switching unit 504, and the adjustment circuit 502 is a circuit that turns off the switching unit 504. Note that, the adjustment circuit 502 may be understood as a discharge circuit that discharges parasitic capacitance of the gate of the switching device 541.

### <Pulse Supply Circuit 503>

The pulse supply circuit 503 is connected to the power terminal Ps, the input terminal Pin, and the grounded terminal Pgd. The control voltage Vin is supplied to the pulse supply circuit 503 via the power terminal Ps. Note that, the control voltage Vin is a value of a voltage that drives the pulse supply circuit 503 constituted by an electronic circuit, and that is lower than the power voltage Vp for operating the load ZL. The pulse supply circuit 503 is connected to the ground potential GND via the grounded terminal Pgd.

The control signal DIN is input to the pulse supply circuit 503 via the input terminal Pin. The control signal DIN is a signal that is at Hi level or Lo level, and is a signal that is at Hi level during a period in which the power voltage Vp is supplied to the load ZL. That is, under the state in which the control signal DIN is at Hi level, the switching device 541 of the switching unit 504 is turned on to supply the power voltage Vp to the load ZL. On the other hand, under the state in which the control signal DIN is at Lo level, the switching device 541 of the switching unit 504 is turned off not to supply the power voltage Vp to the load ZL.

The pulse supply circuit 503 is connected to a first primary coil 511 described below of the conduction circuit 501 and a second primary coil 521 described below of the adjustment circuit 502. The pulse supply circuit 503 supplies a first pulse signal Sp1 to the first primary coil 511, and supplies a second pulse signal Sp2 to the second primary coil 521.

The pulse supply circuit 503 includes a pulse generating circuit 531 and an oscillator circuit 532. The oscillator circuit 532 supplies, to the pulse generating circuit 531, a clock signal that instructs a timing to generate the pulse signal (first pulse signal Sp1 or second pulse signal Sp2). The clock signal to be output from the oscillator circuit 532 is, for example, a square wave with a predetermined frequency and a predetermined duty cycle. The oscillator circuit 532 is configured to be capable of modulating the frequency of the clock signal, and outputting and stopping the clock signal.

The pulse generating circuit 531 generates and outputs the pulse signal according to the clock signal that the oscillator circuit 532 outputs. The pulse generating circuit 531 may be configured to generate the pulse signal, for example, at a timing when the clock signal rises. Alternatively, the pulse generating circuit 531 may be configured to generate the pulse signal, for example, at both timings when the clock signal rises and falls.

The oscillator circuit 532 outputs the clock signal for the period during which the control signal DIN is at Hi level and a certain period after the control signal DIN has been switched from Hi level to Lo level. Note that, the period during which the control signal DIN is at Hi level and the certain period after the control signal DIN has been switched from Hi level to Lo level may be distinguished from each other under the management by the pulse generating circuit 531 or the management by the oscillator circuit 532. When the oscillator circuit 532 manages the distinction, for example, the oscillator circuit 532 may generate the clock signal so that an interval of the clock signal in the period during which the control signal DIN is at Hi level and an interval of the clock signal in the certain period after the control signal DIN has been switched from Hi level to Lo level are different from each other.

### <Conduction Circuit 501>

The conduction circuit 501 includes a first isolation device 510, a diode 513, a resistor 514, and a capacitor 515. The first isolation device 510 includes the first primary coil 511 and a first secondary coil 512. In the conduction circuit 501, the first primary coil 511 and the first secondary coil 512 are electrically isolated from and electromagnetically coupled to each other. Signals and the like can be transmitted from the first primary coil 511 to the first secondary coil 512 by electromagnetic induction. Use of such a first isolation device 510 helps cut off the flow of current from the circuits on the first secondary coil 512 side into the first primary coil 511.

The first primary coil 511 is connected to the pulse supply circuit 503, and receives the first pulse signal Sp1 to be supplied from the pulse supply circuit 503. The first pulse signal Sp1 is a pulse signal to be supplied under the state in which the control signal DIN is at Hi level. Winding directions of the first primary coil 511 and the first secondary coil 512 are set so that an induced current Id1 to flow from a second terminal P12 to a first terminal P11 of the first secondary coil 512 is generated in response to the rising of the first pulse signal Sp1 under the state in which the first pulse signal Sp1 has been supplied to the first primary coil 511.

Moreover, the first terminal P11 of the first secondary coil 512 is connected to the gate of the switching device 541 via the diode 513 and the resistor 514. The anode of the diode 513 is connected to the first terminal P11 of the first secondary coil 512. The cathode of the diode 513 is connected to the gate of the switching device 541 via the resistor 514. That is, the diode 513 is disposed so that its forward direction is a flow direction of the induced current Id1 to be generated in the first secondary coil 512 in response to the rising of the first pulse signal Sp1 supplied to the first primary coil 511. The disposition of the diode 513 in the conduction circuit 501 helps prevent the induced current to be generated in response to falling of the first pulse signal Sp1 from flowing through the conduction circuit 501. Note that, a bipolar transistor with its base and collector connected to each other may be used in place of the diode 513.

The resistor 514 is disposed between the diode 513 and the switching device 541. Moreover, the first terminal of the capacitor 515 is connected to the resistor 514 and the gate of the switching device 541, and the second terminal of the same is connected to the source of the switching device 541, that is, the ground potential GND. The resistor 514 and the capacitor 515 constitute a smoothing circuit that smooths the induced current Id1 according to the first pulse signal Sp1, and thereby generates a voltage Vgs. The capacitor 515 is charged by the induced current Id1. By the charging of the capacitor 515, the voltage Vgs increases, and is finally maintained to be a certain voltage.

### <Adjustment Circuit 502>

The adjustment circuit 502 includes a second isolation device 520, a diode 523, a first adjustment-switching device 524, a resistor 525, and a capacitor 5251. The second isolation device 520 includes the second primary coil 521 and a second secondary coil 522. The second primary coil 521 is connected to the pulse supply circuit 503, and receives the second pulse signal Sp2 to be supplied from the pulse supply circuit 503. The second pulse signal Sp2 is a pulse signal to be supplied for a certain period after a time point when the control signal DIN is switched from Hi level to Lo level. Winding directions of the second primary coil 521 and the second secondary coil 522 are set so that an induced current Id2 is generated from a second terminal P22 to a first terminal P21 of the second secondary coil 522 in response to rising of the second pulse signal Sp2 supplied to the second primary coil 521.

Moreover, the first terminal P21 of the second secondary coil 522 is connected to the gate of the first adjustment-switching device 524 via the diode 523. The anode of the diode 523 is connected to the first terminal P21 of the second secondary coil 522. The cathode of the diode 523 is connected to the gate of the first adjustment-switching device 524. That is, the diode 523 is disposed so that its forward direction is a flow direction of the induced current Id2 to be generated in the second secondary coil 522 in response to the rising of the second pulse signal Sp2 supplied to the second primary coil 521. Note that, the bipolar transistor with its base and collector connected to each other may be used in place of the diode 523. The disposition of the diode 523 in the adjustment circuit 502 helps prevent the induced current to be generated in response to falling of the second pulse signal Sp2 from flowing through the adjustment circuit 502.

The first adjustment-switching device 524 is an n-channel MOS transistor. The drain of the first adjustment-switching device 524 is connected to the gate of the switching device 541 of the switching unit 504. The source of the first adjustment-switching device 524 is connected to the second terminal N2 to which the source of the switching device 541 is connected, and thereby connected to the ground potential GND. The cathode of the diode 523 is connected to the gate of the first adjustment-switching device 524. Moreover, the gate and the source of the first adjustment-switching device 524 are connected to each other via the resistor 525. The resistor 525 is disposed to allow the induced current Id2 to flow. A potential difference to be generated in response to the flowing of the induced current Id2 is a gate-source voltage of the first adjustment-switching device 524, and the first adjustment-switching device 524 is controlled to turn on.

Moreover, the capacitor 5251 is parallel to the resistor 525, and the first terminal and the second terminal of the capacitor 5251 are connected respectively to the gate and the source of the first adjustment-switching device 524. Furthermore, the capacitor 5251 is charged by the induced current Id2. That is, the induced current Id2 is smoothed by the capacitor 5251. A voltage smoothed by the capacitor 5251 is applied between the gate and the source of the first adjustment-switching device 524, and the first adjustment-switching device 524 is maintained to be on. Moreover, the gate and the source of the first adjustment-switching device 524 are connected to each other via the resistor 525 to slow down current flow from the gate to the source. As a result, in response to decreasing of a gate-source voltage to a threshold or less, the first adjustment-switching device 524 is turned off.

The isolation switch 500 has the configuration described above. The isolation switch 500 includes a primary circuit to which the first primary coil 511 and the second primary coil 521 are connected, and a secondary circuit to which the first secondary coil 512 and the second secondary coil 522 are connected. That is, in the isolation switch 500, the primary circuit and the secondary circuit are isolated from each other by the first isolation device 510 and the second isolation device 520. Thus, the current that flows through the secondary circuit and operates the load ZL can be prevented from flowing through the primary circuit.

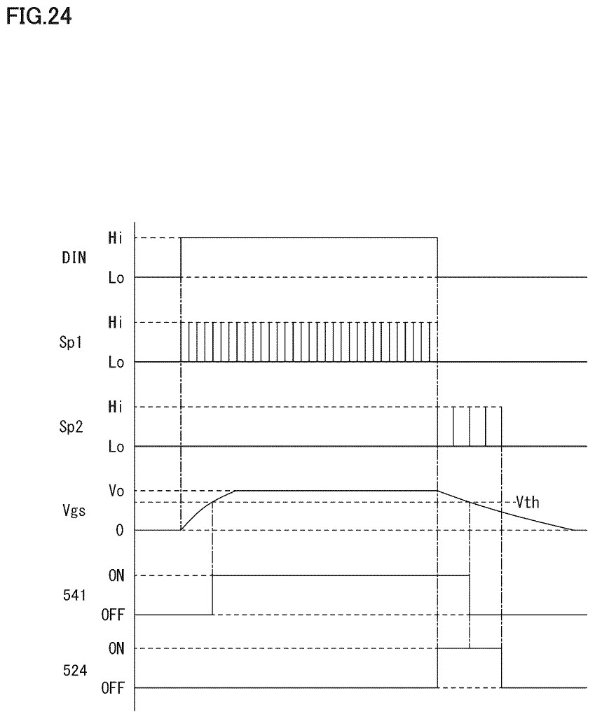

Next, the operation of the isolation switch 500 will be described referring to the drawings. FIG. 24 is a timing chart showing the operation of the isolation switch 500.

As shown in FIG. 24, in order that the power voltage Vp is supplied to the load ZL, the control signal DIN to be input to the pulse supply circuit 503 is switched from Lo level to Hi level. In response to the switching of the control signal DIN from Lo level to Hi level, the pulse supply circuit 503 supplies the first pulse signal Sp1 to the first primary coil 511.

Under the state in which the first pulse signal Sp1 has been supplied to the first primary coil 511, in response to the rising of the first pulse signal Sp1, the induced current Id1 is generated in the first secondary coil 512. Since the induced current Id1 is the current that flows along the forward direction of the diode 513, the induced current Id1 flows through the diode 513 and charges the capacitor 515. Note that, the disposition of the diode 513 prevents the current from flowing through the conduction circuit 501 even in response to the falling of the first pulse signal Sp1.

The first pulse signal Sp1 is supplied from the pulse supply circuit 503 to the first primary coil 511. Then, the capacitor 515 is charged by the induced current Id1 that is generated in the first secondary coil 512 in response to the rising of the first pulse signal Sp1. The voltage Vgs between both the terminals of the capacitor 515 increases to a predetermined voltage value Vo. As described above, a voltage between both the terminals of the capacitor 515 is the gate-source voltage Vgs of the switching device 541. In response to exceeding of the voltage Vgs above a threshold Vth, the switching device 541 is switched on.

In response to the switching on of the switching device 541, conduction between the drain and the source of the switching device 541 is established, and the first terminal N1 and the second terminal N2 are brought into a conducting state. In this way, the power voltage Vp is supplied to the load ZL, and the load ZL operates.

While receiving the control signal DIN at Hi level, the pulse supply circuit 503 continues to output the first pulse signal Sp1. At this time, the voltage Vgs is smoothed by the gate capacitance of the switching device 541 and by the capacitor 515. That is, the capacitor 515 works to maintain the voltage Vgs at the voltage value Vo. Note that, preferably, the cycle of the first pulse signal Sp1 is a cycle that does not interrupt the charging of the capacitor 515. In this way, the voltage Vgs is maintained at the voltage value Vo that is equal to or more than the threshold Vth by the capacitor 515. Thus, the switching device 541 is stably maintained to be on. That is, the power voltage Vp is stably supplied to the load ZL. Note that, when the gate capacitance of the switching device 541 is sufficiently high, the capacitor 515 may be omitted.

In order to end the operation of the load ZL, the control signal DIN from the control circuit CONT is switched from Hi level to Lo level. In response to detection of the switching of the control signal DIN from Hi level to Lo level, the pulse supply circuit 503 stops supplying the first pulse signal Sp1. Since the capacitor 515 has been charged, even under the state in which the supplying of the first pulse signal Sp1 has been stopped, and in which the induced current Id1 has been stopped, the switching device 541 is maintained to be on. That is, despite the instruction to stop the load ZL, the power voltage Vp continues to be supplied to the load ZL.

As a countermeasure, in the isolation switch 500, in response to the detection of the switching of the control signal DIN from Hi level to Lo level, the supplying of the first pulse signal Sp1 is stopped, and the second pulse signal Sp2 is supplied to the second primary coil 521. Under the state in which the second pulse signal Sp2 has been supplied to the second primary coil 521, in the second secondary coil 522, the induced current Id2 is generated in response to the rising of the second pulse signal Sp2. This induced current Id2 is current that flows along the forward direction of the diode 523, and the induced current Id2 flows through the resistor 525. In response to the flowing of the current through the resistor 525, the gate-source voltage of the first adjustment-switching device 524 increases, and the first adjustment-switching device 524 is turned on.

Note that, although the induced current Id2 is current that flows only in a short period, since the gate-source voltage of the first adjustment-switching device 524 is smoothed by the capacitor 5251, the first adjustment-switching device 524 is maintained to be on while the second pulse signal Sp2 is being supplied. Note that, when the gate capacitance of the first adjustment-switching device 524 is high, the first adjustment-switching device 524 can be maintained to be on even without the capacitor 5251.

The drain of the first adjustment-switching device 524 is connected to the gate of the switching device 541, and the source of the same is connected to the ground potential GND. Thus, in response to the turning on of the first adjustment-switching device 524, charge at the gate of the switching device 541 is drawn out. At this time, charge in the capacitor 515 is also drawn out. Thus, the gate-source voltage Vgs of the switching device 541 decreases.

The induced current Id2 increases the gate-source voltage of the first adjustment-switching device 524 to turn on the first adjustment-switching device 524. Thus, the gate charge of the switching device 541 and the charge in the capacitor 515 are drawn out, and the voltage Vgs is caused to fall. This causes the switching device 541 to be turned off.

That is, by being supplied with the second pulse signal Sp2 a plurality of times from the pulse supply circuit 503, the adjustment circuit 502 turns off the switching device 541, and brings the switching unit 504 into a non-conducting state. In this way, by the provision of the adjustment circuit 502, the switching unit 504 is switched to the non-conducting state after the control signal DIN has been switched from Hi level to Lo level.

As described above, use of the isolation switch 500 helps protect the primary circuit by cutting off the current that flows through the secondary circuit into the primary circuit, and helps switch the switching unit 504 to the conducting state and the non-conducting state according to the control signal DIN.

The isolation switch 500 having the configuration in which the isolation devices that utilize magnetic coupling are used causes less deterioration of signals to be transmitted due to fouling, aging, and the like than that in a case where isolation devices utilizing optical signals, such as photocouplers, are used. Thus, the isolation switch 500 having the configuration disclosed herein is capable of being stably opened and closed for a long period. Moreover, the isolation switch 500 is stably operable even on sites that are exposed to external light.

### First Modification

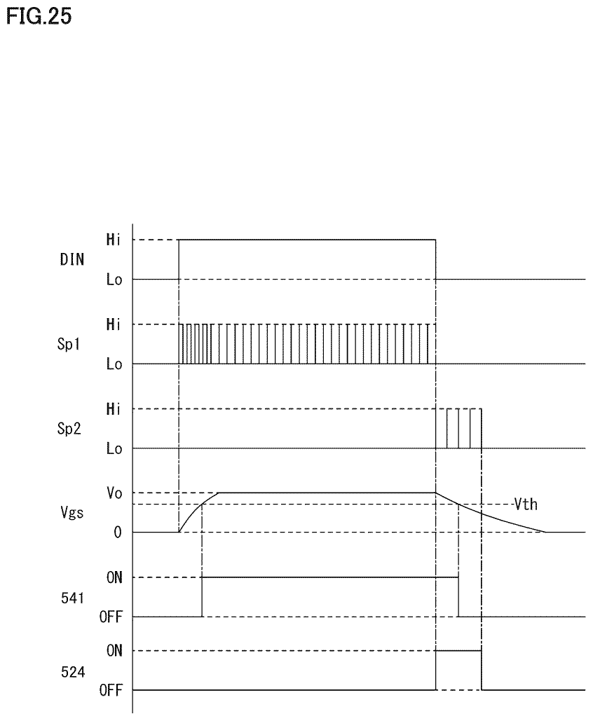

FIG. 25 is a timing chart showing the operation of the isolation switch 500 of a first modification. The isolation switch 500 of the first modification has the same configuration as that of the isolation switch 500 shown in FIG. 23. Thus, no description will be given of the elements denoted by the same reference symbols as those for the isolation switch 500. While the control signal DIN is at Lo level, the gate-source voltage Vgs of the switching device 541 of the switching unit 504 is 0 V, and it takes time to reach the threshold Vth at which the switching device 541 is turned on. Preferably, in the isolation switch 500, after the control signal DIN has been switched from Lo level to Hi level, the switching unit 504 is brought into the conducting state as promptly as possible.

Thus, in the isolation switch 500 of the first modification, the pulse supply circuit 503 outputs the first pulse signal Sp1 at a first frequency for a certain period after the time point when the control signal DIN is switched from Lo level to Hi level. Then, after a lapse of the certain period, the pulse supply circuit 503 outputs the first pulse signal Sp1 at a second frequency lower than the first frequency. In this way, the pulse supply circuit 503 supplies the first pulse signal Sp1 at the higher frequency for the certain period after the time point when the control signal DIN is switched from Lo level to Hi level. This helps promptly increase the gate-source voltage Vgs.

Thus, the switching unit 504 can be promptly switched to the conducting state after the time point when the control signal DIN is switched from Lo level to Hi level. Moreover, after the switching unit 504 has been switched to the conducting state, the frequency of the first pulse signal Sp1 is reduced. In the pulse supply circuit 503, power consumption increases when the frequency of the pulse signal to be output (in the chart, the first pulse signal Sp1) is high. As disclosed herein, by the configuration in which the first pulse signal Sp1 is output at the higher frequency only in a limited period since the rising of the voltage Vgs, power consumption can be suppressed more than in a case where the first pulse signal Sp1 continues to be output at a high frequency. That is, according to the isolation switch 500 of this modification, it is possible to provide an isolation switch with suppressed power consumption and satisfactory response characteristics.

Note that, the frequency of the second pulse signal Sp2 may be adjusted so that a period until the switching unit 504 is brought into the non-conducting state after the time point when the control signal DIN is switched from Hi level to Lo level is close to a period until the switching unit 504 is brought into the conducting state after the time point when the control signal DIN is switched from Lo level to Hi level.

### Second Modification

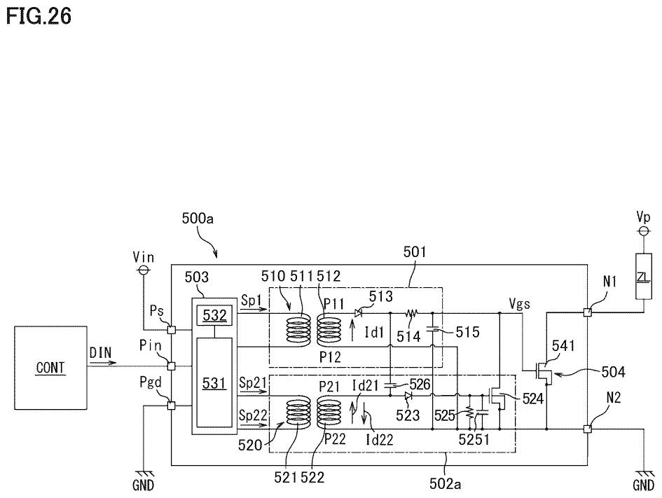

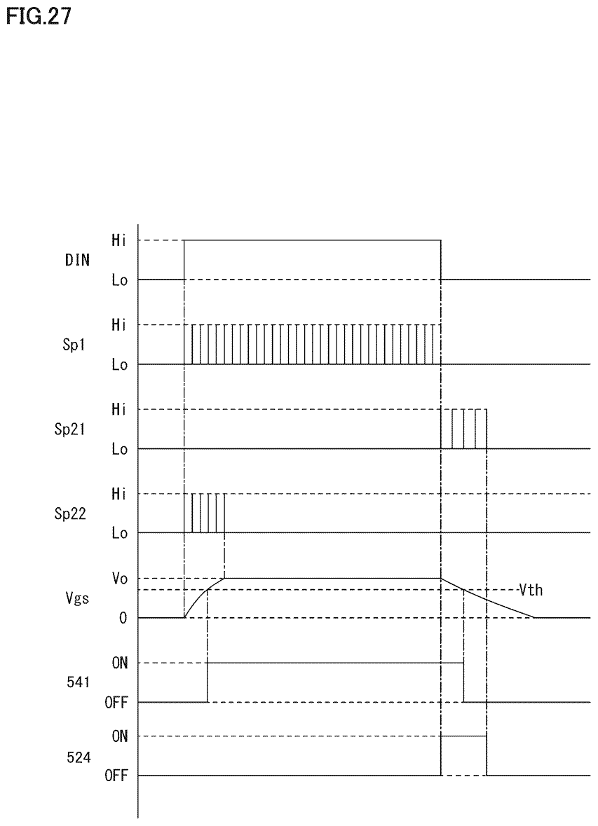

FIG. 26 is a schematic circuit diagram of an isolation switch 500a of a second modification. FIG. 27 is a timing chart showing the operation of the isolation switch 500a of the second modification. The isolation switch 500a of the second modification shown in FIG. 26 has a configuration similar to that of the isolation switch 500 shown in FIG. 23 except that its adjustment circuit 502a is different from the adjustment circuit 502 of the isolation switch 500. Thus, parts that are substantially the same as those of the isolation switch 500 shown in FIG. 23 among the elements of the isolation switch 500a shown in FIG. 26 are denoted by the same reference symbols, and no description will be given of the same parts.

As shown in FIG. 26, the adjustment circuit 502a of the isolation switch 500a includes a capacitor 526 that is disposed to link the anode of the diode 523 of the adjustment circuit 502a and the cathode of the diode 513 of the conduction circuit 501 to each other.

Moreover, in the isolation switch 500a, the pulse supply circuit 503 is configured to supply a second pulse signal Sp21 and a second pulse signal Sp22 to the second isolation device 520. The second pulse signal Sp21 is a pulse signal that generates an induced current Id21 from the second terminal P22 toward the first terminal P21 of the second secondary coil 522. On the other hand, the second pulse signal Sp22 generates an induced current Id22 from the first terminal P21 toward the second terminal P22 in the second secondary coil 522.

In the isolation switch 500a, the pulse supply circuit 503 supplies the second pulse signal Sp22 to the second primary coil 521. At this time, in the second secondary coil 522, magnetic force is applied to generate the induced current Id22 from the first terminal P21 to the second terminal P22. The direction in which the induced current Id22 flows is opposite to that of the diode 523, and hence current does not flow through the adjustment circuit 502a. Thus, the potential on the anode side of the diode 523 decreases. As a result, the potential on the cathode side of the diode 513 of the conduction circuit 501 is reduced via the capacitor 526. This helps a forward voltage to be supplied to the diode 513, and the current to flow in the forward direction of the diode 513. The adjustment circuit 502a is configured to help the current to flow in the forward direction of the diode 513 of the conduction circuit 501 by the supplying of the second pulse signal Sp22 to the adjustment circuit 502a.

Moreover, while the second pulse signal Sp22 is supplied to the second isolation device 520, the first pulse signal Sp1 is supplied to the first isolation device 510. That is, the induced current Id1 according to the first pulse signal Sp1 flows through the conduction circuit 501. The induced current Id1 is the current that flows in the forward direction of the diode 513, and the induced current Id1 is assisted to flow in the forward direction of the diode 513 by the operation of the adjustment circuit 502a.

Next, the operation of the isolation switch 500a will be described. As shown in FIG. 27, in response to the switching of the control signal DIN from Lo level to Hi level, the pulse supply circuit 503 supplies the first pulse signal Sp1 to the first primary coil 511. Moreover, concurrently with the supplying of the first pulse signal Sp1, the pulse supply circuit 503 supplies the second pulse signal Sp22 to the second primary coil 521.

Thus, in the first secondary coil 512 of the conduction circuit 501, the induced current Id1 in a direction in which the induced current Id1 is supplied to the gate of the switching device 541 of the switching unit 504 is generated. Moreover, the second secondary coil 522 of the adjustment circuit 502a operates to generate the induced current Id22. Thus, the potential on the anode side of the diode 523 decreases. As a result, the voltage in the forward direction of the diode 513 of the conduction circuit 501 increases to shorten a time until the current starts to flow through the diode 513. Then, the rate at which the gate-source voltage Vgs rises increases, and a period until the switching device 541 is turned on since the control signal DIN has been switched from Lo level to Hi level can be shortened.

Note that, in the conduction circuit 501, as the induced current Id1 continues to flow through the diode 513 longer, the forward voltage of the diode 513 becomes higher. The diode 513 has characteristics that allows current to easily flow therethrough in its forward direction under a state in which the forward voltage is at a certain level or higher. Thus, in the isolation switch 500a, the adjustment circuit 502a assists the conduction circuit 501 at least until the current in the forward direction of the diode 513 starts to easily flow. In this way, since the operation of the conduction circuit 501 is assisted with the adjustment circuit 502a, the time until the switching unit 504 is brought into the conducting state since the control signal DIN has been switched from Lo level to Hi level can be shortened. That is, the response characteristics of the isolation switch 500a can be enhanced. Note that, a period during which the second pulse signal Sp22 is supplied by the pulse supply circuit 503 is short, and hence an increase in power consumption of the isolation switch 500a can be suppressed.

### Third Modification

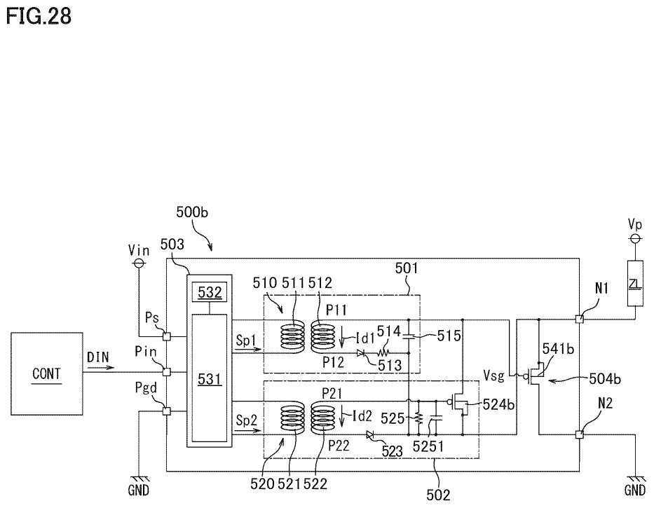

FIG. 28 is a schematic circuit diagram of an isolation switch 500b of a third modification. The switching unit 504b of the isolation switch 500b shown in FIG. 28 is different from the switching unit 504 of the isolation switch 500. Moreover, the first adjustment-switching device 524 is replaced with a first adjustment-switching device 524b. Furthermore, although unvaried in shape, the first isolation device 510 is configured so that the induced current Id1 to be generated in the first secondary coil 512 of the first isolation device 510 flows in the opposite direction, and the diode 513 and the resistor 514 are also changed in disposition according to the direction of the induced current Id1. Likewise, although unvaried in shape, the second isolation device 520 is configured so that the induced current Id2 to be generated in the second secondary coil 522 of the second isolation device 520 flows in the opposite direction, and the diode 523 is also changed in disposition according to the direction of the induced current Id2. Other features of the isolation switch 500b are the same as those of the isolation switch 500. Thus, no detailed description will be given of substantially the same configuration of the isolation switch 500b as that of the isolation switch 500, the same configuration being denoted by the same reference symbols.

As shown in FIG. 28, the isolation switch 500b includes a switching device 541b that is constituted by a p-channel MOS transistor. The source of the switching device 541b is connected to the first terminal N1, and the drain of the same is connected to the second terminal N2. Moreover, the conduction circuit 501 is configured so that the induced current Id1 to be generated in the first secondary coil 512 of the first isolation device 510 causes the current to be drawn out via the gate of the switching device 541b.

The current is drawn out via the gate by the induced current Id1, and the capacitor 515 is charged. Thus, a voltage Vsg of the gate with respect to the source is pulled down. Then, in response to exceeding of an absolute value of the voltage Vsg above the threshold Vth, the switching device 541b is turned on. In this way, the first terminal N1 and the second terminal N2 are brought into the conducting state, and the power voltage Vp is supplied to the load ZL, and the load ZL is brought into an operating state. Note that, the threshold Vth is a voltage value at which the p-channel MOS transistor is turned on, and may be different from a voltage value at which the n-channel MOS transistor is turned on.

Moreover, as shown in FIG. 28, the isolation switch 500b includes the first adjustment-switching device 524b that is constituted by a p-channel MOS transistor. The source of the first adjustment-switching device 524b is connected to the first terminal N1, and the drain of the same is connected to the gate of the switching device 541b. Then, the induced current Id2 to be generated in the second secondary coil 522 of the second isolation device 520 causes the first adjustment-switching device 524b to be turned on. In response to the turning on of the first adjustment-switching device 524b, current flows into the gate of the switching device 541b of the switching unit 504b. Then, every time the first adjustment-switching device 524b is turned on, a certain amount of the current flows to pull up the voltage Vsg of the gate with respect to the source. In this way, the switching device 541b is switched off. Note that, the second terminal P22 of the second secondary coil 522 is connected not to the second terminal N2 but to the first terminal N1.

As described above, even when the isolation switch 500b has the configuration in which the switching unit 504b uses the switching device 541b that includes a p-channel MOS transistor, the isolation switch 500b is capable of operating as in the case of using the switching device 541 including an n-channel MOS transistor.

### Fourth Modification

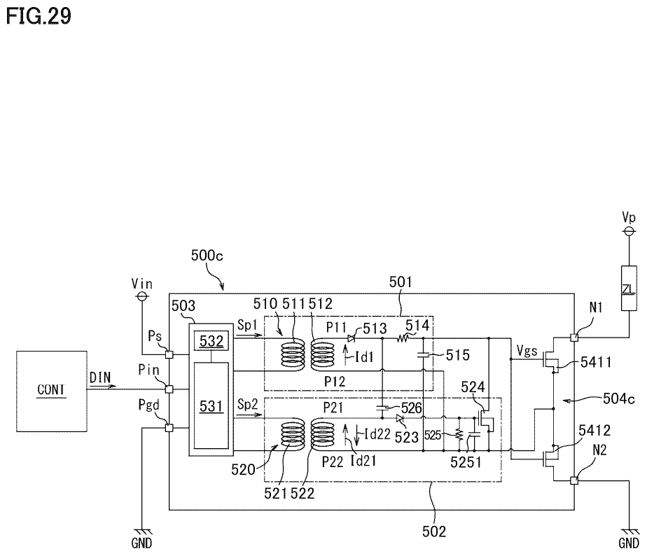

FIG. 29 is a schematic circuit diagram of an isolation switch 500c of a fourth modification. In the isolation switch 500c of the fourth modification, the configuration of a switching unit 504c is different from that of the switching unit 504 of the isolation switch 500. Other parts of the isolation switch 500c are the same as those of the isolation switch 500. Thus, no detailed description will be given of substantially the same parts of the isolation switch 500c as those of the isolation switch 500, the same parts being denoted by the same reference symbols.

As shown in FIG. 29, the switching unit 504c of the isolation switch 500c has the configuration in which a first switching device 5411 and a second switching device 5412 are connected in series. Moreover, the first switching device 5411 and the second switching device 5412 are both n-channel MOS transistors.

The drain of the first switching device 5411 is connected to the first terminal N1. The source of the first switching device 5411 and the source of the second switching device 5412 are connected to each other. The drain of the second switching device 5412 is connected to the second terminal N2. Moreover, the gate of the first switching device 5411 and the gate of the second switching device 5412 are connected to each other.

Furthermore, in the conduction circuit 501, the first terminal P11 of the first secondary coil 512 of the first isolation device 510 is connected to a connection node to which the gates of the first switching device 5411 and the second switching device 5412 are connected. Still furthermore, the second terminal P12 is connected to a connection node to which the sources of both the switching devices 5411 and 5412 are connected.

Such a configuration helps the induced current Id1 that is generated in the first primary coil 511 to flow into the gate of the first switching device 5411 and the gate of the second switching device 5412. Thus, the gate-source voltages Vgs of the first switching device 5411 and the second switching device 5412 is increased. As a result, the first switching device 5411 and the second switching device 5412 are turned on to bring the first terminal N1 and the second terminal N2 into the conducting state.

In the adjustment circuit 502, the induced current Id21 causes the first adjustment-switching device 524 to be turned on. In response to the turning on of the first adjustment-switching device 524, current is drawn out via the gates of the first switching device 5411 and the second switching device 5412. In this way, the first switching device 5411 and the second switching device 5412 are controlled to turn off.

In the configuration of the switching unit 504c, the first terminal P11 of the first secondary coil 512 are connected to the gates of both the first switching device 5411 and the second switching device 5412. Moreover, the second terminal P12 of the first secondary coil 512 is connected to the sources of the first switching device 5411 and the second switching device 5412. Thus, in the isolation switch 500c, regardless of which of voltages at the first terminal N1 and the second terminal N2 is higher, the power voltage Vp can be supplied to the load ZL. Such a configuration helps enhance versatility of the isolation switch 500c.

Note that, in this modification, n-channel MOS transistors need not necessarily be used as both the switching devices of the switching unit 504c, and p-channel MOS transistors may be used as both. In this case, the diodes 513 and 523 are installed in opposite directions.

### Fifth Modification

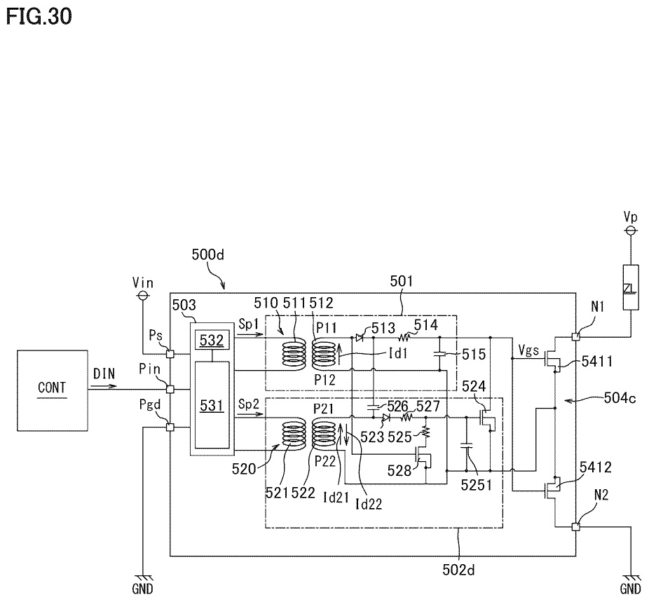

FIG. 30 is a schematic circuit diagram of an isolation switch 500d of a fifth modification. In the isolation switch 500d of the fifth modification, an adjustment circuit 502d is different from the adjustment circuit 502 in including a resistor 527 and a second adjustment-switching device 528. Other features of the configuration are the same as those of the configuration of the isolation switch 500c of the fourth modification shown in FIG. 29. Thus, no detailed description will be given of substantially the same parts of the isolation switch 500d as those of the isolation switch 500c, the same parts being denoted by the same reference symbols. Moreover, the first adjustment-switching device 524 of the isolation switch 500d shown in FIG. 30 has the same configuration as that of the first adjustment-switching device 524 of the isolation switch 500c shown in FIG. 29. Thus, no detailed description will be given of the configuration of the first adjustment-switching device 524. The first adjustment-switching device 524 is connected in parallel to the first secondary coil 512.

As shown in FIG. 30, the resistor 527 is disposed between the diode 523 and the first adjustment-switching device 524. The resistor 527 and the capacitor 5251 constitute a smoothing circuit that smooths the induced current Id21 to be generated according to the second pulse signal Sp2, and thereby generates a voltage that causes the first adjustment-switching device 524 to be turned on. The induced current Id21 causes the first adjustment-switching device 524 to be turned on.

The second adjustment-switching device 528 is connected in series with the resistor 525. Moreover, the second adjustment-switching device 528 is connected in parallel to the second secondary coil 522. The second adjustment-switching device 528 is an n-channel MOS transistor, and its source is connected to the second terminal P22 of the second secondary coil 522. Note that, the second terminal P22 of the second secondary coil 522 is a terminal to serve as a negative electrode side while the induced current Id21 flows. Moreover, the drain of the second adjustment-switching device 528 is connected between the resistor 527 and the gate of the first adjustment-switching device 524 via the resistor 525. Furthermore, the gate of the second adjustment-switching device 528 is connected between the first terminal P11 of the first secondary coil 512 and the anode of the diode 513.

Such a configuration allows the second adjustment-switching device 528 to be turned on by the induced current Id1 that is induced by the first secondary coil 512 under the state in which the first pulse signal Sp1 has been supplied to the first primary coil 511.

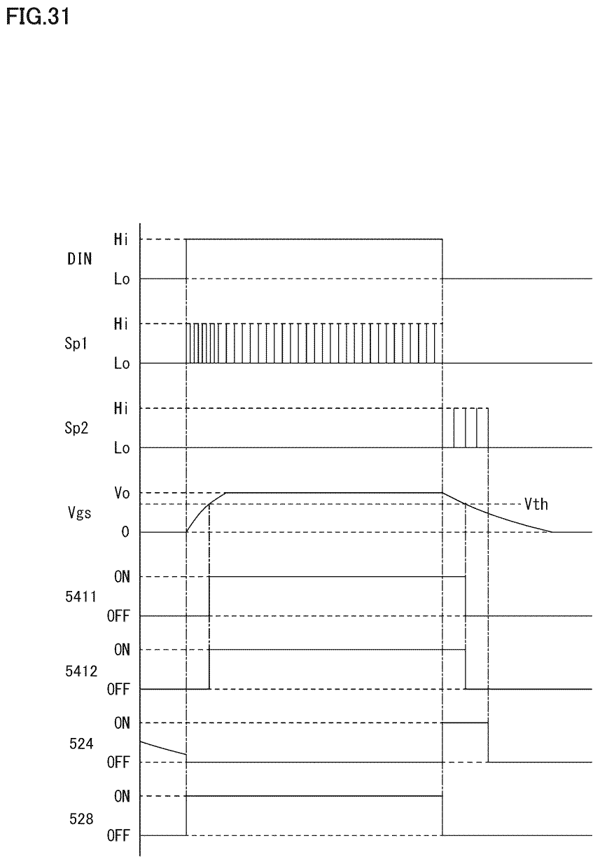

The isolation switch 500d of the fifth modification has the configuration described above. FIG. 31 is a timing chart showing the operation of the isolation switch 500d of the fifth modification. As shown in FIG. 31, in the isolation switch 500d, in response to the switching of the control signal DIN from Lo level to Hi level, the first pulse signal Sp1 is supplied to the first primary coil 511. Thus, the induced current Id1 is generated in the first secondary coil 512 to raise the voltage Vgs.

As shown in FIG. 31, the second adjustment-switching device 528 is turned on by the induced current Id1 induced by the first secondary coil 512. In response to the turning on of the second adjustment-switching device 528, current is drawn out via the gate of the first adjustment-switching device 524. In this way, the first adjustment-switching device 524 is turned off. As shown in FIG. 31, under the state in which the control signal DIN is at Lo level, even when a gate voltage of the first adjustment-switching device 524 has slowly decreased, the current is drawn out in response to the turning on of the second adjustment-switching device 528, and hence the gate voltage falls to off.

That is, in the isolation switch 500d, under the state in which the first pulse signal Sp1 has been supplied to the first primary coil 511, the second adjustment-switching device 528 is turned on by the induced current Id1 that is induced by the first secondary coil 512. In response to the turning on of the second adjustment-switching device 528, current is drawn out via the gate of the first adjustment-switching device 524, and the first adjustment-switching device 524 is turned off. Thus, the voltage Vgs rises under the state in which the first adjustment-switching device 524 has been turned off, and hence the rate at which the voltage Vgs rises increases.

As a result, a time until the first switching device 5411 and the second switching device 5412 are turned on can be shortened, and the isolation switch 500d is switched to the conducting state within a short time after the control signal DIN has been switched from Lo level to Hi level. In this way, the power voltage Vp is applied to the load ZL.

Note that, the operation at the time when the second pulse signal Sp2 is supplied to the second primary coil 521 is the same as those, for example, in the isolation switch 500.

### Sixth Modification

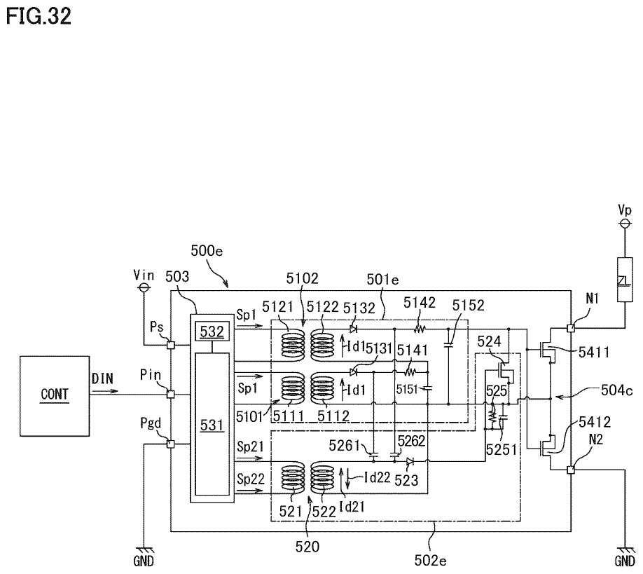

FIG. 32 is a schematic circuit diagram of an isolation switch 500e of a sixth modification. In the isolation switch 500e of the sixth modification, a conduction circuit 501e and an adjustment circuit 502e are different from the conduction circuit 501 and the adjustment circuit 502 of the isolation switch 500 shown in FIG. 23. Moreover, the switching unit 504c has the same configuration as that of the switching unit 504c of the isolation switch 500c shown in FIG. 29. Other parts of the isolation switch 500e have the same configurations as those of the isolation switch 500. Thus, no detailed description will be given of substantially the same parts of the isolation switch 500e as those of the isolation switch 500, the same parts being denoted by the same reference symbols.

As shown in FIG. 32, the conduction circuit 501e of the isolation switch 500e includes a first isolation device 5101 and a first isolation device 5102. The first isolation device 5101 includes a first primary coil 5111 and a first secondary coil 5112. Likewise, the first isolation device 5102 includes a first primary coil 5121 and a first secondary coil 5122. The first primary coil 5111 and the first primary coil 5121 are connected to the pulse supply circuit 503, and have the same configuration as that of the first primary coil 511 of the isolation switch 500 shown in FIG. 23.

In the conduction circuit 501e, the first secondary coil 5112 and the first secondary coil 5122 are connected in series. The first pulse signal Sp1 is supplied to both the first primary coil 5111 and the first primary coil 5121. The induced currents Id1 to be generated in the first secondary coil 5112 and the first secondary coil 5122 are in the same direction. That is, the induced current Id1 generated in each of the first secondary coils 5112 and 5122 flows to the gates of the first switching device 5411 and the second switching device 5412.

A diode 5131, a resistor 5141, and a capacitor 5151 are connected to the first secondary coil 5112. The diode 5131, the resistor 5141, and the capacitor 5151 have configurations similar to those of the diode 513, the resistor 514, and the capacitor 515 of the isolation switch 500a shown in FIG. 26. Thus, no detailed description will be given of those elements. Likewise, a diode 5132, a resistor 5142, and a capacitor 5152 are connected to the first secondary coil 5122. The diode 5132, the resistor 5142, and the capacitor 5152 have configurations similar to those of the diode 513, the resistor 514, and the capacitor 515 of the isolation switch 500a shown in FIG. 26.

The capacitor 5151 is a smoothing capacitor that is connected between the cathode of the diode 5131 and the second terminal of the second secondary coil 5112, and that smooths current to be output from the diode 5131. Likewise, the capacitor 5152 is a smoothing capacitor that is connected to the cathode of the diode 5132 and the second terminal of the second secondary coil 5112, and that smooths current to be output from the diode 5132.

The capacitor 5151 maintains a terminal-to-terminal voltage across the first secondary coil 5112 while the induced current Id1 flows. Likewise, the capacitor 5152 maintains a terminal-to-terminal voltage across of the first secondary coil 5122 while the induced current Id1 flows. Since the first secondary coil 5112 and the first secondary coil 5122 are in series, the induced currents Id1 to be generated in both the coils flow into the switching devices 5411 and 5412 of the switching unit 504c. Thus, periods until the switching devices 5411 and 5412 are turned on are shorter than in the case where one coil is provided.

On the other hand, the adjustment circuit 502e includes a capacitor 5261 and a capacitor 5262 connected to the first terminal P21 of the second secondary coil 522. Like the capacitor 526 of the isolation switch 500a shown in FIG. 26, the capacitors 5261 and 5262 assist forward voltages of the diode 5131 and the diode 5132 to increase. This also shortens the periods until the switching devices 5411 and 5412 of the switching unit 504c are turned on.

In this way, the conduction circuit 501e includes the two first isolation devices 5101 and 5102, and their respective first secondary coils 5112 and 5122 are connected in series. Thus, response characteristics of the isolation switch 500e can be enhanced. Note that, the two first isolation devices 5101 and 5102 need not necessarily be used as in the configuration example described in this modification, and three or more first isolation devices may be used.

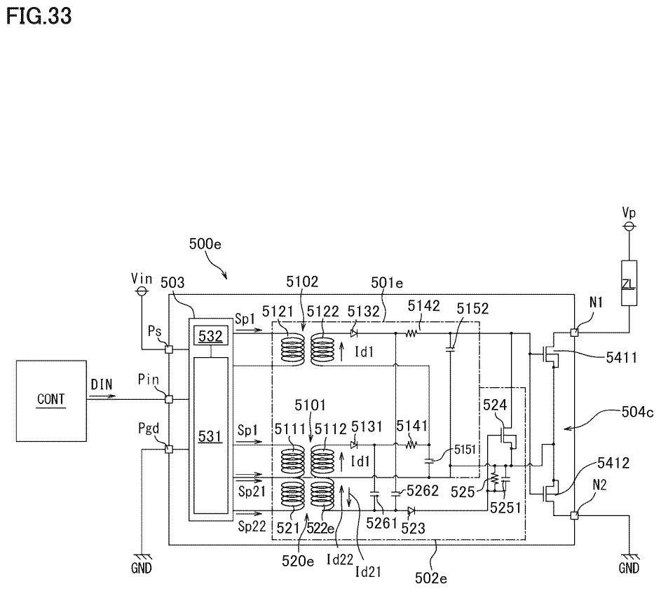

As shown in FIG. 32, the second terminal of the first secondary coil 5112 and the second terminal of the second secondary coil 522 are both connected to wirings that are connected to a connection node between the sources of the first switching device 5411 and the second switching device 5412. In this context, as shown in FIG. 33, the wiring that connects the second terminal of the first secondary coil 5112 and the connection node between the sources of the first switching device 5411 and the second switching device 5412 to each other, and a wiring that connects the second terminal of a second secondary coil 522e and the connection node may be integrated with each other. This helps simplify the wirings. Note that, FIG. 33 is a schematic circuit diagram showing another configuration example of the isolation switch 500e of this modification.

As shown in FIG. 33, when the wirings are integrated, a winding direction of the second secondary coil 522e is opposite to a winding direction of the first secondary coil 5112. Moreover, when the adjustment circuit 502e assists the conduction circuit 501e, the pulse supply circuit 503 supplies the second pulse signal Sp21 to the second primary coil 521 so that the direction of the induced current Id22 is the same as that of the induced current Id1. Furthermore, when the second pulse signal Sp22 is supplied to the second primary coil 521 so that the induced current Id21 flows, wirings to be connected to the first primary coils 5111 and 5121 are controlled to have high impedance.

In this modification, although the first primary coils 5111 and 5121 are provided independently of each other, they may be integrated with each other.

### Seventh Modification

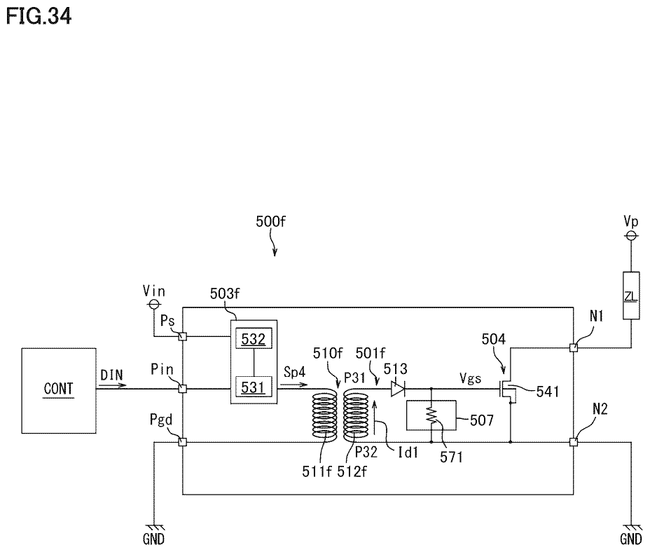

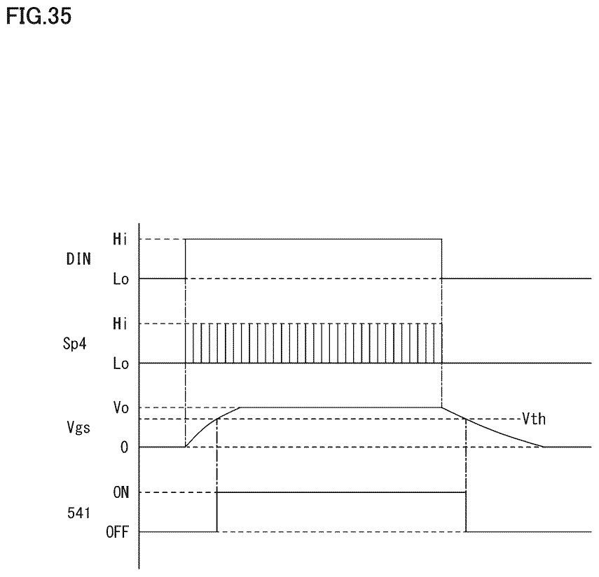

FIG. 34 is a schematic circuit diagram of an isolation switch 500f of a seventh modification. FIG. 35 is a timing chart showing the operation of the isolation switch 500f of the seventh modification. In the isolation switch 500f of the seventh modification, a first isolation device 510f is configured to double as the second isolation device 520, and a conduction circuit 501f, an adjustment circuit 507, and a pulse supply circuit 503f are different from the conduction circuit 501, the adjustment circuit 502, and the pulse supply circuit 503 of the isolation switch 500 shown in FIG. 23. Other parts of the isolation switch 500f have the same configurations as those of the isolation switch 500. Thus, no detailed description will be given of substantially the same parts of the isolation switch 500f as those of the isolation switch 500, the same parts being denoted by the same reference symbols.

As shown in FIG. 34, the first isolation device 510f includes a first primary coil 511f and a first secondary coil 512f. As shown in FIG. 35, the pulse supply circuit 503f is configured to be capable of supplying only a pulse signal Sp4 to the first primary coil 511f of the first isolation device 510f. That is, the pulse supply circuit 503f is connected only to the first terminal of the first primary coil 511f, and is configured to be capable of supplying the pulse signal Sp4 to this first terminal. Note that, the first isolation device 510f is configured to allow current to flow through the first secondary coil 512f from a second terminal p32 to a first terminal P31 in response to the supplying of the pulse signal Sp4 to the first primary coil 511f.

As shown in FIG. 34, the adjustment circuit 507 of the isolation switch 500f has a configuration in which a resistor 571 is disposed between the gate and the source of the switching device 541 of the switching unit 504.

As shown in FIG. 35, in response to the switching of the control signal DIN from Lo level to Hi level, the pulse supply circuit 503f outputs the pulse signal Sp4. The pulse signal Sp4 is supplied to the first primary coil 511f, and the induced current Id1 is generated in the first secondary coil 512f. The direction in which the induced current Id1 flows is the same as the forward direction of the diode 513. Thus, the induced current Id1 flows to the gate of the switching device 541 of the switching unit 504, and the gate-source voltage Vgs increases. In response to the exceeding of the gate-source voltage Vgs above the threshold Vth, the switching device 541 is turned on to bring the first terminal N1 and the second terminal N2 into the conducting state. In this way, the power voltage Vp is supplied to the load ZL.

Moreover, in response to the switching of the control signal DIN from Hi level to Lo level, the pulse supply circuit 503f stops supplying the pulse signal Sp4. Thus, the induced current Id1 is stopped being supplied to the gate of the switching device 541. On the other hand, the gate of the switching device 541 is connected to the ground potential GND via the resistor 571 of the adjustment circuit 507. Thus, the current is drawn out via the gate of the switching device 541 to the ground potential via the resistor 571. As a result, a gate voltage of the switching device 541 decreases. Then, in response to the decreasing of the gate voltage of the switching device 541 to the threshold Vth or less, the switching device 541 is turned off, and the first terminal N1 and the second terminal N2 are brought into the non-conducting state. As a result, the power voltage Vp is stopped being supplied to the load ZL, and the load ZL is stopped.

As described above, in the isolation switch 500f, the adjustment circuit 507 is constituted only by the resistor 571, and hence the circuit configuration is simplified.

### <Uses>

The isolation switches described previously are usable not only as one of switches of PLCs (Programable Logic Controllers) and the like, but also as switches in which the primary side and the secondary side need be isolated from each other.

### Isolation Switch (Additional Embodiment)

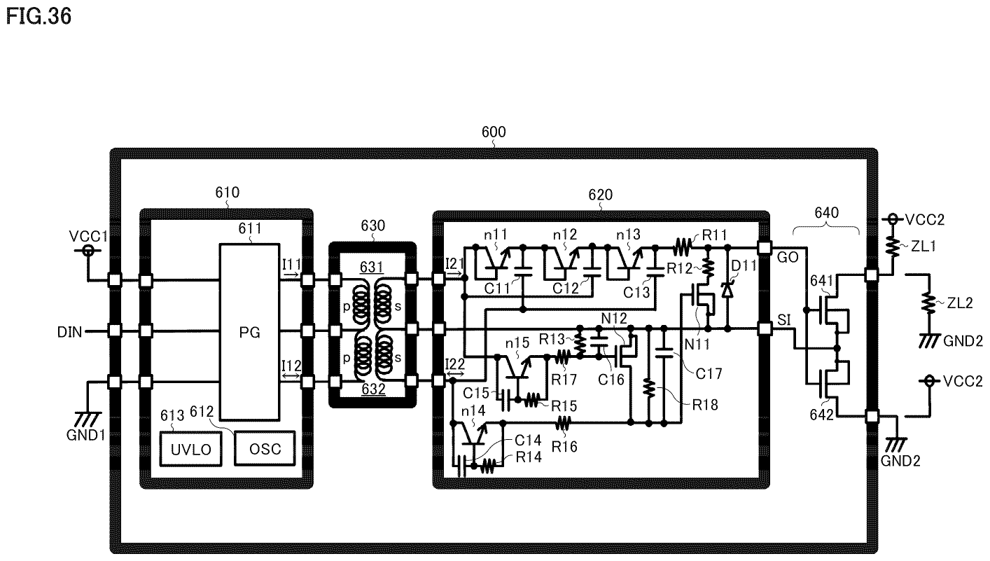

FIG. 36 is a diagram showing an additional embodiment of the isolation switches. An isolation switch 600 of this embodiment includes a first chip 610, a second chip 620, a third chip 630, and a switching circuit 640. The first chip 610, the second chip 620, the third chip 630 may be sealed in a single package.

In the first chip 610, for example, a pulse generating circuit 611, an oscillator circuit 612, and an UVLO [under voltage locked out] circuit 613 are integrated.

The pulse generating circuit 611 generates pulse signals I11 and I12 according to the logic level of the control signal DIN to be input from the outside. For example, under the state in which the control signal DIN is at high level, the pulse generating circuit 611 generates the pulse signal I11. On the other hand, under the state in which the control signal DIN is at low level, the pulse generating circuit 611 generates the pulse signal I12. Note that, the pulse generating circuit 611 corresponds to the pulse generating circuit 531 described previously. The pulse signals I11 and I12 correspond respectively to the first pulse signal Sp1 (Sp21) and the second pulse signal Sp2 (Sp22) described previously.

The oscillator circuit 612 supplies clock signals to the pulse generating circuit 611. The pulse signals I11 and I12 are pulse-driven in synchronization with the clock signals to be output from the oscillator circuit 612. Note that, the oscillator circuit 612 corresponds to the oscillator circuit 532 described previously.

The UVLO 613 is a type of malfunction protection circuit. Specifically, in response to falling of the supply voltage VCC1 to be supplied to the first chip 610 below a UVLO detection threshold, the UVLO 613 brings units (including the pulse generating circuit 611 and the oscillator circuit 612) in the first chip 610 into non-operating states. On the other hand, in response to exceeding of the supply voltage VCC1 above an UVLO cancellation threshold, the UVLO 613 brings the units in the first chip 610 into operating states.

In the second chip 620, for example, transistors n11 to n15 (e.g., npn bipolar transistors), transistors N11 and N12 (e.g., N-channel MOS field-effect transistors), capacitors C11 to C17, resistors R11 to R18, and a Zener diode D11 are integrated.

The base and the collector of the transistor n11 are connected to the first output terminal of the third chip 630 (corresponding to the first terminal of a secondary coil 631s described below). All the emitter of the transistor n11 and the base and the collector of the transistor n12 are connected to the first terminal of the capacitor C11. All the emitter of the transistor n12 and the base and the collector of the transistor n13 are connected to the first terminal of the capacitor C12. The emitter of the transistor n13 and the first terminal of the resistor R11 are both connected to the first terminal of the capacitor C13.

The second terminal of the capacitor C12 is connected to the first output terminal of the third chip 630. The respective second terminals of the capacitors C11 and C13 are connected to the second output terminal of the third chip 630 (corresponding to the first terminal of a secondary coil 632s).

All the second terminal of the resistor R11, the first terminal of the resistor R12, and the cathode of the Zener diode D11 are connected to an application terminal for an output pulse signal GO (corresponding to a control terminal of the switching circuit 640). The second terminal of the Zener diode D11 is connected to an application terminal for a reference voltage SI. The second terminal of the resistor R12 is connected to the drain of the transistor N11. The source and the backgate of the transistor N11 are both connected to the application terminal for the reference voltage SI.

The collector of the transistor n14 and the first terminal of the capacitor C14 are both connected to the second output terminal of the third chip 630. The base of the transistor n14 is connected to the second terminal of the capacitor C14 and the first terminal of the resistor R14. The emitter of the transistor n14 and the second terminal of the resistor R14 are both connected to the first terminal of the resistor R16. The second terminal of the resistor R16 is connected to the gate of the transistor N11.

The collector of the transistor n15 and the first terminal of the capacitor C15 are both connected to the first output terminal of the third chip 630. The base of the transistor n15 is connected to the second terminal of the capacitor C15 and the first terminal of the resistor R15. The emitter of the transistor n15 and the second terminal of the resistor R15 are both connected to the first terminal of the resistor R17.

All the respective first terminals of the resistors R13 and R18, the respective first terminals of the capacitors C16 and C17, and the source and the backgate of the transistor N12 are connected to the application terminal for the reference voltage SI. All the respective second terminals of the resistors R13 and R17 and the capacitor C16 are connected to the gate of the transistor N12. All the respective second terminals of the resistor R18 and the capacitor C17 and the drain of the transistor N12 are connected to the gate of the transistor N11.

The third chip 630 corresponds to an isolation circuit for transmitting the pulse signals I11 and I12 of the first chip 610 as pulse signals of the second chip 620 (induced currents I21 and I22) while electrically isolating between the first chip 610 and the second chip 620.

In terms of what is shown in the diagram, isolation devices 631 and 632 are integrated in the third chip 630. The isolation device 631 may be a transformer including a primary coil 631p to which the pulse signal I11 is applied, and the secondary coil 631s which is electromagnetically coupled to the primary coil 631p and by which the induced current I21 is induced. The isolation device 632 may be a transformer including a primary coil 632p to which the pulse signal I12 is applied, and the secondary coil 632s which is electromagnetically coupled to the primary coil 632p and by which the induced current I22 is induced. The respective second terminals of the secondary coils 631s and 632s are both connected to the application terminal for the reference voltage SI.

Among the elements described above, the transistors n11 to n13, the capacitors C11 to C13, the resistor R11, the Zener diode D11, and the isolation device 631 can be understood as the elements that form the conduction circuit 501 (specifically, the conduction circuit 501c) described previously.

Moreover, among the elements described above, the transistors n14 and n15, the transistors N11 and N12, the capacitors C14 to C17, and the resistors R12 to R18, and the isolation device 632 can be understood as the elements that form the adjustment circuit 502 (specifically, the adjustment circuits 502d and 502e) described previously.

The switching circuit 640 includes switching devices 641 and 642 (e.g., both are N-channel MOS field-effect transistors). Note that the switching circuit 640 corresponds to the switching unit 504 (specifically, the switching unit 504c) described previously.

All the respective sources and backgates of the switching devices 641 and 642 are connected to the application terminal for the reference voltage SI. The gates of the switching devices 641 and 642 are both connected to the application terminal for the output pulse signal GO.

In a first connection mode, the drain of the switching device 641 can be connected to an application terminal for the supply voltage VCC2 via a load ZL1, and the drain of the switching device 642 can be connected to the application terminal for the ground voltage GND2. In this case, the switching circuit 640 functions as a low-side switch.

In a second connection mode, the drain of the switching device 641 can be connected to the application terminal for the ground voltage GND2 via a load ZL2, and the drain of the switching device 642 can be connected to the application terminal for the supply voltage VCC2. In this case, the switching circuit 640 functions as a high-side switch.

Note that, the switching devices 641 and 642 correspond respectively to the first switching device 5411 and the second switching device 5412 described previously.

First, the basic operation of the isolation switch 600 will be described. In the high-level period of the control signal DIN, the pulse signal I11 is generated to drive the primary coil 631p. At this time, the secondary coil 631s generates the induced current I21 that flows in respective forward directions of the diode-connected transistors n11 to n13.

Moreover, in the high-level period of the control signal DIN, the pulse signal I12 in a first direction is generated to drive the primary coil 632p. At this time, the secondary coil 632s generates the induced current I22 that flows in the same direction as that of the induced current I21.

The induced current I21 mentioned above is rectified and smoothed via the transistors n11 to n13 and the capacitors C11 to C13. Thus, the output pulse signal GO is raised to high level. As a result, the switching devices 641 and 642 are turned on, and hence a drive current can be supplied to the load ZL1 (or the load ZL2).

Note that, while the induced current I21 flows, a gate-source voltage of the transistor N12 is elevated via the transistor n15, and hence the transistor N12 is turned on. Thus, a gate-source voltage of the transistor N11 is pulled down, and hence the transistor N11 is turned off. Therefore, the output pulse signal GO is not caused to fall to low level.

On the other hand, in the low-level period of the control signal DIN, the pulse signal I12 in a second direction (corresponding to a direction opposite to the first direction) is generated to drive the primary coil 632p. At this time, the secondary coil 632s generates the induced current I22 that flows in a direction opposite to the direction described previously, that is, in a forward direction of the diode-connected transistor n14.

While the induced current I22 flows in the direction described above, the gate-source voltage of the transistor N11 is elevated via the transistor n14, and hence the transistor N11 is turned on. Thus, the output pulse signal GO is not caused to fall to low level. As a result, the switching devices 641 and 642 are turned off, and hence the drive current is not supplied to the load ZL1 (or the load ZL2).

In this way, the isolation switch 600 is configured to be basically the same as the isolation switches 500d and 500c (FIG. 30, FIG. 32, and FIG. 33) described previously. Note that, so long as operations of main parts described below are compatible with each other, the isolation switch 600 may be configured to be basically the same as the other isolation switches 500 (FIG. 23), 500a (FIG. 26), 500b (FIG. 28), 500c (FIG. 29), and 500f (FIG. 34).

In the following description, various main parts of the isolation switch 600 according to the additional embodiment will each be described in detail.

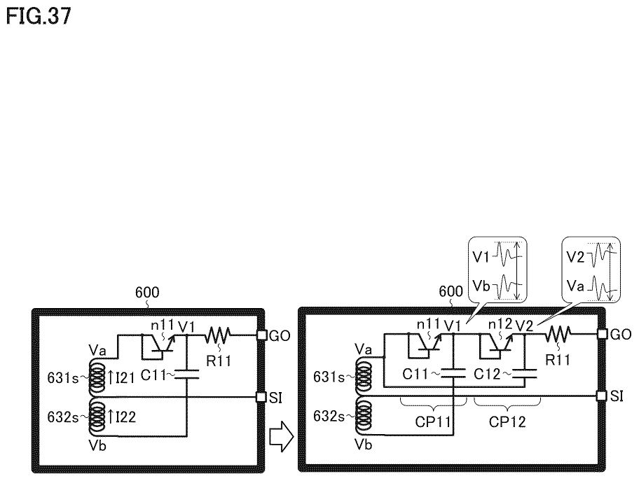

FIG. 37 is a diagram showing a first main part of the isolation switch 600 according to the additional embodiment. As described previously, the isolation switch 600 includes, as the elements that form the conduction circuit 501 (specifically, the conduction circuit 501c) described previously, the transistors n11 to n13 (e.g., npn bipolar transistors), the capacitors C11 to C13, the resistor R11, the Zener diode D11, and the isolation device 631.

Specifically, among the elements mentioned above, the transistors n11 to n13 and the capacitors C11 to C13 form voltage boosting circuits CP11 to CP1x as many as the number of stages x (note that, x is an integer number of 2 or more) connected in series between the secondary coil 631s and the control terminal of the switching circuit 640 (corresponding to the application terminal for the output pulse signal GO).

Note that, although only the voltage boosting circuits CP11 and CP12 in two stages are exemplified on the right-hand side of the diagram for convenience of description, the number of stages x of the voltage boosting circuits CP11 to CP1x is not limited at all to this example. For example, as shown in FIG. 36 referred to previously, the voltage boosting circuits CP11 to CP1x in three stages (or more) may be provided in the isolation switch 600.

Moreover, in the diagram, the diode-connected transistors n11 and n12 are exemplified as rectification devices that respectively form the voltage boosting circuits CP11 and CP12. Note that, as shown in FIG. 30, FIG. 32, FIG. 33, etc. referred to previously, diodes (Schottky diodes and the like) may be used as the rectification devices. That is, in the diode-connected transistors n11 and n12, their respective collectors correspond to anodes of diodes, and their respective emitters correspond to cathodes of the diodes. In this way, it can be understood that the “diodes” conceptually encompass also the diode-connected transistors.

Note that, the voltage boosting circuits CP11 and CP12 each operate as a rectification smoothing circuit alone (refer, for example, to the left-hand side of the diagram). However, the voltage boosting circuits CP11 and CP12 respectively have ingeniously designed circuit configurations (specifically, connection destinations of the capacitors C11 and C12) so that high level of the output pulse signal GO is pulled up.

In terms of what is shown on the right-hand side of the diagram, of the voltage boosting circuits CP11 and CP12, the voltage boosting circuit CP11 in a first stage (odd-numbered stage) includes the transistor n11 and the capacitor C11. Likewise, of the voltage boosting circuits CP11 and CP12, the voltage boosting circuit CP12 in a second stage (even-numbered stage) includes the transistor n12 and the capacitor C12.

The transistor n11 is diode-connected between the first terminal of the secondary coil 631s (corresponding to an application terminal for a node voltage Va) and the control terminal of the switching circuit 640 (corresponding to the application terminal for the output pulse signal GO) so that its forward direction is a flow direction of the induced current I21 to be generated in the secondary coil 631s. Specifically, the collector and the base of the transistor n11 are connected to the first terminal of the secondary coil 631s (corresponding to the application terminal for the node voltage Va). The emitter of the transistor n11 is connected to the application terminal for a node voltage V1.

The transistor n12 is diode-connected between the first terminal of the secondary coil 631s (corresponding to the application terminal for the node voltage Va) and the control terminal of the switching circuit 640 (corresponding to the application terminal for the output pulse signal GO) so that its forward direction is the flow direction of the induced current I21 to be generated in the secondary coil 631s. Specifically, the collector and the base of the transistor n12 are connected to the emitter of the transistor n11 (corresponding to the application terminal for the node voltage V1). The emitter of the transistor n12 is connected to an application terminal for a node voltage V2.

The capacitor C11 is connected between the emitter of the transistor n11 (corresponding to the application terminal for the node voltage V1) and the first terminal of the secondary coil 632s (corresponding to an application terminal for a node voltage Vb). The capacitor C12 is connected between the emitter of the transistor n12 (corresponding to the application terminal for the node voltage V2) and the first terminal of the secondary coil 631s (corresponding to the application terminal for the node voltage Va).

When such a circuit configuration is employed, in the voltage boosting circuit CP11 in the first stage, the signal level is elevated by utilizing a voltage difference between the node voltage V1 and the node voltage Vb. Likewise, in the voltage boosting circuit CP12 in the second stage, the signal level is elevated by utilizing a voltage difference between the node voltage V2 and the node voltage Va (corresponding to a swing-back voltage difference). As a result, the node voltage V2 is higher than the node voltage V1, and hence efficient voltage boosting can be performed.

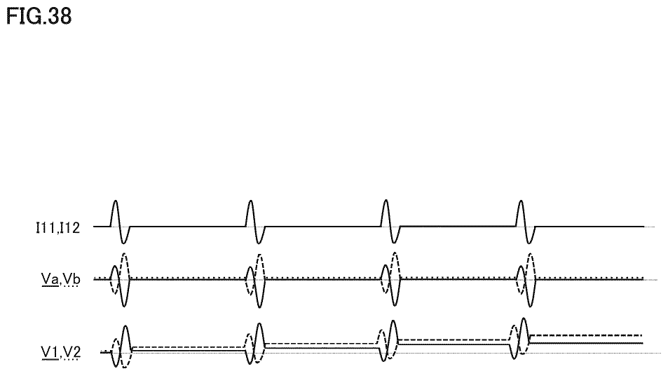

FIG. 38 is a chart showing an operation example of the first main part. Sequentially from the top of the chart, the pulse signals I11 and I12, the node voltages Va and Vb (solid line and dotted line), and the node voltages V1 and V2 (solid line and dashed line) are shown.

As shown in the chart, the node voltages V1 and V2 rise every time the pulse signals I11 and I12 are pulse-driven.

Then, the node voltage V1 gradually approximates max(Va−Vb)−Vf(n11). Note that, max(Va−Vb) is a maximum value of a voltage difference obtained by subtracting the node voltage Vb from the node voltage Va. Moreover, Vf(n11) is a forward drop voltage of the diode-connected transistor n11.

Likewise, the node voltage V2 gradually approximates V1+max(Vb−Va)−Vf(n12). Note that, max(Vb−Va) is a maximum value of a voltage difference obtained by subtracting node voltage Va from the node voltage Vb. Moreover, Vf n12) is a forward drop voltage of the diode-connected transistor n12.

Note that, it is needless to say that the node voltages Vx (i.e., high level of the output pulse signal GO) are further pulled up as the number of stages x of the voltage boosting circuits CP11 to CP1x becomes larger.

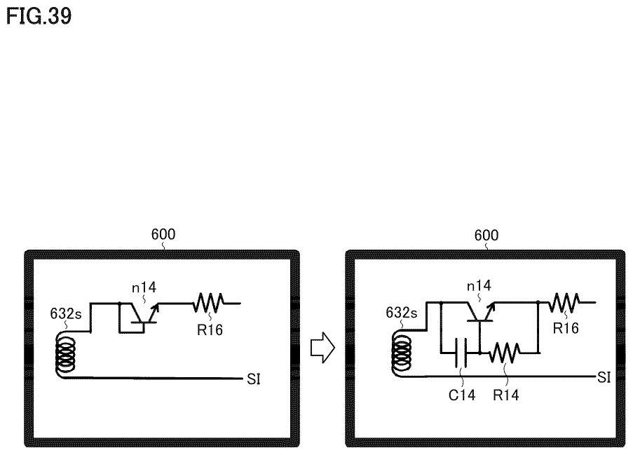

FIG. 39 is a diagram showing a second main part of the isolation switch 600 according to the additional embodiment. As described previously, the isolation switch 600 includes, as the elements that form the adjustment circuit 502 (specifically, adjustment circuits 502d and 502e) described previously, the elements n14 and n15, the transistors N11 and N12, the capacitors C14 to C17, the resistors R12 to R18, and the isolation device 632.

In particular, as can be seen from the comparison between the left and the right of the diagram, the transistor n14 is not of a diode-connected type that simply short-circuits its collector and base to each other, and is ingeniously designed to pull up a gate voltage of the transistor N11.

In terms of what is shown in the right-hand side of the diagram, the capacitor C14 is connected between the collector and the base of the transistor n14. Moreover, the resistor R14 is connected between the emitter and the base of the transistor n14.

Such a configuration helps maintain a voltage elevated by the capacitor C14, and, from a second pulse onward, elevate the voltage on the basis of a difference from a previous signal level. As a result, an emitter voltage of the transistor n14 (i.e., the gate voltage of the transistor N11) is pulled up.

Moreover, it is appropriate for the transistor n15 to employ a circuit configuration similar to that described above. In terms of what is shown in FIG. 36 referred to previously, it is appropriate to connect the capacitor C15 between the collector and the base of the transistor n15. Moreover, it is appropriate to connect the resistor R15 between the emitter and the base of the transistor n15. Such a configuration helps pull up an emitter voltage of the transistor n15 (i.e., a gate voltage of the transistor N12).

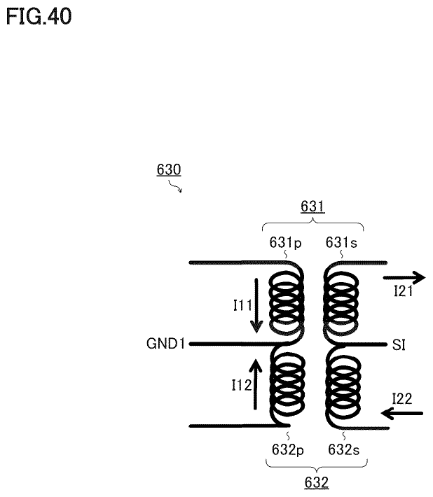

FIG. 40 is a diagram showing a third main part of the isolation switch 600 according to the additional embodiment. As described previously, the isolation devices 631 and 632 are integrated in the third chip 630. The isolation device 631 may be a transformer including the primary coil 631p to which the pulse signal I11 is applied, and the secondary coil 631s which is electromagnetically coupled to the primary coil 631p and by which the induced current I21 is induced. The isolation device 632 may be a transformer including the primary coil 632p to which the pulse signal I12 is applied, and the secondary coil 632s which is electromagnetically coupled to the primary coil 632p and by which the induced current I22 is induced.

Note that, the primary coils 631p and 632p are connected in series. The respective second terminals of the primary coils 631p and 632p (corresponding to a connection tap between both the coils) are connected to the application terminal for the ground voltage GND1. Likewise, the secondary coils 631s and 632s are connected in series. The respective second terminals of the secondary coils 631s and 632s (corresponding to a connection tap between both the coils) are connected to the application terminal for the reference voltage SI.

In particular, respective winding directions of the primary coils 631p and 632p are opposite to each other. Thus, in the isolation device 631, for example, in response to flowing of the pulse signal I11 from the first terminal to the second terminal of the primary coil 631p (downward from the top in the diagram), the induced current I21 flows from the second terminal to the first terminal of the secondary coil 631s (upward from the bottom in the diagram). By contrast, in the isolation device 632, for example, in response to flowing of the pulse signal I12 from the first terminal to the second terminal of the primary coil 632p (upward from the bottom in the diagram), the induced current I22 flows from the first terminal to the second terminal of the secondary coil 632s (upward from the bottom in the diagram).

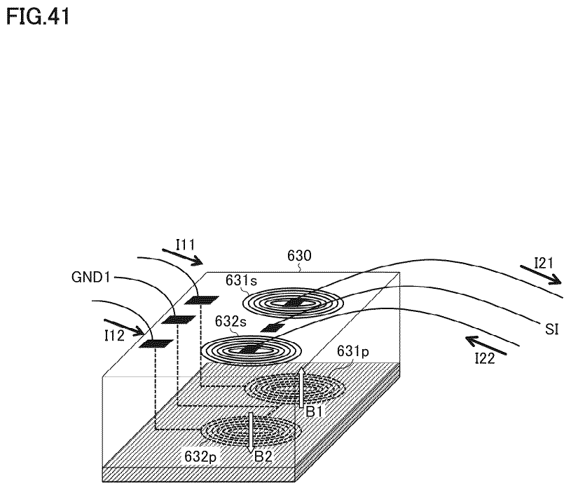

FIG. 41 is a diagram showing the third chip 630 in the third main part. Note that, the basic structure of the third chip 630 is similar to that of the transformer chip 230 (FIG. 2) described previously. That is, the primary coils 631p and 632p are both formed in a first wiring layer (the lower layer in the diagram) in the third chip 630. The secondary coils 631s and 632s are both formed in a second wiring layer (the upper layer in the diagram) in the third chip 630. The secondary coil 631s is disposed right above the primary coil 631p, and faces the primary coil 631p. Likewise, the secondary coil 632s is disposed right above the primary coil 632p, and faces the primary coil 632p.

Moreover, as described previously, respective winding directions of the primary coils 631p and 632p are opposite to each other. Thus, in response to the flowing of the pulse signal I11 from the first terminal to the second terminal (GND1) of the primary coil 631p, for example, a vertically-upward magnetic field B1 is generated in the primary coil 631p. On the other hand, in response to the flowing of the pulse signal I12 from the first terminal to the second terminal (GND1) of the primary coil 632p, for example, a vertically-downward magnetic field B2 is generated in the primary coil 632p. That is, the magnetic fields B1 and B2 cancel each other out. Thus, electromagnetic noise to be emitted from the third chip 630 can be reduced.

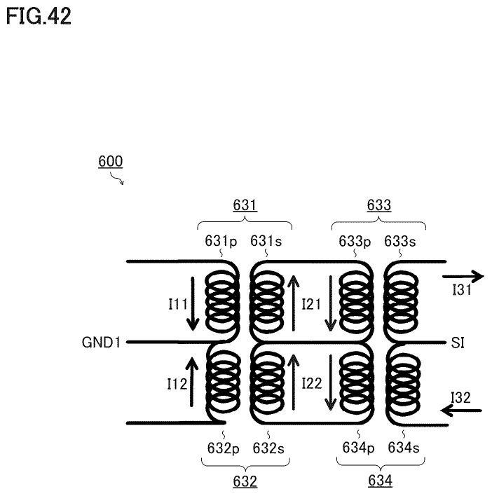

FIG. 42 is a diagram showing a modification of the third main part described above. As shown in the diagram, the isolation switch 600 of this modification includes isolation devices 633 and 634 in addition to the isolation devices 631 and 632 described previously.

The isolation device 633 may be a transformer including a primary coil 633p connected in series with the secondary coil 631s of the isolation device 631, and a secondary coil 633s to be electromagnetically coupled to the primary coil 633p.

The isolation device 634 may be a transformer including a primary coil 634p connected in series with the secondary coil 632s of the isolation device 632, and a secondary coil 634s to be electromagnetically coupled to the primary coil 634p.

The primary coils 633p and 634p are connected in series. In terms of what is shown in the diagram, the first terminal of the primary coil 633p is connected to the first terminal of the secondary coil 631s. The first terminal of the primary coil 634p is connected to the first terminal of the secondary coil 632s. The respective second terminals of the primary coils 633p and 634p are connected to the respective second terminals of the secondary coils 631s and 632s.

Likewise, the secondary coils 633s and 634s are connected in series. The respective second terminals of the secondary coils 633s and 634s (corresponding to a connection tap between both the coils) are connected to the application terminal for the reference voltage SI.

In the isolation device 631, for example, in response to the flowing of the pulse signal I11 from the first terminal to the second terminal of the primary coil 631p (downward from the top in the diagram), the induced current I21 flows from the second terminal to the first terminal of the secondary coil 631s (upward from the bottom in the diagram). At this time, in the isolation device 633, the induced current I21 flows from the first terminal to the second terminal of the primary coil 633p (downward from the top in the diagram). Thus, an induced current I31 flows from the second terminal to the first terminal of the secondary coil 633s (upward from the bottom in the diagram).

By contrast, for example, in the isolation device 632, in response to the flowing of the pulse signal I12 from the first terminal to the second terminal of the primary coil 632p (upward from the bottom in the diagram), the induced current I22 flows from the first terminal to the second terminal of the secondary coil 632s (upward from the bottom in the diagram). At this time, in the isolation device 634, the induced current I22 flows from the second terminal to the first terminal of the primary coil 634p (downward from the top in the diagram). Thus, an induced current I32 flows from the first terminal to the second terminal of the secondary coil 634s (upward from the bottom in the diagram).

Note that, in the isolation switch 600 of this modification, the switching circuit 640 is controlled by the induced currents I31 and I32 described above.

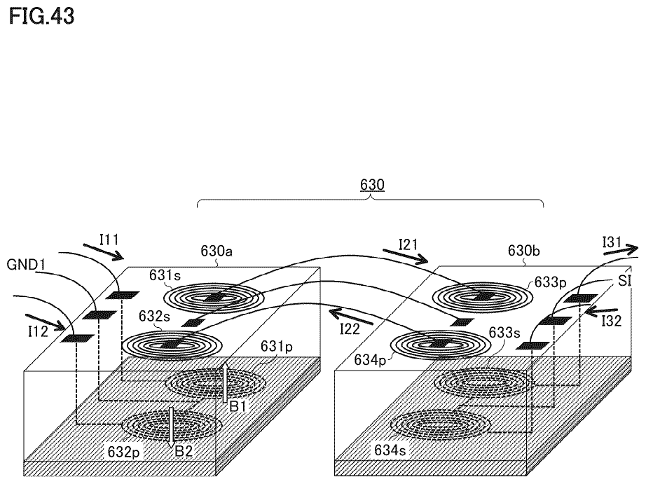

FIG. 43 is a diagram showing the third chip 630 in the modification of the third main part. As shown in the diagram, a third chip 630a in which the isolation devices 631 and 632 are integrated, and a third chip 630b in which the isolation devices 633 and 634 are integrated may be used as the third chip 630 described previously.

Note that, wire-bonding may be performed between the third chip 630a and the third chip 630b. Specifically, wire-bonding may be performed all between the first terminal of the secondary coil 631s and the first terminal of the primary coil 633p, between the first terminal of the secondary coil 632s and the first terminal of the primary coil 634p, and between the respective second terminals of the secondary coils 631s and 632s and the respective second terminals of the primary coils 633p and 634p.

In this way, the configuration in which the isolation devices in a plurality of stages (in the diagram, isolation devices 631 and 633 and isolation devices 632 and 634) are provided while overlapped can help increase a dielectric strength voltage between the first chip 610 and the second chip 620.

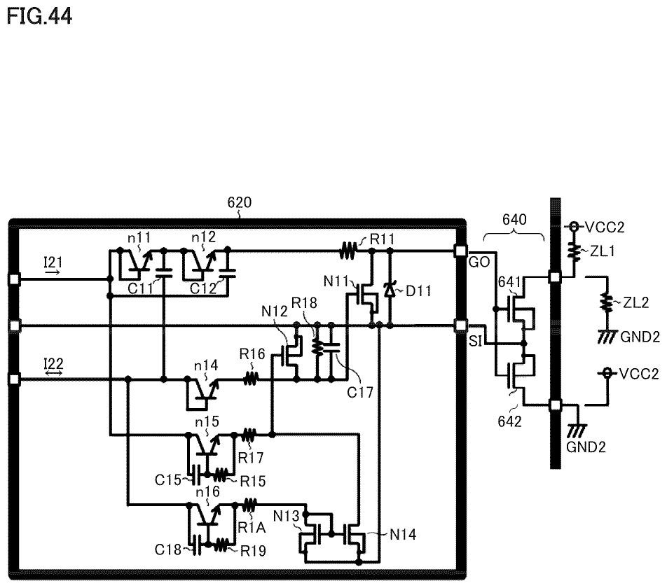

FIG. 44 is a diagram showing a modification of the second chip 620. The second chip 620 of this modification is basically the same as that shown in FIG. 36 referred to previously except that the transistor n13, the capacitors C13, C14, and C16, and the resistors R12 to R14 are omitted. Due to the omission of the capacitor C14, the base and the collector of the transistor n14 are directly short-circuited.

On the other hand, in the second chip 620 of this modification, a transistor n16 (e.g., npn bipolar transistor), transistors N13 and N14 (e.g., n-channel MOS field-effect transistors), a capacitor C18, and resistors R19 and RIA are added.

In the following description, no redundant description will be given of the elements described previously, the elements being denoted by the same reference symbols as those in FIG. 36.

The collector of the transistor n16 and the first terminal of the capacitor C18 are both connected to an application terminal for the induced current I22 (corresponding to the second output terminal of the third chip 630). The base of the transistor n16 is connected to the second terminal of the capacitor C18 and the first terminal of the resistor R19. The emitter of the transistor n16 and the second terminal of the resistor R19 are both connected to the first terminal of the resistor RIA. The second terminal of the resistor RIA is connected to the drain of the transistor N13.

The respective gates of the transistors N13 and N14 are both connected to the drain of the transistor N13. The drain of the transistor N14 is connected to the gate of the transistor N12. The respective sources of the transistors N13 and N14 are both connected to the application terminal for the reference voltage SI. The transistors N13 and N14 forms a current mirror that copies a drain current of the transistor N13 as a drain current of the transistor N14.

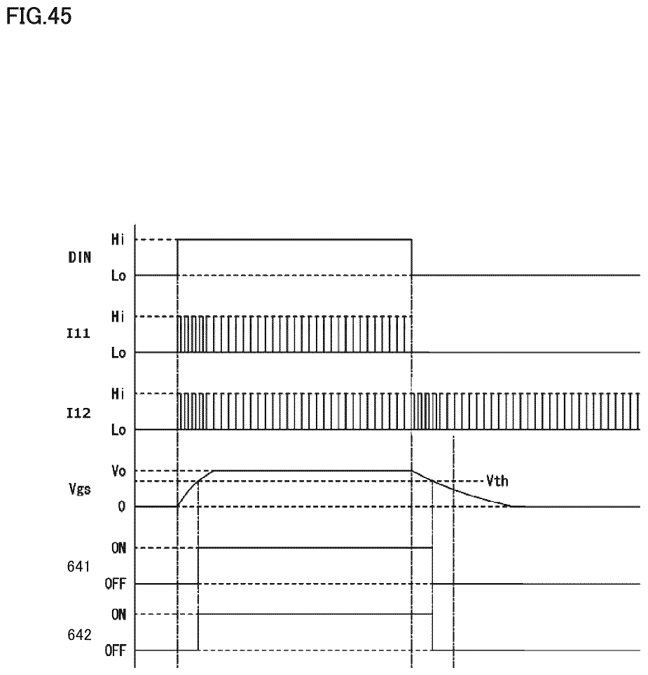

FIG. 45 is a chart showing an operation example of the second chip 620 of the modification described above. Sequentially from the top of the chart, the control signal DIN, the pulse signals I11 and I12, the gate-source voltage Vgs of the transistor N11, and ON/OFF states of the switching devices 641 and 642 are shown.

As shown in the chart, in response to the switching of the control signal DIN to be input from Lo level to Hi level, the pulse signals I11 and I12 both start to be pulse-driven. Thus, the induced currents I21 and I22 are generated in the second chip 620. This causes the switching devices 641 and 642 to be both turned on.

Moreover, in response to the switching of the control signal DIN from Hi level to Lo level, while the pulse signal I11 stops being pulse-driven, the pulse signal I12 continues to be pulse-driven. Thus, while the induced current I21 stops flowing, the induced current I22 continues to flow. This causes the switching devices 641 and 642 to be both turned off.

### Signal Transmission Device (Additional Embodiment)

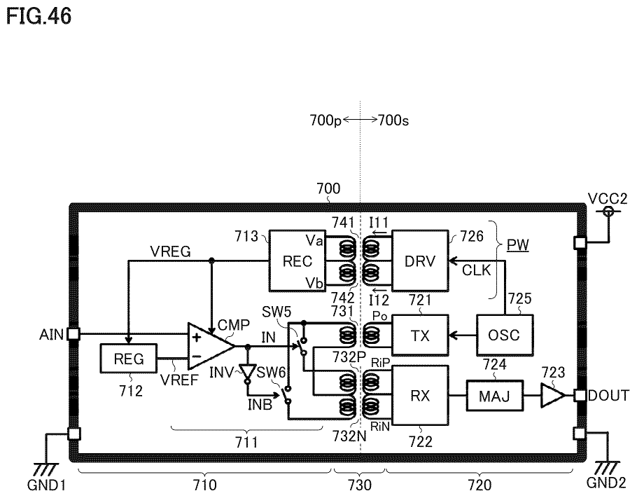

FIG. 46 is a diagram showing an additional embodiment of the signal transmission devices. A signal transmission device 700 of this embodiment transmits, while electrically isolating between a primary circuit system 700p (VREG-GND1 system) and a secondary circuit system 700s (VCC2-GND2 system), an analog input-pulse signal AlN of the primary circuit system 700p as a digital output-pulse signal DOUT of the secondary circuit system 700s.

The signal transmission device 700 may include a first chip 710, a second chip 720, and a third chip 730 like the signal transmission devices 200 (FIG. 1) and 400 (FIG. 10 etc.) described previously. The first chip 710, the second chip 720, and the third chip 730 may be sealed in a single package.

A switching circuit 711, a reference-voltage generating circuit 712, and a rectification circuit 713 that are provided in the primary circuit system 700p are integrated in the first chip 710.

A drive circuit 721, a reception circuit 722, a buffer 723, a majority circuit 724, an oscillator circuit 725, and a supply drive circuit 726 that are provided in the secondary circuit system 700s are integrated in the second chip 720. All these circuit blocks operate by being supplied with the supply voltage VCC2 (e.g., 4.5 to 5.5 V) from an external power supply for the secondary circuit system 700s. Note that, the external power supply for the secondary circuit system 700s can have, for example, a capability to supply a current of 15 mA.

A plurality of isolation devices (731, 732P, 732N, 741, and 742) that serve as signal transmission paths between the primary circuit system 700p and the secondary circuit system 700s while electrically isolating between them are integrated in the third chip 730.

The switching circuit 711 switches a state of connection between the isolation device 731 and the positive-phase isolation device 732P and the negative-phase isolation device 732N according to the analog input-pulse signal AlN. In terms of what is shown in the diagram, the switching circuit 711 includes the switching devices SW5 and SW6, the comparator CMP, and the inverter INV as in the fourth embodiment (FIG. 16) described previously.

The comparator CMP outputs the input pulse signal IN by comparing the analog input-pulse signal AlN to be input to the non-inverting input terminal (+) and a reference voltage VREF to be input to the inverting input terminal (−) with each other. The input pulse signal IN is at high level under a state in which AlN>VREF has been established. On the other hand, the input pulse signal IN is at low level under a state in which AlN<VREF has been established. Current consumption of the comparator CMP may be, for example, 15 μA.

The inverter INV generates the inverted input pulse signal INB by inverting the logic level of the input pulse signal IN. The inverted input pulse signal INB is at low level under the state in which the input pulse signal IN is at high level. On the other hand, the inverted input pulse signal INB is at high level under the state in which the input pulse signal IN is at low level.

Under the state in which the input pulse signal IN is at high level, and in which the inverted input pulse signal INB is at low level, the switching device SW5 is turned on, and the switching device SW6 is turned off. Thus, conduction between the isolation device 731 and the positive-phase isolation device 732P is established, and conduction between the isolation device 731 and the negative-phase isolation device 732N is cut off. As a result, the positive-phase second signal RiP is generated in the positive-phase isolation device 732P. On the other hand, the negative-phase second signal RiN is not generated in the negative-phase isolation device 732N.

Under the state in which the input pulse signal IN is at low level, and in which the inverted input pulse signal INB is at high level, by contrast, the switching device SW5 is turned off, and the switching device SW6 is turned on. Thus, the conduction between the isolation device 731 and the positive-phase isolation device 732P is cut off, and the conduction between the isolation device 731 and the negative-phase isolation device 732N is established. As a result, the negative-phase second signal RiN is generated in the negative-phase isolation device 732N. On the other hand, the positive-phase second signal RiP is not generated in the positive-phase isolation device 732P.

The reference-voltage generating circuit 712 generates the predetermined reference voltage VREF (e.g., 1 V). Current consumption of the reference-voltage generating circuit 712 may be, for example, 5 μA. Output accuracy of the reference voltage VREF may be, for example, +2%. The reference-voltage generating circuit 712 may have a trimming function to increase the output accuracy of the reference voltage VREF.

The rectification circuit 713 generates an internal supply voltage VREG (e.g., 2.4 to 3 V) of the primary circuit system 700p by rectifying and smoothing the node voltages Va and Vb to be induced by the isolation devices 741 and 742. The switching circuit 711 and the reference-voltage generating circuit 712 both operate by being supplied with the internal supply voltage VREG from the rectification circuit 713.

The drive circuit 721 cyclically or continuously pulse-drives the first signal Po to be applied to the isolation device 731. Current consumption of the drive circuit 721 may be, for example, 2 mA. A driving frequency of the first signal Po may be, for example, 10 MHz.

The reception circuit 722 distinguishes the logic level of the input pulse signal IN by detecting the difference between the positive-phase second signal RiP and the negative-phase second signal RiN. Current consumption of the reception circuit 722 may be, for example, 5 mA.

The majority circuit 724 generates the digital output-pulse signal DOUT according to the analog input-pulse signal AlN by executing a majority decision process on a result of the distinction by the reception circuit 722. The majority circuit 724 can be omitted as in the signal transmission device 400 (FIG. 10 etc.) described previously.

The buffer 723 performs waveform shaping on the digital output-pulse signal DOUT, and outputs the digital output-pulse signal DOUT to the outside of the signal transmission device 700.

The oscillator circuit 725 generates a drive clock signal CLK for the supply drive circuit 726. Current consumption of the oscillator circuit 725 may be, for example, 2 mA. An oscillation frequency of the drive clock signal CLK may be, for example, 40 MHz.

The supply drive circuit 726 generates the pulse signals I11 and I12 in synchronization with the drive clock signal CLK.

The isolation device 731 transmits the single-phase first signal Po from the secondary circuit system 700s to the primary circuit system 700p. The isolation device 731 functions as an inquiring isolation device.

The positive-phase isolation device 732P and the negative-phase isolation device 732N respectively transmit the differential second signals Rip and RiN from the primary circuit system 700p to the secondary circuit system 700s. The positive-phase isolation device 732P and the negative-phase isolation device 732N both function as responding isolation devices.

The isolation devices 741 and 742 correspond respectively to isolation circuits for transmitting the pulse signals I11 and I12 of the second chip 720 as pulse signals of the first chip 710 (induced currents I21 and I22).

Among the elements described above, the supply drive circuit 726, the rectification circuit 713, and the isolation devices 741 and 742 can be understood as elements that form an isolation supply circuit PW. That is, the signal transmission device 700 is different from the signal transmission device 400 described previously in further including the isolation supply circuit PW.

### <Isolation Supply Circuit>

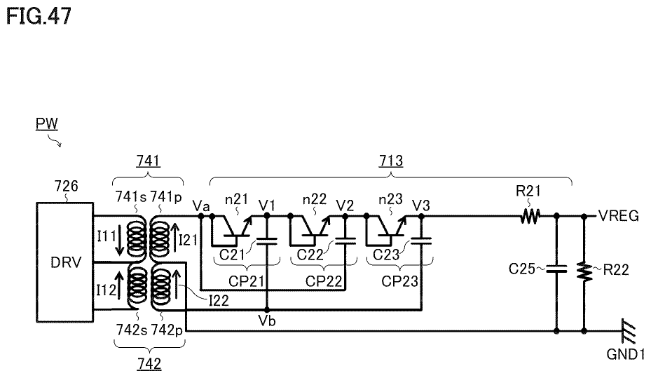

FIG. 47 is a diagram showing a configuration example of the isolation supply circuit PW. In the isolation supply circuit PW of this configuration example, the isolation device 741 may be a transformer including a secondary coil 741s to which the pulse signal I11 is applied, and a primary coil 741p which is electromagnetically coupled to the secondary coil 741s and in which the induced current I21 is induced. The isolation device 742 may be a transformer including a secondary coil 742s to which the pulse signal I12 is applied, and a primary coil 742p which is electromagnetically coupled to the secondary coil 742s and in which the induced current I22 is induced. The respective second terminals of the primary coils 741p and 742p are both connected to the application terminal for the ground voltage GND1.

Note that, the secondary coils 741s and 742s are connected in series. Likewise, the primary coils 741p and 742p are connected in series. The respective second terminals of the primary coils 741p and 742p (corresponding to a connection tap between both the coils) are connected to the application terminal for the ground voltage GND1.

In particular, respective winding directions of the secondary coils 741s and 742s are opposite to each other. Thus, in the isolation device 741, for example, in response to flowing of the pulse signal I11 from the first terminal to the second terminal of the secondary coil 741s (downward from the top in the diagram), the induced current I21 flows from the second terminal to the first terminal of the primary coil 741p (upward from the bottom in the diagram). By contrast, in the isolation device 742, for example, in response to flowing of the pulse signal I12 from the first terminal to the second terminal of the secondary coil 742s (upward from the bottom in the diagram), the induced current I22 flows from the first terminal to the second terminal of the primary coil 742p (upward from the bottom in the diagram).

Thus, the similar operating principle as that of the third main part (FIG. 40 and FIG. 41) of the isolation switch 600 causes magnetic fields that are respectively generated in the isolation devices 741 and 742 to cancel each other. Therefore, electromagnetic noise to be emitted from the third chip 730 can be reduced.

Moreover, the rectification circuit 713 includes transistors n21 to n23 (npn bipolar transistors), capacitors C21 to C23 and C25, and resistors R21 and R22.

In particular, among the elements mentioned above, the transistors n21 to n23 and the capacitors C21 to C23 form voltage boosting circuits CP21 to CP2x as many as the number of stages x (note that, x is an integer number of 2 or more) connected in series between the primary coil 741p and an application terminal for the internal supply voltage VREG. Note that, although the voltage boosting circuits CP21 to CP23 in three stages are exemplified in the diagram, the number of stages x of the voltage boosting circuits CP21 to CP2x are not limited at all to this example.

All the transistors n21 to n23 are diode-connected between the first terminal of the primary coil 741p (corresponding to the application terminal for the node voltage Va) and the application terminal for the internal supply voltage VREG so that their forward directions are a flow direction of the induced current I21 to be generated in the primary coil 741p.

Specifically, the base and the collector of the transistor n21 are connected to the first terminal of the primary coil 741p (corresponding to the application terminal for the node voltage Va). The emitter of the transistor n21 and the collector and the base of the transistor n22 are connected to the application terminal for the node voltage V1. The emitter of the transistor n22 and the collector and the base of the transistor n23 are connected to the application terminal for the node voltage V2. The emitter of the transistor n23 is connected to an application terminal for a node voltage V3.

Note that, the transistors n21 to n23 may be replaced with diodes (Schottky diodes and the like).

The capacitor C21 is connected between the application terminal for the node voltage V1 and the application terminal for the node voltage Vb. The capacitor C22 is connected between the application terminal for the node voltage V2 and the application terminal for the node voltage Va. The capacitor C23 is connected between the application terminal for the node voltage V3 and the application terminal for the node voltage Vb. A capacitance value of each of the capacitors C21 to C23 may be, for example, 10 pF.

The resistor R21 is connected between the application terminal for the node voltage V3 and the application terminal for the internal supply voltage VREG. A resistance value of the resistor R21 may be, for example, 400Ω.

The resistor R22 and the capacitor C25 both may be connected in parallel to each other between the application terminal for the internal supply voltage VREG and the application terminal for the ground voltage GND1. A resistance value of the resistor R22 may be, for example, 100 kΩ (assuming a load of 25 μA). A capacitance value of the capacitor C25 may be, for example, 50 pF.

The isolation supply circuit PW of this configuration example operates on the operating principle similar to that of the first main part (FIG. 37 and FIG. 38) of the isolation switch 600. Thus, efficient voltage boosting can be performed by utilizing the swing-back voltage difference. Therefore, even in a system without a stable external power supply for the primary circuit system 700p, power can be supplied from the secondary circuit system 700s to the primary circuit system 700p.

Moreover, the isolation supply circuit PW can be mounted with its small transformers (the isolation devices 741 and 742) that can be built in the signal transmission device 700. Thus, cost of the isolation supply circuit PW is lower than that of configurations which uses common isolation DC/DC converters.

Note that, a current supply capability of the isolation supply circuit PW (e.g., 25 μA or less) is lower than that of the external power supply for the secondary circuit system 700s. Thus, preferably, current consumption of the primary circuit system 700p is as low as possible.

In terms of this, like the signal transmission device 400 (FIG. 10 etc.) described previously, the signal transmission device 700 employs a reflection-type isolation communication method in which the primary circuit system 700p responds to an inquiry from the secondary circuit system 700s. Thus, the primary circuit system 700p only need perform switching control according to the input pulse signal IN at the respective times to drive the positive-phase isolation device 732P and the negative-phase isolation device 732N. Thus, even when the current supply capability of the isolation supply circuit PW is low, the signal transmission from the primary circuit system 700p to the secondary circuit system 700s is prevented from being disturbed.

Note that, the signal transmission device 700 is configured to be basically the same as the signal transmission device of the fourth embodiment (FIG. 16) described previously. Note that, the isolation supply circuit PW can be suitably introduced even when the signal transmission device is configured to be basically the same as that of another embodiment (FIG. 10, FIG. 13, FIG. 14, FIG. 17, FIG. 18, FIG. 20, or FIG. 21).

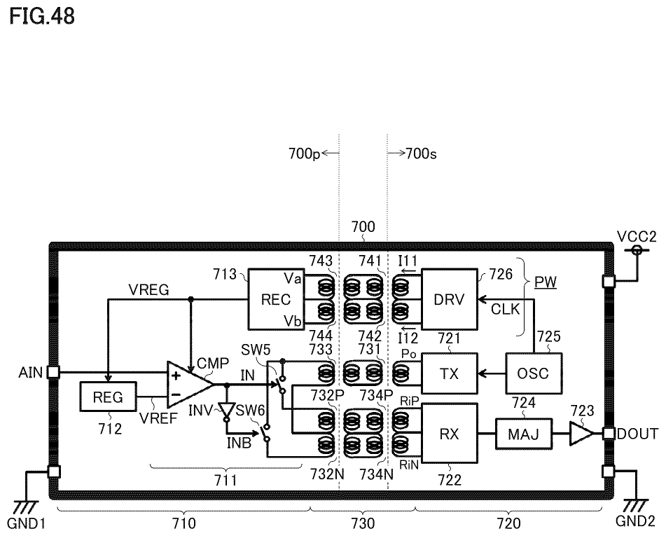

FIG. 48 is a diagram showing a modification of the signal transmission device 700 according to the additional embodiment. In the signal transmission device 700 of this modification, as in FIG. 42 and FIG. 43 referred to previously, a plurality of isolation devices in a plurality of stages are provided while overlapped.

In terms of what is shown in the diagram, the first signal Po is transmitted while isolated via the isolation device 731 and an isolation device 733. The positive-phase second signal RiP is transmitted while isolated via the positive-phase isolation device 732P and a positive-phase isolation device 734p. The negative-phase second signal RiN is transmitted while isolated via the negative-phase isolation device 732N and a negative-phase isolation device 734N. The pulse signal I11 is transmitted while isolated via the isolation devices 741 and 743. The pulse signal I12 is transmitted while isolated via the isolation device 742 and an isolation device 744.

This configuration can help increase a dielectric strength voltage between the first chip 710 and the second chip 720.

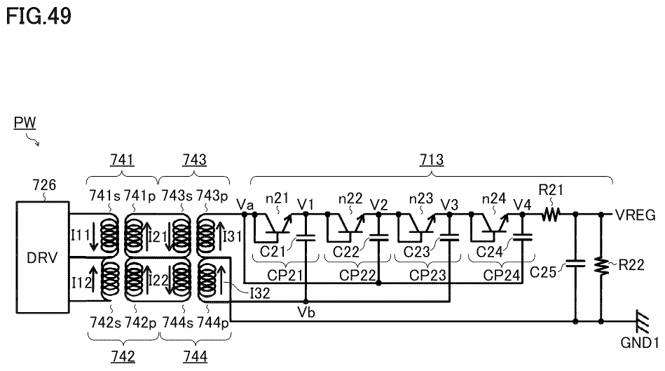

FIG. 49 is a diagram showing a modification of the isolation supply circuit PW. As shown in the diagram, the isolation supply circuit PW of this modification includes the isolation devices 743 and 744 in addition to the isolation devices 741 and 742 described previously.

The isolation device 743 may be a transformer including a secondary coil 743s connected in series with the primary coil 741p of the isolation device 741, and a primary coil 743p to be electromagnetically coupled to the secondary coil 743s.

The isolation device 744 may be a transformer including a secondary coil 744s connected in series with the primary coil 742p of the isolation device 742, and a primary coil 744p to be electromagnetically coupled to the secondary coil 744s.

The secondary coils 743s and 744s are connected in series. In terms of what is shown in the diagram, the first terminal of the secondary coil 743s is connected to the first terminal of the primary coil 741p. The first terminal of the secondary coil 744s is connected to the first terminal of the primary coil 742p. The respective second terminals of the secondary coils 743s and 744s are connected to the respective second terminals of the primary coils 741p and 742p.

Likewise, the primary coils 743p and 744p are connected in series. The respective second terminals of the primary coils 743p and 744p (corresponding to a connection tap between both the coils) are connected to the application terminal for the ground voltage GND1.

In the isolation device 741, for example, in response to the flowing of the pulse signal I11 from the first terminal to the second terminal of the secondary coil 741s (downward from the top in the diagram), the induced current I21 flows from the second terminal to the first terminal of the primary coil 741p (upward from the bottom in the diagram). At this time, in the isolation device 743, the induced current I21 flows from the first terminal to the second terminal of the secondary coil 743s (downward from the top in the diagram). Thus, the induced current I31 flows from the second terminal to the first terminal of the primary coil 743p (upward from the bottom in the diagram).

In contrast, in the isolation device 742, for example, in response to the flowing of the pulse signal I12 from the first terminal to the second terminal of the secondary coil 742s (upward from the bottom in the diagram), the induced current I22 flows from the first terminal to the second terminal of the primary coil 742p (upward from the bottom in the diagram). At this time, in the isolation device 744, the induced current I22 flows from the second terminal to the first terminal of the secondary coil 744s (downward from the top in the diagram). Thus, the induced current I32 flows from the first terminal to the second terminal of the primary coil 744p (upward from the bottom in the diagram).

Note that, in the isolation supply circuit PW of this modification, the induced currents I31 and I32 described above flow through the rectification circuit 713.

The rectification circuit 713 further includes a transistor n24 (e.g., npn bipolar transistor) and a capacitor C24 in addition to the transistors n21 to n23, the capacitors C21 to C23 and C25, and the resistors R21 and R22 described previously. That is, the rectification circuit 713 includes a voltage boosting circuit CP24 in a fourth stage in addition to the voltage boosting circuits CP21 to CP23 described previously.

In terms of what is shown in the diagram, the collector and the base of the transistor n24 are connected to the application terminal for the node voltage V3. The emitter of the transistor n24 is connected to an application terminal for a node voltage V4. The capacitor C24 is connected between the application terminal for the node voltage V4 and the application terminal for the node voltage Va.

In this way, as the number of voltage boosting circuits CP21 to CP2x is increased, the internal supply voltage VREG is pulled up.

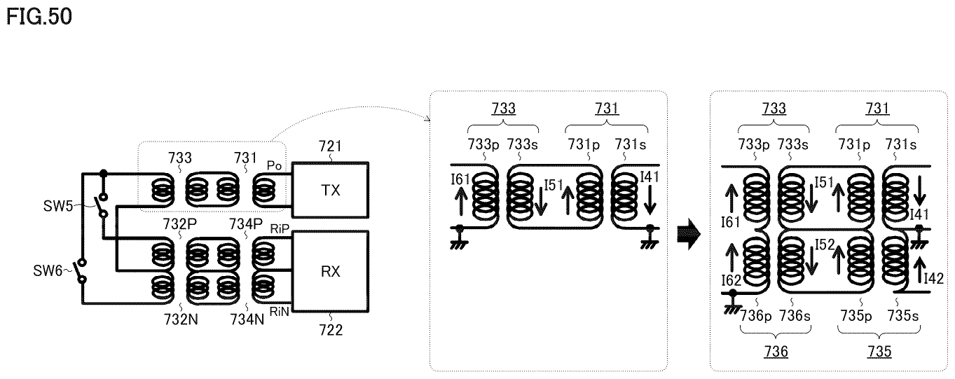

FIG. 50 is a diagram showing a modification of the inquiring isolation devices 731 and 733. As shown in the left-hand side and the center of the diagram, the isolation device 731 may be a transformer including a secondary coil 731s to be connected to the drive circuit 721, and a primary coil 731p to be electromagnetically coupled to the secondary coil 731s. Likewise, the isolation device 733 may be a transformer including a secondary coil 733s connected in series with the primary coil 731p of the isolation device 731, and a primary coil 733p to be electromagnetically coupled to the secondary coil 733s.

In the isolation device 731, for example, in response to flowing of a pulse signal I41 from the first terminal to the second terminal of the secondary coil 731s (downward from the top in the diagram) in response to the application of the first signal Po, an induced current 151 flows from the second terminal to the first terminal of the primary coil 731p (upward from the bottom in the diagram). At this time, in the isolation device 733, the induced current 151 flows from the first terminal to the second terminal of the secondary coil 733s (downward from the top in the diagram). Thus, an induced current 161 flows from the second terminal to the first terminal of the primary coil 733p (upward from the bottom in the diagram).

In this way, the configuration in which the isolation devices 731 and 733 are provided while overlapped can help increase a dielectric strength voltage between the first chip 710 and the second chip 720.

Moreover, as shown in the right-hand side of the diagram, isolation devices 735 and 736 may be integrated in the third chip 730. The isolation device 735 may be a transformer including a secondary coil 735s to be connected to the drive circuit 721, and a primary coil 735p to be electromagnetically coupled to the secondary coil 735s. Likewise, the isolation device 736 may be a transformer including a secondary coil 736s connected in series with the primary coil 735p of the isolation device 735, and a primary coil 736p to be electromagnetically coupled to the secondary coil 736s.

Note that, the secondary coils 731s and 735s are connected in series. The respective second terminals of the secondary coils 731s and 735s (corresponding to a connection tap between both the coils) are connected to the application terminal for the ground voltage GND2.

In particular, respective winding directions of the secondary coils 731s and 735s are opposite to each other. Thus, in the isolation device 731, for example, in response to the flowing of the pulse signal I41 from the first terminal to the second terminal of the secondary coil 731s (downward from the top in the diagram), the induced current 151 flows from the second terminal to the first terminal of the primary coil 731p (upward from the bottom in the diagram). By contrast, in the isolation device 735, for example, in response to the flowing of the pulse signal I42 from the first terminal to the second terminal of the secondary coil 735s (upward from the bottom in the diagram), an induced current 152 flows from the first terminal to the second terminal of the primary coil 735p (upward from the bottom in the diagram).

Thus, the operating principle similar to that of the third main part (FIG. 40 and FIG. 41) of the isolation switch 600 causes magnetic fields that are respectively generated in the isolation devices 731 and 735 to cancel each other. Therefore, electromagnetic noise to be emitted from the third chip 730 can be reduced.

Note that, in response to the flowing of the induced current 152 from the first terminal to the second terminal of the primary coil 735p (upward from the bottom in the diagram), in the isolation device 736, the induced current 152 flows from the second terminal to the first terminal of the secondary coil 736s (downward from the top in the diagram). Thus, an induced current 162 flows from the second terminal to the first terminal of the primary coil 736p (upward from the bottom in the diagram).

### APPENDICES

There is a growing demand for isolation switches that are stably operable for a long period. Moreover, in the related-art signal transmission devices, in a case where a power supply for a primary circuit system is unstable or not capable enough, the signal transmission from the primary circuit system to the secondary circuit system can be disturbed. In the following description, appendices of the present disclosure are provided.

### APPENDIX 1

An isolation switch (500, 500a, 500b, 500c, 500d, 500e, 500f), including:
a switching unit (504, 504b, 504c) configured to be controlled so that the switching unit (504, 504b, 504c) enters a conducting state/a non-conducting state;
a conduction circuit (501, 501e) configured to control the switching unit (504, 504b, 504c) so that the switching unit (504, 504b, 504c) enters the conducting state;
an adjustment circuit (502, 502a, 502d) configured to adjust at least the switching unit (504, 504b, 504c) from the conducting state to the non-conducting state; and
a pulse supply circuit (503, 503f) configured to
   receive a control signal (DIN) and
   supply a pulse signal (Sp1, Sp2, Sp21, Sp22, Sp4) to at least one of the conduction circuit (501, 501e) and the adjustment circuit (502, 502a, 502d),
the conduction circuit (501, 501e) including a first isolation device (510, 5101, 5102) including
   a first primary coil (511, 5111, 5121) that is connected to the pulse supply circuit (503, 503f), and
   a first secondary coil (512, 5112, 5122) that is electromagnetically coupled to the first primary coil (511, 5111, 5121),
the conduction circuit (501, 501e) being configured to bring the switching unit (504, 504b, 504c) into the conducting state with an induced current (Id1) that flows in response to rising of the pulse signal (Sp1, Sp2, Sp21, Sp22, Sp4) supplied to the first primary coil (511, 5111, 5121),
the adjustment circuit (502, 502a, 502d, 507) including
   a second isolation device (520) including
      a second primary coil (521) that is connected to the pulse supply circuit (503, 503f), and
      a second secondary coil (522) that is electromagnetically coupled to the second primary coil (521), and,
   an adjustment device (524, 524b) configured to adjust the switching unit (504, 504b, 504c) into the non-conducting state by adjusting a voltage at a control terminal of the switching unit (504, 504b, 504c) with an induced current (Id2, Id21) that flows through the second secondary coil (522) in response to rising of the pulse signal (Sp1, Sp2, Sp21, Sp22, Sp4), and
the pulse supply circuit (503, 503f) being configured to
   supply the pulse signal (Sp1) to the first primary coil (511, 5111, 5121) under a state in which the control signal (DIN) is at a first level, and
   supply the pulse signal (Sp22) to the second primary coil (521) after a time point when the control signal (DIN) is switched from the first level to a second level that is different from the first level,
the switching unit (504, 504b, 504c) being configured to be set into the conducting state under the state in which the control signal (DIN) is at the first level.

### APPENDIX 2

The isolation switch (500, 500a, 500b, 500c, 500d, 500e, 500f) according to Appendix 1, in which
the conduction circuit (501, 501e) has a configuration in which a diode (513) is disposed between the first secondary coil (512) and the control terminal of the switching unit (504, 504b, 504c) so that a forward direction of the diode (513) is a flow direction of the induced current to be generated in the first secondary coil (512).

### APPENDIX 3

The isolation switch (500, 500a, 500f) according to Appendix 1 or 2, in which
the switching unit (504, 504c) includes an n-channel MOS transistor,
the conduction circuit (501, 501e) is configured to cause the induced current to flow into a gate, and
the adjustment circuit (502, 502a, 502d, 507) is configured to cause current to be drawn out via the gate.

### APPENDIX 4

The isolation switch (500b) according to Appendix 1, in which
the switching unit (504b) includes a p-channel MOS transistor (541b),
the conduction circuit (501) is configured to cause current to be drawn out via the gate by the induced current, and
the adjustment circuit (502) is configured to supply the current to the gate.

### APPENDIX 5

The isolation switch (500c, 500d, 500e) according to any of Appendices 1 to 4, in which
the switching unit (504c) has a configuration in which a first switching device (5411) and a second switching device (5412) are connected in series,
the first switching device (5411) and the second switching device (5412) are each one of an n-channel MOS transistor and a p-channel MOS transistor, and,
a first terminal (P11) of the first secondary coil (512, 5121, 5122) in the conduction circuit (501) is connected to a connection node to which gates of both the first switching device (5411) and the second switching device (5412) are connected, and
a second terminal (P12) of the first secondary coil (512, 5121, 5122) in the conduction circuit (501) is connected to a connection node to which sources of both the first switching device (5411) and the second switching device (5412) are connected.

### APPENDIX 6

The isolation switch (500, 500a, 500b, 500c, 500d, 500e) according to any of Appendices 1 to 5, in which
the adjustment circuit (502, 502a, 502d) includes an adjustment switching device (524, 524b) connected between a gate and a source of a switching device (541, 541b, 5411, 5412) that forms the switching unit (504, 504b, 504c), and
the adjustment circuit (502, 502a, 502d) is configured to turn on the adjustment switching device (524, 524b) with the induced current of the second secondary coil (522).

### APPENDIX 7

The isolation switch (500, 500a, 500c, 500d, 500e) according to any of Appendices 1 to 6, in which
the adjustment circuit (502a, 502d, 502e) is configured to be capable of assisting an operation to bring the switching unit (504, 504c) by the conduction circuit (501, 501a, 501e) into the conducting state under the state in which the control signal (DIN) is at the first level, and
the pulse supply circuit (503) is configured to supply the pulse signal to the second primary coil (521) of the second isolation device (520) under the state in which the control signal (DIN) is at the first level.

### APPENDIX 8

The isolation switch (500d) according to any of Appendices 1 to 7, in which
the conduction circuit (501) is configured to suppress an operation to bring the switching unit (504c) by the adjustment circuit (502d) into the non-conducting state under the state in which the control signal (DIN) is at the first level, and
the conduction circuit (501) is configured to turn off the adjustment device (524) with the induced current (Id1) of the first secondary coil (512).

### APPENDIX 9

The isolation switch (500e) according to any of Appendices 1 to 8, in which
the isolation switch (500e) has a configuration in which
the first secondary coil includes a plurality of first secondary coils (5112, 5122) that are connected in series, and
the first primary coil includes a plurality of first primary coils (5111, 5121) that are electromagnetically coupled respectively to the plurality of first secondary coils (5112, 5122).

### APPENDIX 10

The isolation switch (500e) according to any of Appendices 1 to 9, in which
the first secondary coil (5112) and the second secondary coil (522e) are connected in series, and
a winding direction of the second secondary coil (522e) and a winding direction of the first secondary coil (5112) are opposite to each other.

### APPENDIX 11

The isolation switch (500f) according to any of Appendices 1 to 7, in which
the first isolation device (510f) is configured to double as the second isolation device.

### APPENDIX 12

The isolation switch (500, 500a, 500b, 500c, 500d, 500e, 500f) according to any of Appendices 1 to 10, in which
the pulse supply circuit (503, 503f) is configured to generate the pulse signal (Sp1, Sp4) in a first cycle for a predetermined period after a time point when the control signal (DIN) is switched from the second level to the first level, and to then generate the pulse signal in a second cycle that is longer than the first cycle.

### APPENDIX 13

The isolation switch (500f) according to Appendix 11, in which
the pulse supply circuit (503f) is configured to supply the pulse signal (Sp4) to a first terminal of the first primary coil (511f) under the state in which the control signal (DIN) is at the first level, and
configured to refrain from supplying the pulse signal to the first primary coil (511f) under a state in which the control signal (DIN) is at the second level.

### APPENDIX 14

The isolation switch (500f) according to Appendix 11 or 12, in which
the adjustment circuit (507) is constituted by a resistor (571) that is connected to the control terminal of the switching unit (504) and to a ground potential (GND).

### APPENDIX 15

The isolation switch (500d) according to any of Appendices 1 to 8, in which
the adjustment circuit (502d) includes
   a first adjustment-switching device (524) connected in parallel to the first secondary coil (512), and
   a second adjustment-switching device (528) connected in parallel to the second secondary coil (522), and
the adjustment circuit (502d) has a configuration in which
   the first adjustment-switching device (524) is switched on by the induced current (Id21) to be induced by the second secondary coil (522) under a state in which the pulse signal (Sp2) has been supplied to the second primary coil (521), and
   the first adjustment-switching device (524) is switched off in response to switching on of the second adjustment-switching device (528) by the induced current (Id1) to be induced by the first secondary coil (512) under the state in which the pulse signal (Sp1) has been supplied to the first primary coil (511).

### APPENDIX 16

The isolation switch (600) according to any of Appendices 1 to 15, in which
the conduction circuit includes voltage boosting circuits (CP11, CP12) connected in series in a plurality of stages between the first secondary coil (631s) and the control terminal (GO) of the switching unit,
a voltage boosting circuit (CP11) in an odd-numbered stage among the voltage boosting circuits (CP11, CP12) in the plurality of stages includes
   a first diode (n11) connected between the first secondary coil (631s) and the control terminal (GO) of the switching unit so that a forward direction of the first diode (n11) is a flow direction of an induced current (I21) to be generated in the first secondary coil (631s), and
   a first capacitor (CP11) connected between a cathode of the first diode (n11) and the second secondary coil (632s), and
a voltage boosting circuit (CP12) in an even-numbered stage among the voltage boosting circuits (CP11, CP12) in the plurality of stages includes
   a second diode (n12) connected between the first secondary coil (631s) and the control terminal (GO) of the switching unit so that a forward direction of the second diode (n12) is the flow direction of the induced current (I21) to be generated in the first secondary coil (631s), and
   a second capacitor (CP12) connected between a cathode of the second diode (n12) and the first secondary coil (631s).

### APPENDIX 17

The isolation switch (600) according to any of Appendices 1 to 16, in which
the adjustment circuit includes
   a first adjustment-switching device (N11) connected in parallel to the first secondary coil (631s),
   a first transistor (n14) connected between the second secondary coil (632s) and a control terminal of the first adjustment-switching device (N11),
   a first capacitor (C14) connected between a first main electrode and a control terminal of the first transistor (n14), and
   a first resistor (R14) connected between a second main electrode and the control terminal of the first transistor (n14).

### APPENDIX 18

The isolation switch (600) according to Appendix 17, in which
the adjustment circuit includes
   a second adjustment-switching device (N12) connected in parallel to the second secondary coil (632s),
   a second transistor (n15) connected between the first secondary coil (631s) and a control terminal of the second adjustment-switching device (N12),
   a second capacitor (C15) connected between a first main electrode and a control terminal of the second transistor (n15), and
   a second resistor (R15) connected between a second main electrode and the control terminal of the second transistor (n15).

### APPENDIX 19

The isolation switch (600) according to any of Appendices 1 to 18, in which
the first primary coil (631p) and the second primary coil (632p) are connected in series, and
a winding direction of the first primary coil (631p) and a winding direction of the second primary coil (632p) are opposite to each other.

### APPENDIX 20

The isolation switch (600) according to any of Appendices 1 to 19, further including:
a third isolation device (633) including
   a third primary coil (633p) connected in series with the first secondary coil (631s) and
   a third secondary coil (633s) to be electromagnetically coupled to the third primary coil (633p); and
a fourth isolation device (634) including
   a fourth primary coil (634p) connected in series with the second secondary coil (632s), and
   a fourth secondary coil (634s) to be electromagnetically coupled to the fourth primary coil (634p), in which
the switching unit (640) is controlled by induced currents (I31, I32) to flow respectively through the third secondary coil (633s) and the fourth secondary coil (634s).

### APPENDIX 21

A sequencer, including the isolation switch (500, 500a, 500b, 500c, 500d, 500e, 500f) according to any of Appendices 1 to 20.

According to Appendices 1 to 21, it is possible to provide isolation switches and sequencers that are stably operable for a long period.

### APPENDIX 22

A signal transmission device (400) configured to transmit a signal between a primary circuit system (400p) and a secondary circuit system (400s) while isolating between the primary circuit system (400p) and the secondary circuit system (400s), the signal transmission device (400) including:
a first isolation device (431, 433) configured to transmit a first signal (Po) from the secondary circuit system (400s) to the primary circuit system (400p);
a second isolation device (432, 434) configured to transmit a second signal (Ri) from the primary circuit system (400p) to the secondary circuit system (400s);
a drive circuit (421) provided in the secondary circuit system (400s) and configured to drive the first isolation device (431, 433);
a switching circuit (411) provided in the primary circuit system (400p) and configured to switch a state of connection between the first isolation device (431, 433) and the second isolation device (432, 434) according to an input signal (INP, INN); and
a reception circuit (422) provided in the secondary circuit system (400s) and configured to detect the second signal (Ri) and to generate an output signal (OUT) according to the input signal (INP, INN).

### APPENDIX 23

The signal transmission device (400) according to Appendix 22, in which
the second isolation device (432) is configured to output the second signal (Ri) in a single phase, and
the switching circuit (411) switches a state of the connection between the first isolation device (431, 433) and the second isolation device (432, 434) to either one of a first connection state in which the second isolation device (432) is driven according to the first signal (Po) and a second connection state in which the second isolation device (432) refrains from being driven according to the first signal (Po).

### APPENDIX 24

The signal transmission device (400) according to Appendix 22, in which
the second isolation device (432) includes a positive-phase isolation device (432P) and a negative-phase isolation device (432N), and is configured to differentially output respective output signals from the positive-phase isolation device (432P) and the negative-phase isolation device (432N) as the second signals (Rip, RiN),
the switching circuit (411) switches a state of the connection between the first isolation device (431) and the second isolation device (432) to either one of a first connection state in which the positive-phase isolation device (432P) is driven according to the first signal (Po) and a second connection state in which the negative-phase isolation device (432N) is driven according to the first signal (Po).

### APPENDIX 25

The signal transmission device (400) according to any of Appendices 22 to 24, in which
the first isolation device (431) and the second isolation device (432) are each a transformer, and
the switching circuit (411) includes a switching device (SW1, SW5, SW6) that is connected between the first isolation device (431) and the second isolation device (432).

### APPENDIX 26

The signal transmission device (400) according to any of Appendices 22 to 25, in which
the first isolation device (431) and the second isolation device (432) are each a transformer, and
the switching circuit (411) includes a switching device (SW2, SW3, SW4) that is connected in parallel to at least one of the first isolation device (431) and the second isolation device (432).

### APPENDIX 27

The signal transmission device (400) according to any of Appendices 22 to 24, in which
the first isolation device (433) and the second isolation device (434) are each a capacitor, and
the switching circuit (411) includes a first switching device (SW7, SW8) that is connected between the second isolation device (434) and a fixed potential terminal (GND).

### APPENDIX 28

The signal transmission device (400) according to Appendix 27, in which
the switching circuit (411) further includes a second switching device (SW9, SW10) that is connected between the first isolation device (433) and the second isolation device (434).

### APPENDIX 29

The signal transmission device (400) according to any of Appendices 22 to 28, in which
the drive circuit (421) drives the first isolation device (431, 433) in one of a cyclical manner and a continuous manner.

### APPENDIX 30

The signal transmission device (400) according to any of Appendices 22 to 30, in which a power supply for the secondary circuit system (400s) has a current capability higher than that of a power supply for the primary circuit system (400p).

### APPENDIX 31

The signal transmission device (400) according to any of Appendices 22 to 30, further including:
a first chip (410) in which the switching circuit (411) is integrated;
a second chip (420) in which the drive circuit (421) and the reception circuit (422) are integrated; and
a third chip (430) in which the first isolation device (431, 433) and the second isolation device (432, 434) are integrated, in which
the first chip (410), the second chip (420), and the third chip (430) are sealed in a single package.

### APPENDIX 32

The signal transmission device (700) according to any of Appendices 22 to 26, further including an isolation supply circuit (PW) configured to supply power from the secondary circuit system (700s) to the primary circuit system (700p) while isolating between the primary circuit system (700p) and the secondary circuit system (700s).

### APPENDIX 33

The signal transmission device (700) according to Appendix 32, in which
the isolation supply circuit (PW) includes
   a supply drive circuit (726) configured to generate both a third signal (I11) and a fourth signal (I12),
   a third isolation device (741) configured to be driven according to the third signal (I11) while isolating between the primary circuit system (700p) and the secondary circuit system (700s),
   a fourth isolation device (742) configured to be driven according to the fourth signal (I12) while isolating between the primary circuit system (700p) and the secondary circuit system (700s), and
   a rectification circuit (713) configured to generate a supply voltage (VREG) for the primary circuit system (700p) by using a first voltage (Va) to be induced in the primary circuit system (700p) via the third isolation device (741) and a second voltage (Vb) to be induced in the primary circuit system (700p) via the fourth isolation device (742).

### APPENDIX 34

The signal transmission device (700) according to Appendix 33, in which
the rectification circuit (713) includes voltage boosting circuits (CP21 to CP24) connected in series in a plurality of stages between an application terminal for the first voltage (Va) and an application terminal for the supply voltage (VREG),
voltage boosting circuits (CP21, CP23) in odd-numbered stages among the voltage boosting circuits (CP21 to CP24) in the plurality of stages respectively include
   first diodes (n21, n23) connected between the application terminal for the first voltage (Va) and the application terminal for the supply voltage (VREG) so that forward directions of the first diodes (n21, n23) are each a flow direction of a first current (I31) to be induced via the third isolation device (741), and
   first capacitors (C21, C23) connected between cathodes of the first diodes (n21, n23) and an application terminal for the second voltage (Vb), and
voltage boosting circuits (CP22, CP24) in even-numbered stages among the voltage boosting circuits (CP21 to CP24) in the plurality of stages respectively include
   second diodes (n22, n24) connected between the application terminal for the first voltage (Va) and the application terminal for the supply voltage (VREG) so that forward directions of the second diodes (n22, n24) are each the flow direction of the first current (I31), and
   second capacitors (C22, C24) connected between cathodes of the second diodes (n22, n24) and the application terminal for the first voltage (Va).

### APPENDIX 35

The signal transmission device (700) according to Appendix 33 or 34, in which a secondary coil (741s) to which the third signal (I11) is applied of the third isolation device (741) and a secondary coil (742s) to which the second signal (I12) is applied of the second isolation device (742) are connected in series, and
a winding direction of the secondary coil (741s) of the third isolation device (741) and a winding direction of the secondary coil (742s) of the fourth isolation device (742) are opposite to each other.

### APPENDIX 36

The signal transmission device (700) according to any of Appendices 33 to 35, further including:
a fifth isolation device (743) configured to isolate between the third isolation device (741) and an application terminal for the first voltage (Va); and
a sixth isolation device (744) configured to isolate between the fourth isolation device (742) and an application terminal for the second voltage (Vb).

### APPENDIX 37

The signal transmission device (700) according to any of Appendices 22 to 26, further including a third isolation device (735), in which
the drive circuit generates a third signal (I41) and a fourth signal (I42) as the first signal (Po),
a secondary coil (731s) to which the third signal (I41) is applied of the first isolation device (731) and a secondary coil (735s) to which the fourth signal (I42) is applied of the third isolation device (735) are connected in series, and
a winding direction of the secondary coil (731s) of the first isolation device (731) and a winding direction of the secondary coil (735s) of the third isolation device (7735) are opposite to each other.

### APPENDIX 38

The signal transmission device (700) according to any of Appendices 22 to 26, further including:
a third isolation device (733) configured to isolate between the first isolation device (731) and the switching circuit (711); and
a fourth isolation device (734) configured to isolate between the second isolation device (732) and the reception circuit 722.

The signal transmission device according to any of Appendices 22 to 38 can help signal transmission that does not depend on a power supply for the primary circuit system.

### APPENDIX 39

An isolation supply circuit (PW), including:
a supply drive circuit (726) configured to generate both a first signal (I11) and a second signal (I12);
a first isolation device (741) configured to be driven according to the first signal (I11) while isolating between the primary circuit system (700p) and the secondary circuit system (700s);
a second isolation device (742) configured to be driven according to the second signal (I12) while isolating between the primary circuit system (700p) and the secondary circuit system (700s); and
a rectification circuit (713) configured to generate a supply voltage (VREG) for the primary circuit system (700p) by using a first voltage (Va) to be induced in the primary circuit system (700p) via the first isolation device (741) and a second voltage (Vb) to be induced in the primary circuit system (700p) via the second isolation device (742).

### APPENDIX 40

The isolation supply circuit (PW) according to Appendix 39, in which
the rectification circuit (713) includes voltage boosting circuits (CP21 to CP24) connected in series in a plurality of stages between an application terminal for the first voltage (Va) and an application terminal for the supply voltage (VREG),
voltage boosting circuits (CP21, CP23) in odd-numbered stages among the voltage boosting circuits (CP21 to CP24) in the plurality of stages respectively include
   first diodes (n21, n23) connected between the application terminal for the first voltage (Va) and the application terminal for the supply voltage (VREG) so that forward directions of the first diodes (n21, n23) are each a flow direction of a first current (I31) to be induced via the first isolation device (741), and
   first capacitors (C21, C23) connected between cathodes of the first diodes (n21, n23) and an application terminal for the second voltage (Vb), and
voltage boosting circuits (CP22, CP24) in even-numbered stages among the voltage boosting circuits (CP21 to CP24) in the plurality of stages respectively include
   second diodes (n22, n24) connected between the application terminal for the first voltage (Va) and the application terminal for the supply voltage (VREG) so that forward directions of the second diodes (n22, n24) are each the flow direction of the first current (I31), and
   second capacitors (C22, C24) connected between cathodes of the second diodes (n22, n24) and the application terminal for the first voltage (Va).

The isolation supply circuits according to Appendices 39 or 40 can help supply power from the secondary circuit system to the primary circuit system without a power supply.

### APPENDIX 41

An isolation circuit (630, 730), including:
a first isolation device (631, 731, 741); and
a second isolation device (632, 735, 742),
the first isolation device (631, 731, 741) including
   a first coil (631p, 731s, 741s) to which a first signal (I11, I41) is applied, and
   a second coil (631s, 731p, 741p) which is electromagnetically coupled to the first coil (631p, 731s, 741s),
the second isolation device (632, 735, 742) including
   a third coil (632p, 735s, 742s) to which a second signal (I12, I42) is applied, and
   a fourth coil (632s, 735p, 742p) which is electromagnetically coupled to the third coil (632p, 735s, 742s),
the first coil (631p, 731s, 741s) and the third coil (632p, 735s, 742s) being connected in series,
a winding direction of the first coil (631p, 731s, 741s) and a winding direction of the third coil (632p, 735s, 742s) being opposite to each other.

### APPENDIX 42

The isolation circuit (630, 730) according to Appendix 41, further including:
a third isolation device (633, 733, 743); and
a fourth isolation device (634, 736, 744), in which
the third isolation device (633, 733, 743) includes
   a fifth coil (633p, 733s, 743s) which is connected in series with the second coil (631s, 731p, 741p), and
   a sixth coil (633s, 733p, 743p) which is electromagnetically coupled to the fifth coil (633p, 733s, 743s),
the fourth isolation device (634, 736, 744) includes
   a seventh coil (634p, 736s, 744s) which is connected in series with the fourth coil (632s, 735p, 742p), and
   an eighth coil (634s, 736p, 744p) which is electromagnetically coupled to the seventh coil (634p, 736s, 744s).

### Other Modification

Note that, the various technical features disclosed herein may be implemented in any manners other than those in the embodiments described above, and allow for various modifications without departure from the spirit of their technical ingenuity. That is, the embodiments described above should be understood to be illustrative and not restrictive in every aspect. Moreover, it should be understood that the technical scope of the present disclosure is defined by the appended claims, and encompasses any modifications within a scope and sense equivalent to those claims.

1. An isolation switch, comprising:
a switching unit configured to be controlled so that the switching unit enters a conducting state/a non-conducting state;
a conduction circuit configured to control the switching unit so that the switching unit enters the conducting state;
an adjustment circuit configured to adjust at least the switching unit from the conducting state to the non-conducting state; and
a pulse supply circuit configured to
receive a control signal and
supply a pulse signal to at least one of the conduction circuits and the adjustment circuit,
the conduction circuit including a first isolation device including
a first primary coil that is connected to the pulse supply circuit, and
a first secondary coil that is electromagnetically coupled to the first primary coil,
the conduction circuit being configured to bring the switching unit into the conducting state with an induced current that flows in response to rising of the pulse signal supplied to the first primary coil,
the adjustment circuit including
a second isolation device including
a second primary coil that is connected to the pulse supply circuit, and
a second secondary coil that is electromagnetically coupled to the second primary coil, and,
an adjustment device configured to adjust the switching unit into the non-conducting state by adjusting a voltage at a control terminal of the switching unit with an induced current that flows through the second secondary coil in response to rising of the pulse signal, and
the pulse supply circuit being configured to
supply the pulse signal to the first primary coil under a state in which the control signal is at a first level, and
supply the pulse signal to the second primary coil after a time point when the control signal is switched from the first level to a second level that is different from the first level,
the switching unit being configured to be set into the conducting state under the state in which the control signal is at the first level.

2. The isolation switch according to claim 1, wherein the conduction circuit has a configuration in which a diode is disposed between the first secondary coil and the control terminal of the switching unit so that a forward direction of the diode is a flow direction of the induced current to be generated in the first secondary coil.

3. The isolation switch according to claim 1, wherein
the switching unit includes an n-channel MOS transistor,
the conduction circuit is configured to cause the induced current to flow into a gate, and
the adjustment circuit is configured to cause current to be drawn out via the gate.

4. The isolation switch according to claim 1, wherein
the switching unit includes a p-channel MOS transistor,
the conduction circuit is configured to cause current to be drawn out via the gate by the induced current, and
the adjustment circuit is configured to supply the current to the gate.

5. The isolation switch according to claim 1, wherein
the switching unit has a configuration in which a first switching device and a second switching device are connected in series,
the first switching device and the second switching device are each one of an n-channel MOS transistor and a p-channel MOS transistor, and
a first terminal of the first secondary coil in the conduction circuit is connected to a connection node to which gates of both the first switching device and the second switching device are connected, and
a second terminal of the first secondary coil in the conduction circuit is connected to a connection node to which sources of both the first switching device and the second switching device are connected.

6. The isolation switch according to claim 1, wherein
the adjustment circuit includes an adjustment switching device connected between a gate and a source of a switching device that forms the switching unit, and
the adjustment circuit is configured to turn on the adjustment switching device with the induced current of the second secondary coil.

7. The isolation switch according to claim 1, wherein
the adjustment circuit is configured to be capable of assisting an operation to bring the switching unit by the conduction circuit into the conducting state under the state in which the control signal is at the first level, and
the pulse supply circuit is configured to supply the pulse signal to the second primary coil of the second isolation device under the state in which the control signal is at the first level.

8. The isolation switch according to claim 6, wherein
the conduction circuit is configured to suppress an operation to bring the switching unit by the adjustment circuit into the non-conducting state under the state in which the control signal is at the first level, and
the conduction circuit is configured to turn off the adjustment switching device with the induced current of the first secondary coil.

9. The isolation switch according to claim 1, wherein
the isolation switch has a configuration in which
the first secondary coil includes a plurality of first secondary coils that are connected in series, and
the first primary coil includes a plurality of first primary coils that are electromagnetically coupled respectively to the plurality of first secondary coils.

10. The isolation switch according to claim 1, wherein
the first secondary coil and the second secondary coil are connected in series, and
a winding direction of the second secondary coil and a winding direction of the first secondary coil are opposite to each other.

11. The isolation switch according to claim 1, wherein
the first isolation device is configured to double as the second isolation device.

12. The isolation switch according to claim 1, wherein
the pulse supply circuit is configured to generate the pulse signal in a first cycle for a predetermined period after a time point when the control signal is switched from the second level to the first level, and to then generate the pulse signal in a second cycle that is longer than the first cycle.

13. The isolation switch according to claim 11, wherein
the pulse supply circuit is
configured to supply the pulse signal to a first terminal of the first primary coil under the state in which the control signal is at the first level, and
configured to refrain from supplying the pulse signal to the first primary coil under a state in which the control signal is at the second level.

14. The isolation switch according to claim 11, wherein
the adjustment circuit is constituted by a resistor that is connected to the control terminal of the switching unit and to a ground potential.

15. The isolation switch according to claim 1, wherein
the adjustment circuit includes
a first adjustment-switching device connected in parallel to the first secondary coil, and
a second adjustment-switching device connected in parallel to the second secondary coil, and
the adjustment circuit has a configuration in which
the first adjustment-switching device is switched on by the induced current to be induced by the second secondary coil under a state in which the pulse signal has been supplied to the second primary coil, and
the first adjustment-switching device is switched off in response to switching on of the second adjustment-switching device by the induced current to be induced by the first secondary coil under the state in which the pulse signal has been supplied to the first primary coil.

16. The isolation switch according to claim 1, wherein
the conduction circuit includes voltage boosting circuits connected in series in a plurality of stages between the first secondary coil and the control terminal of the switching unit,
a voltage boosting circuit in an odd-numbered stage among the voltage boosting circuits in the plurality of stages includes
a first diode connected between the first secondary coil and the control terminal of the switching unit so that a forward direction of the first diode is a flow direction of an induced current to be generated in the first secondary coil, and
a first capacitor connected between a cathode of the first diode and the second secondary coil, and
a voltage boosting circuit in an even-numbered stage among the voltage boosting circuits in the plurality of stages includes
a second diode connected between the first secondary coil and the control terminal of the switching unit so that a forward direction of the second diode is the flow direction of the induced current to be generated in the first secondary coil, and
a second capacitor connected between a cathode of the second diode and the first secondary coil.

17. The isolation switch according to claim 1, wherein
the adjustment circuit includes
a first adjustment-switching device connected in parallel to the first secondary coil,
a first transistor connected between the second secondary coil and a control terminal of the first adjustment-switching device,
a first capacitor connected between a first main electrode and a control terminal of the first transistor, and
a first resistor connected between a second main electrode and the control terminal of the first transistor.

18. The isolation switch according to claim 17, wherein
the adjustment circuit includes
a second adjustment-switching device connected in parallel to the second secondary coil,
a second transistor connected between the first secondary coil and a control terminal of the second adjustment-switching device,
a second capacitor connected between a first main electrode and a control terminal of the second transistor, and
a second resistor connected between a second main electrode and the control terminal of the second transistor.

19. The isolation switch according to claim 1, wherein
the first primary coil and the second primary coil are connected in series, and
a winding direction of the first primary coil and a winding direction of the second primary coil are opposite to each other.

20. The isolation switch according to claim 1, further comprising:
a third isolation device including
a third primary coil connected in series with the first secondary coil and
a third secondary coil to be electromagnetically coupled to the third primary coil; and
a fourth isolation device including
a fourth primary coil connected in series with the second secondary coil, and
a fourth secondary coil to be electromagnetically coupled to the fourth primary coil, wherein
the switching unit is controlled by induced currents to flow respectively through the third secondary coil and the fourth secondary coil.

21. A sequencer, comprising the isolation switch according to claim 1.
